(19) United States
(12) Patent Application Publication
(10) Pub. No.: US 2018/0017720 A1
(43) Pub. Date: Jan. 18, 2018

(54) INFRARED CUT FILTER, KIT, AND SOLID-STATE IMAGING DEVICE

(71) Applicant: FUJIFILM Corporation, Tokyo (JP)

(72) Inventors: Keisuke ARIMURA, Haibara-gun (JP); Kazuto SHIMADA, Haibara-gun (JP); Daisuke SASAKI, Haibara-gun (JP); Yuki HIRAI, Haibara-gun (JP); Tokihiko MATSUMURA, Haibara-gun (JP)

(73) Assignee: FUJIFILM Corporation, Tokyo (JP)

(21) Appl. No.: 15/717,025

(22) Filed: Sep. 27, 2017

Related U.S. Application Data
(63) Continuation of application No. PCT/JP2016/059811, filed on Mar. 28, 2016.

(30) Foreign Application Priority Data
Mar. 31, 2015 (JP) 2015-072578

(51) Int. Cl. G02B 5/20; C09B 23/16; C09B 57/00; G02B 5/00; H01L 27/146

(52) U.S. Cl. CPC G02B 5/208; C09B 57/007; G02B 5/003; C09B 23/164; C09B 57/00; H01L 27/14621

(57) ABSTRACT

To provide an infrared cut filter having a wide view angle and excellent infrared shieldability, a kit for manufacturing the infrared cut filter, and a solid-state imaging device. An infrared cut filter has: a copper-containing transparent layer 1. The copper-containing transparent layer 1 further contains an infrared absorbing agent, or an infrared absorbing agent-containing layer 2 is further provided.

### CROSS-REFERENCE TO RELATED APPLICATIONS

This application is a Continuation of PCT International Application No. PCT/JP2016/059811 filed on Mar. 28, 2016, which claims priority under 35 U.S.C §119(a) to Japanese Patent Application No. 2015-072578 filed on Mar. 31, 2015. Each of the above application(s) is hereby expressly incorporated by reference, in its entirety, into the present application.

### BACKGROUND OF THE INVENTION

### 1. Field of the Invention

The present invention relates to an infrared cut filter, a kit for manufacturing the infrared cut filter, and a solid-state imaging device having the infrared cut filter.

### 2. Description of the Related Art

In a video camera, a digital still camera, a cellular phone with a camera function, or the like, a charge coupled device (CCD) or a complementary metal oxide semiconductor (CMOS) which is a solid-state imaging device for a color image is used. These solid-state imaging devices use a silicon photodiode having sensitivity to an infrared ray in a light receiving section thereof. Therefore, visibility correction is required and an infrared cut filter is used in many cases.

As an infrared cut filter, there is an infrared cut filter having an infrared reflection film formed on a surface of a transparent member such as glass. The infrared reflection film is required to have a high transmittance of light with a visible wavelength, and from such a viewpoint, a dielectric multi-layer film in which high refractive index material layers and low refractive index material layers are laminated is used as an infrared reflection film (see JP2000-221322A, JP1982-58109A (JP-S57-58109A), JP1996-249914A (JP-H08-249914A), JP2006-36560A, and JP2006-71851A).

In addition, an infrared cut filter may be formed of infrared absorbing glass having an infrared absorbing composition system. As the infrared absorbing glass, phosphate-based glass or fluorophosphate-based glass containing CuO added thereto is known (see JP1989-219037A (JP-H01-219037A)).

In addition, WO2014/168189A discloses an infrared cut filter in which an infrared absorbing layer containing a transparent resin and an organic coloring agent is formed on a surface of a transparent member. A polyester resin is used as the transparent resin.

### SUMMARY OF THE INVENTION

However, the infrared cut filters disclosed in JP2000-221322A, JP1982-58109A (JP-S57-58109A), JP1996-249914A (JP-H08-249914A), JP2006-36560A, and JP2006-71851A have a problem in that these have different optical characteristics with respect to vertical incident light and oblique incident light, and the view angle is easily reduced.

The infrared cut filters disclosed in JP1989-219037A (JP-H01-219037A) and WO2014/168189A do not have sufficient infrared shieldability.

Accordingly, an object of the invention is to provide an infrared cut filter having a wide view angle and excellent infrared shieldability, a kit for manufacturing the infrared cut filter, and a solid-state imaging device.

The inventors have conducted various examinations in order to achieve the object, and as a result, have found that the object can be achieved with the following configurations, and completed the invention. The invention provides the followings.

<1> An infrared cut filter comprising: a copper-containing transparent layer, in which the copper-containing transparent layer further contains an infrared absorbing agent, or an infrared absorbing agent-containing layer is further provided.

<2> The infrared cut filter according to <1>, in which a maximum absorption wavelength is shown in a wavelength region of 600 nm or greater, and a ratio B/A of, to absorbance A at the maximum absorption wavelength before the infrared cut filter is dipped in at least one organic solvent selected from propylene glycol monomethyl ether, propylene glycol monomethyl ether acetate, methyl 3-methoxypropionate, ethyl lactate, acetone, and ethanol, absorbance B at the wavelength at which the absorbance A is measured after the infrared cut filter is dipped in the organic solvent for 2 minutes at 25° C. is 0.9 or greater.

<3> The infrared cut filter according to <1> or <2>, in which the infrared absorbing agent-containing layer includes a resin.

<4> The infrared cut filter according to any one of <1> to <3>, in which the infrared absorbing agent-containing layer includes a three-dimensional crosslinked material.

<5> The infrared cut filter according to <4>, in which the three-dimensional crosslinked material is formed by curing a polymerizable compound having two or more polymerizable groups.

<6> The infrared cut filter according to any one of <1> to <5>, in which the infrared absorbing agent-containing layer includes gelatin.

<7> The infrared cut filter according to any one of <1> to <6>, in which the infrared absorbing agent is a compound having a maximum absorption wavelength in a wavelength region of 675 to 900 nm.

<8> The infrared cut filter according to any one of <1> to <7>, in which the infrared absorbing agent includes an organic coloring agent.

<9> The infrared cut filter according to any one of <1> to <8>, in which the infrared absorbing agent contains at least one selected from a cyanine compound, a pyrrolopyrrole compound, a squarylium compound, a phthalocyanine compound, and a naphthalocyanine compound.

<10> The infrared cut filter according to any one of <1> to <9>, in which the infrared absorbing agent is at least one selected from compounds represented by Formulae 1 to 3,

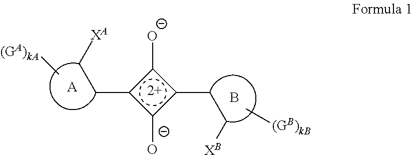

in Formula 1, a ring A and a ring B each independently represent an aromatic ring,

X^{A} and X^{B} each independently represent a substituent,

G^{A} and G^{B} each independently represent a substituent,

kA represents an integer of 0 to nA, and kB represents an integer of 0 to nB,

nA represents a maximum integer in which substitution with the ring A is possible, and nB represents a maximum integer in which substitution with the ring B is possible, and

each of X^{A} and G^{A}, and X^{B} and G^{B} may be bonded to form a ring, and in a case where there are plural G^{A}'s and G^{B}'s, each of G^{A}'s and G^{B}'s may be bonded to form a ring,

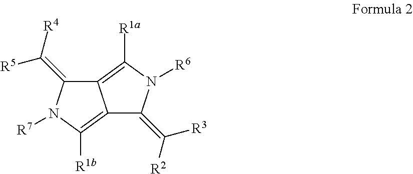

in Formula 2, R^{1a} and R^{1b} each independently represent an alkyl group, an aryl group, or a heteroaryl group,

R² to R⁵ each independently represent a hydrogen atom or a substituent, and each of R² and R³, and R⁴ and R⁵ may be bonded to form a ring,

R⁶ and R⁷ each independently represent a hydrogen atom, an alkyl group, an aryl group, a heteroaryl group, —BR^{A}R^{B}, or a metal atom, and R^{A} and R^{B} each independently represent a hydrogen atom or a substituent, and

R⁶ may be bonded to R^{1a} or R³ by a covalent bond or a coordination bond, and R⁷ may be bonded to R^{1b} or R⁵ by a covalent bond or a coordination bond,

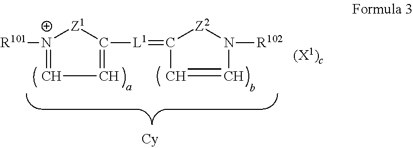

in Formula 3, Z¹ and Z² each independently represent a non-metallic atomic group necessary for forming a five-membered or six-membered nitrogen-containing heterocyclic ring that may be condensed,

R¹⁰¹ and R¹⁰² each independently represent an alkyl group, an alkenyl group, alkynyl group, an aralkyl group, or an aryl group,

L¹ represents a methine chain composed of an odd number of methines.

a and b each independently represent 0 or 1,

in a case where a is 0, a carbon atom and a nitrogen atom are bonded by a double bond, and in a case where b is 0, a carbon atom and a nitrogen atom are bonded by a single bond, and

in a case where a site represented by Cy in the formula is a cationic portion, X¹ represents an anion, and c represents the number necessary for keeping a balance of electric charges, in a case where a site represented by Cy in the formula is an anionic portion, X¹ represents a cation, and c represents the number necessary for keeping a balance of electric charges, and in a case where the electric charge of a site represented by Cy in the formula is neutralized in the molecule, c is zero.

<11> The infrared cut filter according to any one of <1> to <10>, in which the infrared absorbing agent is a compound capable of being dissolved in an amount of 1 mass % or greater in water at 25° C.

<12> The infrared cut filter according to any one of <1> to <11>, comprising: the copper-containing transparent layer; and the infrared absorbing agent-containing layer, in which the infrared absorbing agent-containing layer is provided on both sides of the copper-containing transparent layer.

<13> The infrared cut filter according to any one of <1> to <12>, further comprising: a dielectric multi-layer film.

<14> The infrared cut filter according to <13>, comprising: the copper-containing transparent layer; the infrared absorbing agent-containing layer; and the dielectric multi-layer film, in which the infrared absorbing agent-containing layer is provided between the copper-containing transparent layer and the dielectric multi-layer film, and the infrared absorbing agent-containing layer and the dielectric multi-layer film are in contact with each other.

<15> A kit for manufacturing an infrared cut filter having a copper-containing transparent layer and an infrared absorbing agent-containing layer, comprising: a copper-containing transparent member; and an infrared absorbing composition containing an infrared absorbing agent.

<16> A solid-state imaging device comprising: the infrared cut filter according to any one of claims 1 to 14.

According to the invention, it is possible to provide an infrared cut filter having a wide view angle and excellent infrared shieldability. In addition, it is possible to provide a kit for the infrared cut filter and a solid-state imaging device.

### BRIEF DESCRIPTION OF THE DRAWINGS

FIG. 1 is a schematic diagram of an infrared cut filter according to an embodiment of the invention.

### DESCRIPTION OF THE PREFERRED EMBODIMENTS

Hereinafter, the contents of the invention will be described in detail.

In this specification, the expression “to” is used to mean that numerical values before and after the expression are included as a lower limit value and an upper limit value.

In the description of a group (atomic group) in this specification, a denotation without substitution and unsubstitution includes a group (atomic group) with a substituent, together with a group (atomic group) without a substituent. For example, an “alkyl group” includes not only an alkyl group (unsubstituted alkyl group) without a substituent but also an alkyl group (substituted alkyl group) with a substituent.

In this specification, “(meth)acrylate” represents acrylate and methacrylate, “(meth)acryl” represents acryl and methacryl, and “(meth)acryloyl” represents acryloyl and methacryloyl.

In this specification, a monomer refers to a compound that is distinguished from an oligomer and a polymer and has a weight average molecular weight of 2,000 or less.

In this specification, a polymerizable compound refers to a compound having a polymerizable functional group, and may be a monomer or a polymer. A polymerizable functional group refers to a group involved in a polymerization reaction.

A weight average molecular weight and a number average molecular weight of a compound used in the invention can be measured by gel permeation chromatography (GPC), and are defined as values in terms of polystyrene measured by GPC.

In this specification, an infrared ray refers to light with a maximum absorption wavelength region of 700 to 2,500 nm (electromagnetic wave).

In this specification, a total solid content refers to a total mass of components except for a solvent from the entire content of a composition. In the invention, a solid content is a solid content at 25° C.

<Infrared Cut Filter>

An infrared cut filter according to the invention has a copper-containing transparent layer. The copper-containing transparent layer further contains an infrared absorbing agent, or the infrared cut filter further has an infrared absorbing agent-containing layer.

The infrared cut filter according to the present invention can be formed as an infrared cut filter having a wide view angle and excellent infrared shieldability in a case where the copper-containing transparent layer further contains an infrared absorbing agent, or the infrared cut filter further has an infrared absorbing agent-containing layer other than the copper-containing transparent layer.

In a first embodiment of the infrared cut filter according to the invention, the infrared cut filter has a copper-containing transparent layer and an infrared absorbing agent-containing layer. In this aspect, the copper-containing transparent layer may or may not further contain an infrared absorbing agent. That is, the copper-containing transparent layer of the first embodiment may contain copper and an infrared absorbing agent.

As the copper-containing transparent layer, a glass base formed of copper-containing glass (copper-containing glass base) or a layer containing a copper complex (copper complex-containing layer) to be described later can be used. In a case where a copper complex-containing layer is used as the copper-containing transparent layer, the copper complex-containing layer may be used alone or in combination with a support.

In the first embodiment of the infrared cut filter according to the invention, the infrared cut filter may have at least a copper-containing transparent layer (copper complex-containing layer) and an infrared absorbing agent-containing layer, or may have at least a support, a copper-containing transparent layer (copper complex-containing layer), and an infrared absorbing agent-containing layer. In addition, the infrared cut filter may further have a dielectric multi-layer film to be described later.

In a second embodiment of the infrared cut filter according to the invention, the infrared cut filter has a transparent layer containing copper and an infrared absorbing agent.

The transparent layer containing copper and an infrared absorbing agent can be used alone or in combination with a support. The infrared cut filter may further have a dielectric multi-layer film to be described later.

In the infrared cut filter according to the invention, the transmittance of light with a wavelength of 420 to 550 nm measured in a direction perpendicular to the infrared cut filter is preferably 80% or greater, more preferably 90% or greater, and even more preferably 95% or greater. In addition, the transmittance of light with a wavelength of 700 nm measured in the direction perpendicular to the infrared cut filter is preferably 5% or less, more preferably 1% or less, and even more preferably 0.5% or less. In addition, the average of the transmittance of light with a wavelength of 700 to 1,000 nm measured in the direction perpendicular to the infrared cut filter is preferably less than 5%, more preferably less than 3%, and even more preferably less than 1%.

In addition, in the infrared cut filter according to the invention, the wavelength at which the transmittance of a slope caused by a reduction in the spectral transmittance in a region ranging from visible to near-infrared, measured in the direction perpendicular to the infrared cut filter, is 50% is preferably in a range of 600 to 700 nm, more preferably in a range of 610 to 660 nm, and even more preferably in a range of 620 to 650 nm. In addition, the difference in wavelength at which the transmittance is 50% between a case where the transmittance is measured in the direction perpendicular to the infrared cut filter (angle: 0 degrees) and a case where the transmittance is measured at an angle of 40 degrees is preferably less than 30 nm, more preferably less than 10 nm, and even more preferably less than 5 nm.

The infrared cut filter according to the invention preferably has a maximum absorption wavelength in a wavelength region of 600 nm or greater.

A ratio B/A of, to absorbance A at the maximum absorption wavelength before the infrared cut filter is dipped in at least one organic solvent selected from propylene glycol monomethyl ether, propylene glycol monomethyl ether acetate, methyl 3-methoxypropionate, ethyl lactate, acetone, and ethanol, absorbance B at the wavelength at which the absorbance A is measured after the infrared cut filter is dipped in the organic solvent for 2 minutes at 25° C. is preferably 0.9 or greater. In a case where the absorbance ratio B/A is 0.9 or greater, it is possible to suppress the generation of defects caused by washing with the organic solvent.

In addition, in a case where the infrared cut filter according to the invention has a copper-containing transparent layer and an infrared absorbing agent-containing layer, the infrared absorbing agent-containing layer preferably has a maximum absorption wavelength in a wavelength region of 600 nm or greater. In addition, a ratio B/A of, to absorbance A at the maximum absorption wavelength before the infrared absorbing agent-containing layer is dipped in at least one organic solvent selected from propylene glycol monomethyl ether, propylene glycol monomethyl ether acetate, methyl 3-methoxypropionate, ethyl lactate, acetone, and ethanol, absorbance B at the wavelength at which the absorbance A is measured after the infrared absorbing agent-containing layer is dipped in the organic solvent for 2 minutes at 25° C. is preferably 0.9 or greater.

Hereinafter, the infrared cut filter according to the invention will be described in detail.

<<Copper-Containing Transparent Layer>>

Examples of the copper-containing transparent layer include a glass base formed of copper-containing glass (copper-containing glass base) and a layer containing a copper complex (copper complex-containing layer).

In the copper-containing transparent layer (hereinafter, also referred to as the transparent layer), the transmittance of light with a wavelength of 420 to 550 nm measured in a direction perpendicular to the transparent layer is preferably 80% or greater, more preferably 90% or greater, and even more preferably 95% or greater.

The copper-containing transparent layer may further contain an infrared absorbing agent. In this case, the infrared cut filter may have an infrared absorbing layer to be described later, or the infrared absorbing layer may be omitted. The infrared absorbing agent will be described later.

<<<Copper-Containing Glass Base>>>

Examples of the copper-containing glass include copper-containing phosphate glass and copper-containing fluorophosphates glass.

Specific examples of the copper-containing glass are as follows.

(1) Glass containing 0.5 to 7 parts by mass of CuO in terms of outer percentage, to 100 parts by mass of base glass containing, in mass %, 46% to 70% of P₂O₅, 0.2% to 20% of AlF₃, 0% to 25% of ΣRF (R═Li, Na, K), and 1% to 50% of ΣR′F₂ (R′=Mg, Ca, Sr, Ba, Pb) where F is 0.5% to 32% and O is 26% to 54%.

(2) Glass made of, in mass %, 25% to 60% of P₂O₅, 1% to 13% of Al₂O₃, 1% to 10% of MgO, 1% to 16% of CaO, 1% to 26% of BaO, 0% to 16% of SrO, 0% to 16% of ZnO, 0% to 13% of Li₂O, 0% to 10% of Na₂O, 0% to 11% of K₂O, 1% to 7% of CuO, 15% to 40% of ΣRO (R═Mg, Ca, Sr, Ba), 3% to 18% of ΣR′₂O (R′═Li, Na, K) (up to 39% molar quantity of O²⁻ ion is substituted with F).

(3) Glass containing, in mass %, 5% to 45% of P₂O₅, 1% to 35% of AlF₃, 0% to 40% of ΣRF (R═Li, Na, K), 10% to 75% of ΣR′F₂ (R′═Mg, Ca, Sr, Ba, Pb, Zn), 0% to 15% of R″Fₘ (R″═La, Y, Cd, Si, B, Zr, Ta, and m is the number corresponding to valence of R″) (up to 70% of the total amount of a fluoride can be substituted with an oxide), and 0.2% to 15% of CuO.

(4) Glass containing, in cation %, 11% to 43% of P⁵⁺, 1% to 29% of Al³⁺, 14% to 50% of ΣR cation (R═Mg, Ca, Sr, Ba, Pb, Zn), 0% to 43% of ΣR′ cation (R′═Li, Na, K), 0% to 8% of ΣR″ cation (R″═La, Y, Gd, Si, B, Zr, Ta), and 0.5% to 13% of Cu²⁺, and further containing 17% to 80% of F⁻ in anion %.

(5) Glass containing, in cation %, 23% to 41% of P⁵⁺, 4% to 16% of Al³⁺, 11% to 40% of Li⁺, 3% to 13% of Na⁺, 12% to 53% of ΣR cation (R═Mg, Ca, Sr, Ba, Zn), and 2.6% to 4.7% of Cu²⁺, and further containing, in anion %, 25% to 48% of F⁻ and 52% to 75% of O²⁻.

(6) Glass containing 0.1 to 5 parts by mass of CuO in terms of outer percentage, to 100 parts by mass of base glass made of, in mass %, 70% to 85% of P₂O₅, 8% to 17% of Al₂O₃, 1% to 10% of B₂O₃, 0% to 3% of Li₂O, 0% to 5% of Na₂O, 0% to 5% of K₂O where ΣR₂O (R═Li, Na, K) is 0.1% to 5% with 0% to 3% of SiO₂.

Examples of commercially available products of the above-described copper-containing glass include NF-50 (manufactured by Asahi Glass Co., Ltd, trade name), BG-60, BG-61 (all manufactured by Schott AG, trade name), and CD5000 (manufactured by HOYA, trade name).

The above-described copper-containing glass may further contain one or more predetermined metal oxides such as Fe₂O₃, MoO₃, WO₃, CeO₂, Sb₂O₃, and V₂O₅, and thus may be used as glass having ultraviolet absorption characteristics imparted thereto. Specifically, with respect to 100 parts by mass of the above-described copper-containing glass, in a case of at least one selected from the group consisting of Fe₂O₃, MoO₃, WO₃, and CeO₂, Fe₂O₃ is 0.6 to 5 parts by mass, MoO₃ is 0.5 to 5 parts by mass, WO₃ is 1 to 6 parts by mass, and CeO₂ is 2.5 to 6 parts by mass, or in a case of two of Fe₂O₃ and Sb₂O₃, Fe₂O₃ is 0.6 to 5 parts by mass+Sb₂O₃ is 0.1 to 5 parts by mass, or in a case of two of V₂O₅ and CeO₂, V₂O₅ is 0.01 to 0.5 parts by mass+CeO₂ is 1 to 6 parts by mass.

In a case where a copper-containing glass base is used as the copper-containing transparent layer, the thickness of the copper-containing glass base is preferably 0.05 to 1.0 mm. The lower limit is preferably not less than 0.05 mm, and more preferably not less than 0.1 mm. The upper limit is preferably not greater than 0.3 mm, and more preferably not greater than 0.2 mm.

<<Copper Complex-Containing Layer>>

Examples of the copper complex-containing layer include a layer formed using a copper complex-containing composition containing a copper complex.

<<<Copper Complex>>>

The copper complex is preferably a compound having a maximum absorption wavelength in a wavelength region of 700 to 1,200 nm. The maximum absorption wavelength of the copper complex is more preferably in a wavelength region of 720 to 1,200 nm, and even more preferably in a wavelength region of 800 to 1,100 nm. The maximum absorption wavelength can be measured using, for example, Cary 5000 UV-Vis-NIR (spectrophotometer, manufactured by Agilent Technologies).

The molar light absorption coefficient at the maximum absorption wavelength in the above-described wavelength region of the copper complex is preferably 120 (L/mol·cm) or greater, more preferably 150 (L/mol·cm) or greater, even more preferably 200 (L/mol·cm) or greater, still more preferably 300 (L/mol·cm) or greater, and particularly preferably 400 (L/mol·cm) or greater. The upper limit is not particularly limited, but may be, for example, not greater than 30,000 (L/mol·cm). In a case where the molar light absorption coefficient of the copper complex is 100 (L/mol·cm) or greater, it is possible to form a cured film having excellent infrared shieldability even with a small thickness.

The gram light absorption coefficient of the copper complex at 800 nm is preferably 0.11 (L/g·cm) or greater, more preferably 0.15 (L/g·cm) or greater, and even more preferably 0.24 (L/g·cm) or greater.

In the invention, the molar light absorption coefficient and the gram light absorption coefficient of the copper complex can be obtained by measuring an absorption spectrum of a solution with a concentration of 1 g/L prepared by dissolving the copper complex in a solvent. As the measuring device, UV-1800 manufactured by Shimadzu Corporation (wavelength region: 200 to 1,100 nm), Cary 5000 manufactured by Agilent Technologies (wavelength region: 200 to 1,300 nm), or the like can be used. Examples of the measuring solvent include water, N,N-dimethylformamide, propylene glycol monomethyl ether, 1,2,4-trichlorobenzene, and acetone. In the invention, among the above-described measuring solvents, a solvent that can dissolve the copper complex that is a measuring target is selected and used. Among these, in a case of a copper complex that is dissolved in propylene glycol monomethyl ether, propylene glycol monomethyl ether is preferably used as the measuring solvent. The verb dissolve means a state in which the solubility of the copper complex with respect to a solvent at 25° C. is greater than 0.01 g/100 g Solvent.

In the invention, the molar light absorption coefficient and the gram light absorption coefficient of the copper complex are preferably values measured using any one of the above-described measuring solvents, and more preferably values measured using propylene glycol monomethyl ether.

Examples of the method of adjusting the molar light absorption coefficient of the copper complex to 100 (L/mol·cm) or greater include methods using a five-coordinate copper complex, methods using a ligand having high π-donation properties, and methods using a copper complex having low symmetry.

A mechanism capable of achieving 100 (L/mol·cm) or greater of a molar light absorption coefficient using a five-coordinate copper complex is presumed as follows. That is, the symmetry of the complex is reduced by employing a pentadentate, preferably, five-coordinate trigonal bipyramid structure, or a five-coordinate quadrangular pyramid structure. Accordingly, in the interaction between the ligand and the copper, a p-orbit is easy to mix with a d-orbit. In this case, d-d transition (absorption of near-infrared region) is not pure d-d transition, and contribution of p-d transition that is allowable transition mixes therewith. Accordingly, the light absorption coefficient is improved and it can be thought that 100 (L/mol·cm) or greater can be achieved.

The five-coordinate copper complex can be prepared by, for example, reacting a copper ion with: two bidentate ligands (these may be the same or different) and one monodentate ligand; one tridentate ligand and two bidentate ligands (these may be the same or different); one tridentate ligand and one bidentate ligand; one tetradentate ligand and one monodentate ligand; or one pentadentate ligand. In this case, the monodentate ligand coordinating by an unshared electron pair may be used as a reaction solvent. For example, in a case where a copper ion is reacted with two bidentate ligands in a solvent containing water, a five-coordinate complex coordinating with the two bidentate ligands and the water as a monodentate ligand is obtained.

A mechanism capable of achieving 100 (L/mol·cm) or greater of a molar light absorption coefficient using a ligand having high π-donation properties is presumed as follows. That is, using a ligand having high π-donation properties (a ligand at a place where a π-orbit or a p-orbit of the ligand is energetically low), a p-orbit of a metal is easy to mix with the p-orbit (or π-orbit) of the ligand. In this case, d-d transition is not pure d-d transition, and contribution of ligand to metal charge transfer (LMCT) transition that is allowable transition mixes therewith. Accordingly, the light absorption coefficient is improved and it can be thought that 100 (L/mol·cm) or greater can be achieved.

Examples of the ligand having high π-donation properties include a halogen ligand, an oxygen anion ligand, and a sulfur anion ligand. Examples of the copper complex using a ligand having high π-donation properties include a copper complex having a Cl ligand as a monodentate ligand.

The copper complex having low symmetry can be obtained by using a ligand having low symmetry or unsymmetrically introducing a ligand with respect to a copper ion. Specific description is as follows.

For example, in a case where a tridentate ligand L¹-L²-L³ and two monodentate ligands L⁴ and L⁵ are used, as shown in Formula (1), a ligand having low symmetry, for example, a ligand where L¹ and L³ are different is used to obtain a copper complex having low symmetry. In addition, a copper complex having low symmetry is obtained in a case where a ligand is unsymmetrically introduced with respect to a copper ion, for example, L⁴ and L⁵ are different rather than the same.

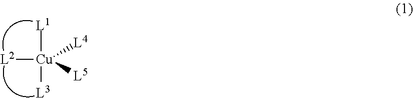

In addition, in a case where L⁴ and L⁵ are the same in a quadrangular pyramid complex, a copper complex having low symmetry is obtained in a case L⁴ and L⁵ are adjacent to each other on the bottom surface as in Formula (3) or one monodentate ligand is at a top vertex of the quadrangular pyramid as in Formula (4), rather than in a case where L⁴ and L⁵ are on the diagonal line of the bottom surface of the quadrangular pyramid as in Formula (2).

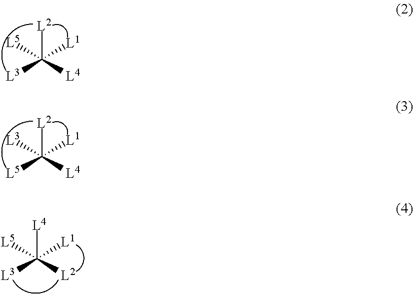

In addition, in a case where two bidentate ligands L⁶-L⁷ and L⁸-L⁹ and a monodentate ligand L¹⁰ are used, as shown in Formula (5), a ligand having low symmetry, for example, a ligand where L⁶ and L⁷ are different, and/or L⁸ and L⁹ are different is used to obtain a copper complex having low symmetry.

In addition, a copper complex having low symmetry is obtained in a case where a ligand is unsymmetrically introduced with respect to a copper ion, for example, L⁶-L⁷ and L⁸-L⁹ are different rather than the same. In addition, in a case where L⁶-L⁷ and L⁸-L⁹ are the same, a copper complex having lower symmetry is obtained in a case of L⁶=L⁹ and L⁷=L⁸ than in a case of L⁶=L⁸ and L⁷=L⁹.

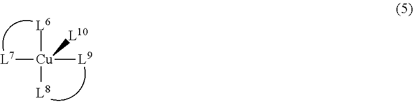

In the invention, the copper complex preferably has a compound having at least two coordination sites (hereinafter, also referred to as the compound (A)) as a ligand. The compound (A) more preferably has at least three coordination sites, and even more preferably has three to five coordination sites. The compound (A) acts as a chelate ligand on a copper component. That is, it is thought that at least two coordinating atoms of the compound (A) form chelate coordination to copper, and thus the structure of the copper complex is distorted, high transmittance is obtained in a visible light region, infrared light absorption performance can be improved, and color valency is improved. Accordingly, even in a case where an infrared cut filter is used for a long period of time, characteristics thereof are not damaged, and a camera module can be stably manufactured.

The copper complex used in the invention may have two or more compounds (A). In a case where the copper complex has two or more compounds (A), the respective compounds (A) may be the same or different.

Examples of the coordination site of the compound (A) include a coordination site coordinating by an anion and a coordination site coordinating by an unshared electron pair.

As the copper complex used in the invention, a four-coordinate copper complex, a five-coordinate copper complex, and a six-coordinate copper complex are exemplified. A four-coordinate copper complex and a five-coordinate copper complex are more preferable, and a five-coordinate copper complex is even more preferable.

In addition, in the copper complex, a five-membered ring and/or a six-membered ring is/are preferably formed by copper and a ligand. Such a copper complex has a stable shape and is excellent in complex stability.

The copper of the copper complex used in the invention can be obtained by mixing and reacting the compound (A) with, for example, a copper component (copper or copper-containing compound).

The copper component is preferably a compound containing divalent copper. The copper component may be used singly, or two or more types thereof may be used.

For example, a copper oxide or copper salt can be used as the copper component. As the copper salt, for example, copper carboxylate (such as copper acetate, copper ethyl acetoacetate, copper formate, copper benzoate, copper stearate, copper naphthenate, copper citrate, and copper 2-ethylhexanoate), copper sulfonate (such as copper methanesulfonate), copper phosphate, phosphoric acid ester copper, copper phosphonate, phosphonic acid ester copper, copper phosphinate, copper amide, copper sulfonamide, copper imide, copper acyl sulfonimide, copper bissulfonimide, copper methide, alkoxycopper, phenoxycopper, copper hydroxide, copper carbonate, copper sulfate, copper nitrate, copper perchlorate, copper fluoride, copper chloride, and copper bromide are preferable, copper carboxylate, copper sulfonate, copper sulfonamide, copper imide, copper acyl sulfonimide, copper bissulfonimide, alkoxycopper, phenoxycopper, copper hydroxide, copper carbonate, copper fluoride, copper chloride, copper sulfate, and copper nitrate are more preferable, copper carboxylate, copper acyl sulfonimide, phenoxycopper, copper chloride, copper sulfate, and copper nitrate are even more preferable, and copper carboxylate, copper acyl sulfonimide, copper chloride, and copper sulfate are particularly preferable.

The amount of the copper component to be reacted with the compound (A) is, in terms of molar ratio (compound (A):copper component), preferably 1:0.5 to 1:8, and more preferably 1:0.5 to 1:4.

Regarding reaction conditions for reaction of the copper component with the compound (A), the reaction is preferably performed at 20° C. to 100° C. for 0.5 hours or longer.

The copper complex used in the invention may have a ligand other than the compound (A). Examples of the ligand other than the compound (A) include a monodentate ligand coordinating by an anion or an unshared electron pair. Examples of the ligand coordinating by an anion include a halide anion, a hydroxide anion, an alkoxide anion, a phenoxide anion, an amide anion (including amides substituted with an acyl group or a sulfonyl group), an imide anion (including imides substituted with an acyl group or a sulfonyl group), an anilide anion (including anilides substituted with an acyl group or a sulfonyl group), a thiolate anion, a hydrogen carbonate anion, a carboxylate anion, a thiocarboxylate anion, a dithiocarboxylate anion, a hydrogen sulfate anion, a sulfonate anion, a dihydrogen phosphate anion, a phosphoric acid diester anion, a phosphonic acid monoester anion, a hydrogen phosphonate anion, a phosphinate anion, a nitrogen-containing heterocyclic anion, a nitrate anion, a hypochlorite anion, a cyanide anion, a cyanate anion, an isocyanate anion, a thiocyanate anion, an isothiocyanate anion, and an azide anion. Examples of the monodentate ligand coordinating by an unshared electron pair include water, alcohol, phenol, ether, amine, aniline, amide, imide, imine, nitrile, isonitrile, thiol, thioether, a carbonyl compound, a thiocarbonyl compound, sulfoxide, a hetero ring, a carbonic acid, a carboxylic acid, a sulfuric acid, a sulfonic acid, a phosphoric acid, a phosphonic acid, a phosphinic acid, a nitric acid, and esters of the acids.

The type and the number of the monodentate ligands can be suitably selected according to the compound (A) coordinating with a copper complex.

Specific examples of the monodentate ligand used as a ligand other than the compound (A) are as follows, but not limited thereto. In the following table, Ph represents a phenyl group, and Me represents a methyl group.

TABLE 1

| | |
|---|---|
| A1-1 | —Cl |
| A1-2 | —Br |
| A1-3 | —F |
| A1-4 | —OH |
| A1-5 | —OMe |
| A1-6 | —OPh |
| A1-7 | —NH₂ |
| A1-8 | —NHCOCH₃ |
| A1-9 | —NHCOCF₃ |
| A1-10 | —NHSO₂CH₃ |
| A1-11 | —NHSO₂CF₃ |
| A1-12 | —N(COCH₃)₂ |
| A1-13 | —N(SO₂CF₃)₂ |
| A1-14 | —SC(═S)CH₃ |
| A1-15 | —OP(═O)(OMe)Ph |
| A1-16 | —OS(═O)₂CF₃ |
| A1-17 | —NMe₂ |
| A1-18 | —N(SiMe₃)₂ |
| A1-19 | —NHPh |
| A1-20 | —SPh |
| A1-21 | —OS(═O)(OH)₂ |
| A1-22 | —OS(═O)₂CH₃ |
| A1-23 | —OCOCH₃ |
| A1-24 | —OCOPh |
| A1-25 | —OP(═O)(OH)₂ |
| A1-26 | —OP(═O)(OPh)₂ |
| A1-27 | —OP(═O)Me₂ |
| A1-28 | —ONO₂ |
| A1-29 | —NCO |
| A1-30 | —OCN |
| A1-31 | —NCS |
| A1-32 | —SCN |
| A1-33 | —CN |
| A1-34 | —N₃ |
| A1-35 | 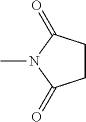 |
| A1-36 | 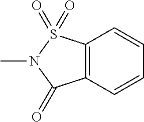 |
| A1-37 | 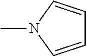 |
| A1-38 | 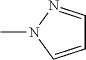 |
| A1-39 | 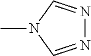 |
| A1-40 | 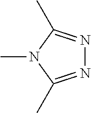 |
| A1-41 | —OH₂ |
| A1-42 | —OHMe |
| A1-43 | —OHPh |
| A1-44 | —NH₃ |
| A1-45 | —NEt₃ |
| A1-46 | —NH₂Ph |
| A1-47 | —NCMe |
| A1-48 | —O═C(CH₃)₂ |
| A1-49 | —O═S(CH₃)₂ |
| A1-50 | —SHPh |
| A1-51 | 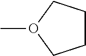 |
| A1-52 | 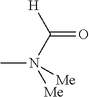 |
| A1-53 | 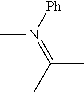 |
| A1-54 | 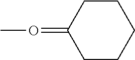 |
| A1-55 | 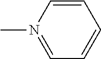 |
| A1-56 | 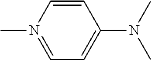 |
| A1-57 | 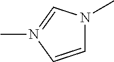 |
| A1-58 | —OCOCF₃ |

In a case where the compound (A) forming a ligand has a coordination site coordinating by an anion, the copper complex used in the invention may be a cationic complex or an anionic complex in addition to a neutral complex having no electric charge according to the number of coordination sites coordinating by an anion. In this case, in order to neutralize the electric charge of the copper complex, counter ions exist as necessary.

In a case where the counter ion is a negative counter ion, for example, the counter ion may be an inorganic anion or an organic anion. Specific examples of the counter ion include a hydroxide ion, a halogen anion (such as a fluoride ion, a chloride ion, a bromide ion, and an iodide ion), a substituted or unsubstituted alkyl carboxylate ion (an acetate ion, a trifluoroacetate ion, and the like), a substituted or unsubstituted aryl carboxylate ion (a benzoate ion and the like), a substituted or unsubstituted alkyl sulfonate ion (a methane sulfonate ion, a trifluoromethane sulfonate ion, and the like), a substituted or unsubstituted aryl sulfonate ion (such as a p-toluene sulfonate ion and a p-chlorobenzene sulfonate ion), an aryl disulfonate ion (such as a 1,3-benzene disulfonate ion, a 1,5-naphthalene disulfonate ion, and a 2,6-naphthalene disulfonate ion), an alkyl sulfate ion (such as a methyl sulfate ion), a sulfate ion, a thiocyanate ion, a nitrate ion, a perchlorate ion, a tetrafluoroborate ion, a tetraaryl borate ion, a hexafluorophosphate ion, a picrate ion, an amide ion (including amide ions substituted with an acyl group or a sulfonyl group), an imide ion (including imide ions substituted with an acyl group or a sulfonyl group), and a methide ion (including methide ions substituted with an acyl group or a sulfonyl group). A halogen anion, a substituted or unsubstituted alkyl carboxylate ion, a sulfate ion, a nitrate ion, a tetrafluoroborate ion, a tetraaryl borate ion, a hexafluorophosphate ion, an amide ion (including amide ions substituted with an acyl group or a sulfonyl group), an imide ion (including imide ions substituted with an acyl group or a sulfonyl group), and a methide ion (including methide ions substituted with an acyl group or a sulfonyl group) are preferable.

In a case where the counter ion is a positive counter ion, examples of the counter ion include an inorganic or organic ammonium ion (such as a tetraalkyl ammonium ion such as a tetrabutyl ammonium ion, a triethyl benzyl ammonium ion, and a pyridinium ion), a phosphonium ion (such as a tetraalkyl phosphonium ion such as a tetrabutyl phosphonium ion, an alkyl triphenyl phosphonium ion, and a triethyl phenyl phosphonium ion), an alkali metal ion, and a proton.

In addition, the counter ion may be a metal complex ion, and in particular, the counter ion may be a copper complex, that is, a salt of a cationic copper complex and an anionic copper complex.

Preferable examples of an aspect of the copper complex used in the invention include the following aspects (1) to (5). (2) to (5) are more preferable, (3) to (5) are even more preferable, and (4) is most preferable.

(1) A copper complex having one or two compounds having two coordination sites as a ligand

(2) A copper complex having a compound having three coordination sites as a ligand

(3) A copper complex having a compound having three coordination sites and a compound having two coordination sites as a ligand

(4) A copper complex having a compound having four coordination sites as a ligand

(5) A copper complex having a compound having five coordination sites as a ligand

In the above-described aspect (1), the compound having two coordination sites is preferably a compound having two coordination sites coordinating by an unshared electron pair, or a compound having a coordination site coordinating by an anion and a coordination site coordinating by an unshared electron pair. In a case where two compounds having two coordination sites are included as a ligand, the compounds as the ligand may be the same or different.

In addition, in the aspect (1), the copper complex may further have the above-described monodentate ligand. The number of monodentate ligands may be zero, or one to three. Regarding the type of the monodentate ligand, any one of a monodentate ligand coordinating by an anion and a monodentate ligand coordinating by an unshared electron pair is preferable. In a case where the compound having two coordination sites is a compound having two coordination sites coordinating by an unshared electron pair, a monodentate ligand coordinating by an anion is more preferable due to a strong coordination force. In a case where the compound having two coordination sites is a compound having a coordination site coordinating by an anion and a coordination site coordinating by an unshared electron pair, a monodentate ligand coordinating by an unshared electron pair is more preferable since the entire complex has no electric charge.

In the above-described aspect (2), the compound having three coordination sites is preferably a compound having a coordination site coordinating by an unshared electron pair, and more preferably a compound having three coordination sites coordinating by an unshared electron pair.

In the aspect (2), the copper complex may further have the above-described monodentate ligand. The number of monodentate ligands may be zero. In addition, the number of monodentate ligands may be one or more, more preferably one to three, even more preferably one or two, and still more preferably two. Regarding the type of the monodentate ligand, any one of a monodentate ligand coordinating by an anion and a monodentate ligand coordinating by an unshared electron pair is preferable, and a monodentate ligand coordinating by an anion is more preferable from the above-described reason.

In the above-described aspect (3), the compound having three coordination sites is preferably a compound having a coordination site coordinating by an anion and a coordination site coordinating by an unshared electron pair, and more preferably a compound having two coordination sites coordinating by an anion and one coordination site coordinating by an unshared electron pair. Furthermore, it is particularly preferable that the two coordination sites coordinating by an anion are different. In addition, the compound having two coordination sites is preferably a compound having a coordination site coordinating by an unshared electron pair, and more preferably a compound having two coordination sites coordinating by an unshared electron pair. Among these, a combination in which the compound having three coordination sites is a compound having two coordination sites coordinating by an anion and one coordination site coordinating by an unshared electron pair, and the compound having two coordination sites is a compound having two coordination sites coordinating by an unshared electron pair is particularly preferable.

In the aspect (3), the copper complex may further have the above-described monodentate ligand. The number of monodentate ligands may be zero, or one or more. The number of monodentate ligands is more preferably zero.

In the above-described aspect (4), the compound having four coordination sites is preferably a compound having a coordination site coordinating by an unshared electron pair, more preferably a compound having two or more coordination sites coordinating by an unshared electron pair, and even more preferably a compound having four coordination sites coordinating by an unshared electron pair.

In the aspect (4), the copper complex may further have the above-described monodentate ligand. The number of monodentate ligands may be zero, one or more, or two or more. The number of monodentate ligands is preferably one. Regarding the type of the monodentate ligand, any one of a monodentate ligand coordinating by an anion and a monodentate ligand coordinating by an unshared electron pair is preferable.

In the above-described aspect (5), the compound having five coordination sites is preferably a compound having a coordination site coordinating by an unshared electron pair, more preferably a compound having two or more coordination sites coordinating by an unshared electron pair, and even more preferably a compound having five coordination sites coordinating by an unshared electron pair.

In the aspect (5), the copper complex may further have the above-described monodentate ligand. The number of monodentate ligands may be zero, or one or more. The number of monodentate ligands is preferably zero.

Specific examples of the copper complex are as follows.

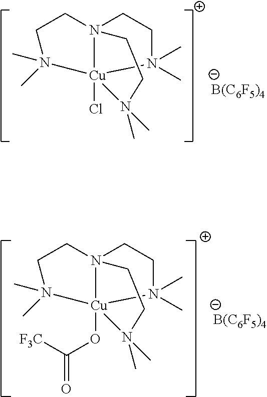

The content of the copper complex is preferably 15 mass % or greater, more preferably 20 mass % or greater, and even more preferably 25 mass % or greater with respect to the total solid content of the composition. The upper limit is preferably not greater than 80 mass %, more preferably not greater than 70 mass %, and even more preferably not greater than 50 mass %.

<<<Resin>>>

The copper complex-containing composition preferably contains a resin.

Examples of the resin include a (meth)acrylic resin, a styrene resin, an epoxy resin, an ene-thiol resin, a polycarbonate resin, a polyether resin, a polyarylate resin, a polysulfone resin, a polyethersulfone resin, a polyparaphenylene resin, a polyarylene ether phosphine oxide resin, a polyimide resin, a polyamideimide resin, a polyolefin resin, a cyclic olefin resin, and a polyester resin. One of these resins may be used alone, or two or more types may be mixed and used. The details thereof will be described in Infrared Absorbing Composition to be described later.

The weight average molecular weight (Mw) of the resin is preferably 2,000 to 2,000,000. The upper limit is preferably not greater than 1,000,000, and more preferably not greater than 500,000. The lower limit is preferably not less than 3,000, and more preferably not less than 5,000.

In a case of an epoxy resin, the weight average molecular weight (Mw) of the epoxy resin is preferably 100 or greater, and more preferably 200 to 2,000,000. The upper limit is preferably not greater than 1,000,000, and more preferably not greater than 500,000. The lower limit is preferably not less than 100, and more preferably not less than 200.

Regarding the resin, a 5% thermal mass reduction temperature raised from 25° C. at 20° C./min is preferably 200° C. or higher, and more preferably 260° C. or higher.

As the resin, a polymer having one selected from a repeating unit represented by the following (MX2-1), a repeating unit represented by the following (MX2-2), and a repeating unit represented by the following (MX2-3) can be used.

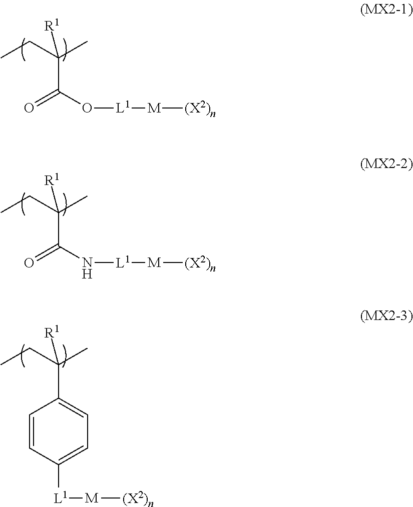

M represents an atom selected from Si, Ti, Zr, and Al. X² represents a substituent or a ligand, and at least one of n X²'s is one selected from a hydroxy group, an alkoxy group, an acyloxy group, a phosphoryloxy group, a sulfonyloxy group, an amino group, an oxime group, and O═C(R^{a})(R^{b}). X²'s may be bonded to form a ring. R¹ represents a hydrogen atom or an alkyl group. L¹ represents a single bond or a divalent linking group. n represents the number of bonds of M to X².

M is an atom selected from Si, Ti, Zr, and Al, preferably Si, Ti, or Zr, and more preferably Si.

X² represents a substituent or a ligand, and at least one of n X²'s is one selected from a hydroxy group, an alkoxy group, an acyloxy group, a phosphoryloxy group, a sulfonyloxy group, an amino group, an oxime group, and O═C(R^{a})(R^{b}). X²'s may be bonded to form a ring.

It is preferable that at least one of n X²'s is one selected from an alkoxy group, an acyloxy group, and an oxime group, it is more preferable that at least one of n X²'s is an alkoxy group, and it is even more preferable that all of X²'s are alkoxy groups. In a case where X² is O═C(R^{a})(R^{b}), it is bonded to M by an unshared electron pair of an oxygen atom of a carbonyl group (—CO—). R^{a} and R^{b} each independently represent a monovalent organic group.

The number of carbon atoms of the alkoxy group represented by X² is preferably 1 to 20, more preferably 1 to 10, even more preferably 1 to 5, and particularly preferably 1 or 2. The alkoxy group may be linear, branched, or cyclic. The alkoxy group is preferably linear or branched, and more preferably linear. The alkoxy group may be unsubstituted or may have a substituent, and is preferably unsubstituted. Examples of the substituent include a halogen atom (preferably a fluorine atom), a polymerizable group (such as a vinyl group, a (meth)acryloyl group, a styryl group, an epoxy group, and an oxetane group), an amino group, an isocyanate group, an isocyanurate group, an ureido group, a mercapto group, a sulfide group, a sulfo group, a carboxyl group, and a hydroxyl group.

Examples of the acyloxy group represented by X² include a substituted or unsubstituted alkylcarbonyloxy group having 2 to 30 carbon atoms and a substituted or unsubstituted aryloxycarbonyl group having 6 to 30 carbon atoms. Examples thereof include a formyloxy group, an acetyloxy group, a pivaloyloxy group, stearoyloxy group, a benzoyloxy group, and a p-methoxyphenylcarbonyloxy group. Examples of the substituent are as described above.

The number of carbon atoms of the oxime group represented by X² is preferably 1 to 20, more preferably 1 to 10, and even more preferably 1 to 5. Examples of the oxime group include an ethyl methyl ketoxime group.

Examples of the amino group represented by X² include an amino group, a substituted or unsubstituted alkylamino group having 1 to 30 carbon atoms, a substituted or unsubstituted arylamino group having 6 to 30 carbon atoms, and a heterocyclic amino group having 0 to 30 carbon atoms. Examples thereof include amino, methylamino, dimethylamino, anilino, N-methyl-anilino, diphenylamino, and N-1,3,5-triazine-2-ylamino. Examples of the substituent are as described above.

Examples of the monovalent organic groups represented by R^{a} and R^{b} include an alkyl group, an aryl group, and a group represented by —R¹⁰¹—COR¹⁰².

The number of carbon atoms of the alkyl group is preferably 1 to 20, and more preferably 1 to 10. The alkyl group may be linear, branched, or cyclic. The alkyl group may be unsubstituted or may have the above-described substituent.

The number of carbon atoms of the aryl group is preferably 6 to 20, and more preferably 6 to 12. The aryl group may be unsubstituted or may have the above-described substituent.

In a group represented by —R¹⁰¹—COR¹⁰², R¹⁰¹ represents an arylene group, and R¹⁰² represents an alkyl group or an aryl group.

The number of carbon atoms of the arylene group represented by R¹⁰¹ is preferably 1 to 20, and more preferably 1 to 10. The arylene group may be linear, branched, or cyclic. The arylene group may be unsubstituted or may have the above-described substituent.

Examples of the alkyl group and the aryl group represented by R¹⁰² include those in the description of R^{a} and R^{b}, and their preferable ranges are also similar.

Among substituents and ligands represented by X², as a substituent other than a hydroxy group, an alkoxy group, an acyloxy group, a phosphoryloxy group, a sulfonyloxy group, an amino group, and an oxime group, a hydrocarbon group is preferable. Examples of the hydrocarbon group include an alkyl group, an alkenyl group, and an aryl group.

The alkyl group may be linear, branched, or cyclic. The number of carbon atoms of a linear alkyl group is preferably 1 to 20, more preferably 1 to 12, and even more preferably 1 to 8. The number of carbon atoms of a branched alkyl group is preferably 3 to 20, more preferably 3 to 12, and even more preferably 3 to 8. A cyclic alkyl group may be monocyclic or polycyclic. The number of carbon atoms of a cyclic alkyl group is preferably 3 to 20, more preferably 4 to 10, and even more preferably 6 to 10.

The number of carbon atoms of the alkenyl group is preferably 2 to 10, more preferably 2 to 8, and even more preferably 2 to 4.

The number of carbon atoms of the aryl group is preferably 6 to 18, more preferably 6 to 14, and even more preferably 6 to 10.

The hydrocarbon group may have a substituent. Examples of the substituent include an alkyl group, a halogen atom (preferably a fluorine atom), a polymerizable group (such as a vinyl group, a (meth)acryloyl group, a styryl group, an epoxy group, and an oxetane group), an amino group, an isocyanate group, an isocyanurate group, an ureido group, a mercapto group, a sulfide group, a sulfo group, a carboxyl group, a hydroxyl group, and an alkoxy group.

R¹ represents a hydrogen atom or an alkyl group. The number of carbon atoms of the alkyl group is preferably 1 to 5, more preferably 1 to 3, and particularly preferably 1. The alkyl group is preferably linear or branched, and more preferably linear. Regarding the alkyl group, some or all of hydrogen atoms may be substituted with a halogen atom (preferably a fluorine atom).

L¹ represents a single bond or a divalent linking group. Examples of the divalent linking group include an alkylene group, an arylene group, —O—, —S—, —CO—, —COO—, —OCO—, —SO₂—, —NR¹⁰— (R¹⁰ represents a hydrogen atom or an alkyl group, and is preferably a hydrogen atom), and a group formed of a combination of these, and an alkylene group and a group formed of a combination of —O— with at least one of an arylene group and an alkylene group are preferable.

The number of carbon atoms of the alkylene group is preferably 1 to 30, more preferably 1 to 15, and even more preferably 1 to 10. The alkylene group may have a substituent, but is preferably unsubstituted. The alkylene group may be linear, branched, or cyclic. A cyclic alkylene group may be monocyclic or polycyclic.

The number of carbon atoms of the arylene group is preferably 6 to 18, more preferably 6 to 14, and even more preferably 6 to 10, and a phenylene group is particularly preferable.

The above-described polymer may contain other repeating units in addition to the repeating units represented by (MX2-1), (MX2-2), and (MX2-3).

Regarding constituent components of other repeating units, the description of copolymerizable components disclosed in paragraphs of 0068 to 0075 of JP2010-106268A ([0112] to [0118] of US2011/0124824A corresponding thereto) can be referred to, and the contents thereof are incorporated into this specification.

Preferable examples of other repeating units include repeating units represented by Formulae (MX3-1) to (MX3-4).

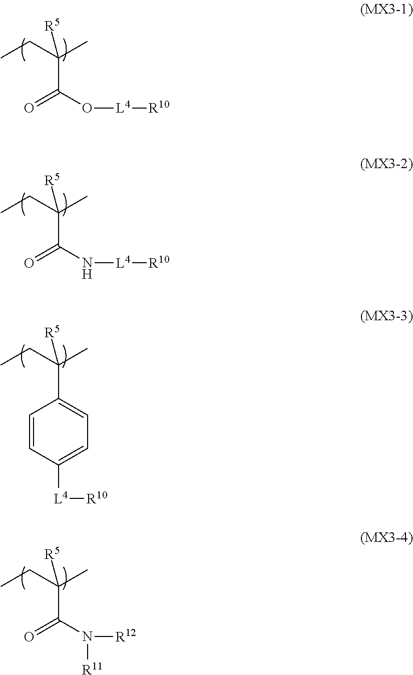

In Formulae (MX3-1) to (MX3-4), R⁵ represents a hydrogen atom or an alkyl group. L⁴ represents a single bond or a divalent linking group. R¹⁰ represents an alkyl group or an aryl group. R¹¹ and R¹² each independently represent a hydrogen atom, an alkyl group, or an aryl group.

R⁵ is synonymous with R¹ in Formulae (MX2-1) to (MX2-3), and its preferable ranges are also similar.

L⁴ is synonymous with L¹ in Formulae (MX2-1) to (MX2-3), and its preferable ranges are also similar.

The alkyl group represented by R¹⁰ may be linear, branched, or cyclic, and is preferably cyclic. The number of carbon atoms of the alkyl group is preferably 1 to 30, more preferably 1 to 20, and even more preferably 1 to 10. The alkyl group may have a substituent. Examples of the substituent are as described above.

The aryl group represented by R¹⁰ may be monocyclic or polycyclic, and is preferably monocyclic. The number of carbon atoms of the aryl group is preferably 6 to 18, more preferably 6 to 12, and even more preferably 6.

R¹⁰ is preferably a cyclic alkyl group or an aryl group.

R¹¹ and R¹² each independently represent a hydrogen atom, an alkyl group, or an aryl group. Examples of the alkyl group and examples of the aryl group include those in the description of R¹⁰. An alkyl group is preferable. The alkyl group is preferably linear. The number of carbon atoms of the alkyl group is preferably 1 to 30, more preferably 1 to 20, even more preferably 1 to 10, and still more preferably 1 to 5.

In a case where the above-described polymer contains other repeating units (preferably repeating units represented by Formulae (MX3-1) to (MX3-4)), a molar ratio of a total of repeating units represented by Formulae (MX2-1) to (MX2-3) to a total of other repeating units is preferably 95:5 to 20:80, and more preferably 90:10 to 30:70. In a case where the content of repeating units represented by Formulae (MX2-1) to (MX2-3) is increased within the above-described range, moisture resistance and solvent resistance tend to increase. In addition, in a case where the content of repeating units represented by Formulae (MX2-1) to (MX2-3) is reduced within the above-described range, heat resistance tends to increase.

Specific examples of the above-described polymer are as follows.

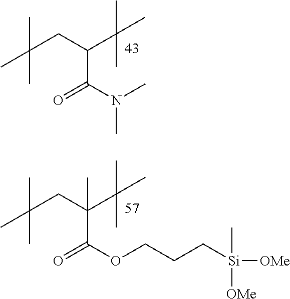

The weight average molecular weight of the above-described polymer is preferably 500 to 300,000. The lower limit is preferably not less than 1,000, and more preferably not less than 2,000. The upper limit is preferably not greater than 250,000, and more preferably not greater than 200,000.

The content of the resin is preferably 15 mass % or greater, more preferably 20 mass % or greater, and even more preferably 25 mass % or greater with respect to the total solid content of the copper complex-containing composition. The upper limit is preferably not greater than 80 mass %, more preferably not greater than 70 mass %, and even more preferably not greater than 50 mass %.

<<<Infrared Absorbing Agent>>>

The copper complex-containing composition may contain an infrared absorbing agent. Details of the infrared absorbing agent are as described in Infrared Absorbing Composition to be described later. In the invention, the infrared absorbing agent is a compound other than the above-described copper complex.

In a case where the copper complex-containing composition contains an infrared absorbing agent, the content of the infrared absorbing agent is preferably 0.01 mass % or greater, more preferably 0.05 mass % or greater, and even more preferably 0.1 mass % or greater with respect to the total solid content of the copper complex-containing composition. The upper limit is preferably not greater than 10 mass %, more preferably not greater than 5 mass %, and even more preferably not greater than 1 mass %.

In addition, 10 to 90 parts by mass of an infrared absorbing agent is preferably contained with respect to 100 parts by mass of a copper complex. The lower limit is preferably not less than 20 parts by mass, and more preferably not less than 30 parts by mass. The upper limit is preferably not greater than 70 parts by mass, and more preferably not greater than 50 parts by mass.

<<<Heat Stability Imparting Agent>>>

The copper complex-containing composition may contain an oxime compound as a heat stability imparting agent.

As the oxime compound, IRGACURE-OXE01 (manufactured by BASF SE), IRGACURE-OXE02 (manufactured by BASF SE), TR-PBG-304 (manufactured by Changzhou Tronly New Electronic Materials CO., LTD.), ADEKA ARKLS NCI-831 (manufactured by ADEKA Corporation), and ADEKA ARKLS NCI-930 (manufactured by ADEKA Corporation), and the like that are commercially available products can be used.

The content of the heat stability imparting agent is preferably 0.01 to 30 mass % with respect to the total solid content of the copper complex-containing composition. The lower limit is preferably not less than 0.1 mass %. The upper limit is preferably not greater than 20 mass %, and more preferably not greater than 10 mass %.

<<<Polymerizable Compound>>>

The copper complex-containing composition preferably contains a polymerizable compound. Details of the polymerizable compound are as described in Infrared Absorbing Composition to be described later.

The content of the polymerizable compound is preferably 15 mass % or greater, more preferably 20 mass % or greater, and even more preferably 25 mass % or greater with respect to the total solid content of the copper complex-containing composition. The upper limit is preferably not greater than 60 mass %, more preferably not greater than 50 mass %, and even more preferably not greater than 45 mass %.

<<<Photopolymerization Initiator>>>

The copper complex-containing composition preferably contains a photopolymerization initiator. Details of the photopolymerization initiator are as described in Infrared Absorbing Composition to be described later.

The content of the photopolymerization initiator is preferably 0.01 to 30 mass % with respect to the total solid content of the copper complex-containing composition. The lower limit is preferably not less than 0.1 mass %, and more preferably not less than 0.5 mass %. The upper limit is preferably not greater than 20 mass %, and more preferably not greater than 15 mass %.

<<<Gelatin>>>

The copper complex-containing composition preferably contains gelatin. Details of the gelatin are as described in Infrared Absorbing Composition to be described later.

A film having excellent heat resistance is easily formed in a case where gelatin is contained.

The content of the gelatin is preferably 1 to 99 mass % with respect to the total solid content of the copper complex-containing composition. The lower limit is preferably not less than 10 mass %, and more preferably not less than 20 mass %. The upper limit is preferably not greater than 95 mass %, and more preferably not greater than 90 mass %.

<<<Solvent>>>

The copper complex-containing composition preferably contains a solvent. Water or an organic solvent can be used as the solvent. Water and an organic solvent can be used in combination. Details of the organic solvent are as described in Infrared Absorbing Composition to be described later.

The content of the solvent is set such that the total solid content of the copper complex-containing composition is preferably 5 to 60 mass %, and more preferably 10 to 40 mass %.

<<<Catalyst>>>

The copper complex-containing composition preferably contains a catalyst. In a case where a catalyst is contained, an infrared cut filter having excellent solvent resistance and heat resistance is easily obtained. Examples of the catalyst include organic metal-based catalysts, acid-based catalysts, and amine-based catalysts, and organic metal-based catalysts are preferable. Examples of the organic metal-based catalysts include tris(2,4-pentanedionato)aluminum.

The content of the catalyst is preferably 0.01 to 5 mass % with respect to the total solid content of the copper complex-containing composition. The lower limit is preferably not less than 0.05 mass %. The upper limit is preferably not greater than 3 mass %, and more preferably not greater than 1 mass %.

<<<Other Components>>>

The copper complex-containing composition may further contain, for example, an ultraviolet absorbing agent, a dispersing agent, a sensitizer, a crosslinking agent, a curing accelerator, a filler, a thermal curing accelerator, a thermal polymerization inhibitor, a plasticizer, an adhesion promoter, and other auxiliary agents (such as conductive particles, a filler, an antifoaming agent, a flame retardant, a leveling agent, a peeling promoter, an antioxidant, a fragrance material, a surface tension adjuster, and a chain transfer agent).

Regarding these components, for example, the description in paragraph 0183 and subsequent paragraphs of JP2012-003225A ([0237] and subsequent paragraphs of US2013/0034812A corresponding thereto), paragraphs 0101 to 0104 and 0107 to 0109 of JP2008-250074A, and the like can be referred to, and the contents thereof are incorporated into this specification.

In a case where a copper complex-containing layer is used as the copper-containing transparent layer, the copper complex-containing layer may be used alone or in combination with a support. The material of the support is not particularly limited as long as it can transmit at least light of a visible wavelength region, and examples thereof include glass, crystal, and a resin. Examples of the glass include soda lime glass, borosilicate glass, alkali free glass, and silica glass. Examples of the crystal include crystal, lithium niobate, and sapphire. Examples of the resin include polyester resins such as polyethylene terephthalate and polybutylene terephthalate, polyolefin resins such as polyethylene, polypropylene, and an ethylene-vinyl acetate copolymer, norbornene resins, acrylic resins such as polyacrylate and polymethyl methacrylate, urethane resins, vinyl chloride resins, fluorine resins, polycarbonate resins, polyvinyl butyral resins, and polyvinyl alcohol resins.

In a case where a copper complex-containing layer is used in combination with a support, other layers may be interposed between the copper complex-containing layer and the support. That is, an infrared absorbing layer and a dielectric multi-layer film to be described later may be interposed between the copper complex-containing layer and the support.

In a case where a copper complex-containing layer is used in combination with a support, an infrared absorbing layer may be formed on one or both sides of the support. The outer periphery of the support may be covered with a copper complex-containing layer.

In a case where a copper complex-containing layer and a support are used in combination and these are in contact with each other, a laminate of the copper complex-containing layer and the support corresponds to the “copper-containing transparent layer” according to the invention. In a case where the copper complex-containing layer and the support are not in contact with each other and other layers are interposed between the copper complex-containing layer and the support, only the copper complex-containing layer corresponds to the “copper-containing transparent layer” according to the invention.

In a case where a copper complex-containing layer is used alone, the thickness of the copper complex-containing layer is preferably 0.05 to 1.0 mm. The lower limit is preferably not less than 0.05 mm, and more preferably not less than 0.1 mm. The upper limit is preferably not greater than 0.3 mm, and more preferably not greater than 0.2 mm.

In a case where a copper complex-containing layer is used in combination with a support, the thickness of the copper complex-containing layer is preferably 0.1 to 1.0 mm. The lower limit is preferably not less than 0.1 mm, and more preferably not less than 0.15 mm. The upper limit is preferably not greater than 0.3 mm, and more preferably not greater than 0.2 mm.

<<Infrared Absorbing Layer>>

The infrared cut filter according to the invention preferably has a layer containing an infrared absorbing agent (hereinafter, also referred to as the infrared absorbing layer). In the invention, the infrared absorbing agent is a compound other than the copper complex described in Copper Complex-Containing Layer.

The infrared absorbing layer may be formed on one or both sides of the copper-containing transparent layer. From the viewpoint of warping suppression, the infrared absorbing layer is preferably formed on both sides of the copper-containing transparent layer. In addition, the infrared absorbing layer may be or may not be in contact with the copper-containing transparent layer. That is, the infrared absorbing layer may be formed on a surface of the copper-containing transparent layer, or other layers (dielectric multi-layer film and the like to be described later) may be interposed between the infrared absorbing layer and the copper-containing transparent layer.

In a case where the copper-containing transparent layer further contains an infrared absorbing agent as described above, the infrared cut filter according to the invention may have an infrared absorbing layer, or the infrared absorbing layer may be omitted. That is, in the invention, the layer containing copper and an infrared absorbing agent corresponds to the “copper-containing transparent layer”.

In a case where the copper-containing transparent layer contains no infrared absorbing agent, the infrared cut filter according to the invention has an infrared absorbing layer in addition to the copper-containing transparent layer.

In the invention, the infrared absorbing layer preferably has a maximum absorption wavelength in a wavelength region of 600 nm or greater, and more preferably has a maximum absorption wavelength in a wavelength region of 700 to 900 nm.

In the infrared absorbing layer, the transmittance of light with a wavelength of 700 nm measured in a direction perpendicular to the infrared absorbing layer is preferably 10% or less, more preferably 5% or less, and even more preferably 1% or less. The transmittance of light with a wavelength of 800 nm measured in a direction perpendicular to the infrared absorbing layer is preferably 10% or less, more preferably 5% or less, and even more preferably 1% or less.

A ratio B/A of, to absorbance A at the maximum absorption wavelength before the infrared absorbing layer is dipped in at least one organic solvent selected from propylene glycol monomethyl ether, propylene glycol monomethyl ether acetate, methyl 3-methoxypropionate, ethyl lactate, acetone, and ethanol, absorbance B at the wavelength at which the absorbance A is measured after the infrared absorbing layer is dipped in the organic solvent for 2 minutes at 25° C. is preferably 0.9 or greater.

The absorbance ratio B/A is preferably a value with respect to two or more organic solvents selected from propylene glycol monomethyl ether, propylene glycol monomethyl ether acetate, methyl 3-methoxypropionate, ethyl lactate, acetone, and ethanol, and particularly preferably a value with respect to each of organic solvents, propylene glycol monomethyl ether, propylene glycol monomethyl ether acetate, methyl 3-methoxypropionate, ethyl lactate, acetone, and ethanol.

The absorbance ratio B/A is more preferably 0.9 to 1.0, and even more preferably 0.95 to 1.0.

The content of the infrared absorbing agent is preferably 1 to 80 mass % with respect to the mass of the infrared absorbing layer. The lower limit is preferably not less than 5 mass %, and more preferably not less than 10 mass %. The upper limit is preferably not greater than 60 mass %, and more preferably not greater than 50 mass %.

The infrared absorbing layer can be formed using an infrared absorbing composition containing an infrared absorbing agent. Hereinafter, the infrared absorbing composition will be described.

<<<Infrared absorbing Composition>>>

<<<<Infrared Absorbing Agent>>>>

In the invention, the infrared absorbing agent means a compound having absorption in a near-infrared wavelength region (preferably wavelength 650 to 1,300 nm).

The infrared absorbing agent is preferably a compound having a maximum absorption wavelength in a wavelength region of 675 to 900 nm.

In the invention, the infrared absorbing agent is preferably an organic coloring agent. In the invention, the organic coloring agent means a coloring agent formed of an organic compound.

In addition, the infrared absorbing agent is preferably at least one selected from a cyanine compound, a pyrrolopyrrole compound, a squarylium compound, a phthalocyanine compound, and a naphthalocyanine compound.

In addition, in the invention, the infrared absorbing agent is preferably a compound that is dissolved in an amount of 1 mass % or greater in water at 25° C., and more preferably a compound that is dissolved in an amount of 10 mass % or greater in water at 25° C. Using such a compound, solvent resistance is improved.

In the invention, the infrared absorbing agent is preferably at least one selected from compounds represented by Formulae 1 to 3.

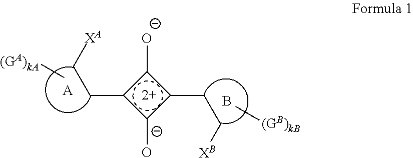

In Formula 1, a ring A and a ring B each independently represent an aromatic ring.

X^{A} and X^{B} each independently represent a substituent.

G^{A} and G^{B} each independently represent a substituent.

kA represents an integer of 0 to nA, and kB represents an integer of 0 to nB.

nA represents a maximum integer in which substitution with the ring A is possible, and nB represents a maximum integer in which substitution with the ring B is possible.

Each of X^{A} and G^{A}, and X^{B} and G^{B} may be bonded to form a ring. In a case where there are plural G^{A}'s and G^{B}'s, each of G^{A}'s and G^{B}'s may be bonded to form a ring.

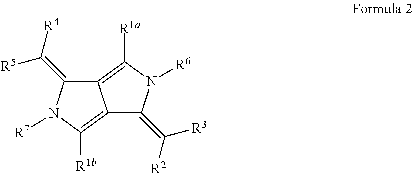

In Formula 2, R^{1a} and R^{1b} each independently represent an alkyl group, an aryl group, or a heteroaryl group.

R² to R⁵ each independently represent a hydrogen atom or a substituent. Each of R² and R³, and R⁴ and R⁵ may be bonded to form a ring.

R⁶ and R⁷ each independently represent a hydrogen atom, an alkyl group, an aryl group, a heteroaryl group, —BR^{A}R^{B}, or a metal atom. R^{A} and R^{B} each independently represent a hydrogen atom or a substituent.

R⁶ may be bonded to R^{1a} or R³ by a covalent bond or a coordination bond. R⁷ may be bonded to R^{1b} or R⁵ by a covalent bond or a coordination bond.

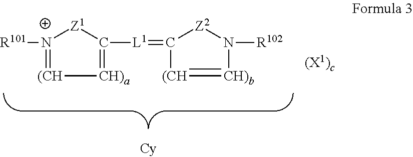

In Formula 3, Z¹ and Z² each independently represent a non-metallic atomic group necessary for forming a five-membered or six-membered nitrogen-containing heterocyclic ring that may be condensed.

R¹⁰¹ and R¹⁰² each independently represent an alkyl group, an alkenyl group, alkynyl group, an aralkyl group, or an aryl group.

L¹ represents a methine chain composed of an odd number of methines.

a and b each independently represent 0 or 1.

In a case where a is 0, a carbon atom and a nitrogen atom are bonded by a double bond, and in a case where b is 0, a carbon atom and a nitrogen atom are bonded by a single bond.

In a case where a site represented by Cy in the formula is a cationic portion, X¹ represents an anion, and c represents the number necessary for keeping a balance of electric charges. In a case where a site represented by Cy in the formula is an anionic portion, X¹ represents a cation, and c represents the number necessary for keeping a balance of electric charges. In a case where the electric charge of a site represented by Cy in the formula is neutralized in the molecule, c is zero.

<<<<Compound Represented by Formula 1 (Squarylium Compound)>>>>

In Formula 1, G^{A} and G^{B} each independently represent a substituent.

Examples of the substituent include a halogen atom, a cyano group, a nitro group, an alkyl group, an alkenyl group, an alkynyl group, an aryl group, a heteroaryl group, an aralkyl group, an alkoxy group, an aryloxy group, a heteroaryloxy group, an alkylthio group, an arylthio group, a heteroarylthio group, —NR^{a1}R^{a2}, —COR^{a3}, —COOR^{a4}, —OCOR^{a5}, —NHCOR^{a6}, —CONR^{a7}R^{a8}, —NHCONR^{a9}R^{a10}, —NHCOOR^{a11}, —SO₂R^{a12}, —SO₂OR^{a13}, —NHSO₂R^{a14}, and —SO₂NR^{a15}R^{a16}. R^{a1} to R^{a16} each independently represent a hydrogen atom, an alkyl group, an alkenyl group, an alkynyl group, an aryl group, or a heteroaryl group.

Examples of the halogen atom include a fluorine atom, a chlorine atom, a bromine atom, and an iodine atom.

The number of carbon atoms of each of the alkyl group, the alkoxy group, and the alkylthio group is preferably 1 to 20, more preferably 1 to 15, and even more preferably 1 to 8. The alkyl group may be linear, branched, or cyclic, and is preferably linear or branched.

The number of carbon atoms of the alkenyl group is preferably 2 to 20, more preferably 2 to 12, and particularly preferably 2 to 8. The alkenyl group may be linear, branched, or cyclic, and is preferably linear or branched.

The number of carbon atoms of the alkynyl group is preferably 2 to 40, more preferably 2 to 30, and particularly preferably 2 to 25. The alkynyl group may be linear, branched, or cyclic, and is preferably linear or branched.

The number of carbon atoms of the aryl group is preferably 6 to 30, more preferably 6 to 20, and even more preferably 6 to 12.

Examples of the aryl group of the aryloxy group and the arylthio group are as described above, and its preferable ranges are also similar.

The alkyl portion of the aralkyl group is the same as the alkyl group. The aryl portion of the aralkyl group is the same as the aryl group. The number of carbon atoms of the aralkyl group is preferably 7 to 40, more preferably 7 to 30, and even more preferably 7 to 25.

The heteroaryl group is preferably monocyclic or fused, more preferably monocyclic or fused with a fused number of 2 to 8, and even more preferably monocyclic or fused with a fused number of 2 to 4. The number of hetero atoms constituting the ring of the heteroaryl group is preferably 1 to 3. As the hetero atom constituting the ring of the heteroaryl group, a nitrogen atom, an oxygen atom, or a sulfur atom is preferable. The heteroaryl group is preferably a five-membered ring or a six-membered ring. The number of carbon atoms constituting the ring of the heteroaryl group is preferably 3 to 30, more preferably 3 to 18, and even more preferably 3 to 12.

Examples of the heteroaryl group of the heteroaryloxy group and the hetero arylthio group are as described above, and its preferable ranges are also similar.

In Formula 1, X^{A} and X^{B} each independently represent a substituent. The substituent is preferably a group having active hydrogen, more preferably —OH, —SH, —COOH, —SO₃H, —NR^{G1}R^{G2}, —NHCOR^{G1}, —CONR^{G1}R^{G2}, —NHCONR^{G1}R^{G2}, —NHCOOR^{G1}, —NHSO₂R^{G1}, —B(OH)₂, or —PO(OH)₂, even more preferably —OH, —SH, or —NR^{G1}R^{G2}, and particularly preferably —NR^{G1}R^{G2}

R^{G1} and R^{G2} each independently represent a hydrogen atom or a substituent. Examples of the substituent include an alkyl group, an alkenyl group, an alkynyl group, an aryl group, and a heteroaryl group. Details of the alkyl group, the alkenyl group, the alkynyl group, the aryl group, and the heteroaryl group are synonymous with the ranges in the description of G^{A} and G^{B}.

In Formula 1, the ring A and the ring B each independently represent an aromatic ring.

The aromatic ring may be monocyclic or fused. The aromatic ring may be an aromatic hydrocarbon ring or an aromatic heterocyclic ring.

Specific examples of the aromatic ring include a benzene ring, a naphthalene ring, a pentalene ring, an indene ring, an azulene ring, a heptalene ring, an indecene ring, a perylene ring, a pentacene ring, an acenaphthene ring, a phenanthrene ring, an anthracene ring, a naphthacene ring, a chrysene ring, a triphenylene ring, a fluorene ring, a biphenyl ring, a pyrrole ring, a furan ring, a thiophene ring, an imidazole ring, an oxazole ring, a thiazole ring, a pyridine ring, a pyrazine ring, a pyrimidine ring, a pyridazine ring, an indolizine ring, an indole ring, a benzofuran ring, a benzothiophene ring, an isobenzofuran ring, a quinolidine ring, a quinoline ring, a phthalazine ring, a naphthylidine ring, a quinoxaline ring, a quinoxazoline ring, an isoquinoline ring, a carbazole ring, a phenanthridine ring, an acridine ring, a phenanthroline ring, a thianthrene ring, a chromene ring, a xanthene ring, a phenoxathiine ring, a phenothiazine ring, and a phenazine ring. A benzene ring or a naphthalene ring is preferable, and a naphthalene ring is more preferable.

The aromatic ring may be unsubstituted or may have a substituent. Examples of the substituent include the substituents in the description of G^{A} and G^{B}.

In Formula 1, each of X^{A} and G^{A}, and X^{B} and G^{B} may be bonded to form a ring. In a case where there are plural G^{A}'s and G^{B}'s, each of G^{A}'s and G^{B}'s may be bonded to form a ring.

The ring is preferably a five-membered ring or a six-membered ring. The ring may be monocyclic or polycyclic.

In a case where X^{A} and G^{A}, X^{B} and G^{B}, G^{A}'S, or G^{B}'s are bonded to form a ring, these may be directly bonded to form a ring, or may be bonded via a divalent linking group selected from the group consisting of an alkylene group, —CO—, —O—, —NH—, —BR—, and combinations thereof to form a ring. X^{A} and G^{A}, X^{B} and G^{B}, G^{A}'s, or G^{B}'s are preferably bonded via —BR— to form a ring.

R represents a hydrogen atom or a substituent.

In Formula 1, kA represents an integer of 0 to nA, kB represents an integer of 0 to nB, nA represents a maximum integer in which substitution with the ring A is possible, and nB represents a maximum integer in which substitution with the ring B is possible.

kA and kB each independently are preferably 0 to 4, more preferably 0 to 2, and even more preferably 0 or 1.

The compound represented by Formula 1 is preferably a compound represented by Formula 1-1. This compound has excellent heat resistance.

### Formula 1-1

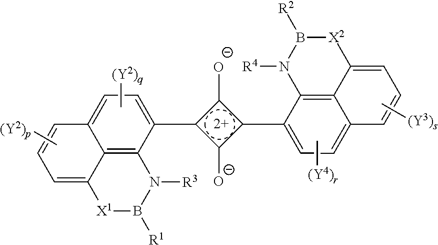

In the formula, R¹ and R² each independently represent an alkyl group, an alkenyl group, an aryl group, a heteroaryl group, or a group represented by Formula (W).

R³ and R⁴ each independently represent a hydrogen atom or an alkyl group.

X¹ and X² each independently represent an oxygen atom or —N(R⁵)—.

R⁵ represents a hydrogen atom, an alkyl group, an aryl group, or a heteroaryl group.

Y¹ to Y⁴ each independently represent a substituent. Each of Y¹ and Y², and Y³ and Y⁴ may be bonded to form a ring.

In a case where there are plural Y¹'s, Y²'s, Y³'s, and Y⁴'s, each of Y¹'s, Y²'s, Y³'s, and Y⁴'s may be bonded to form a ring.

p and s each independently represent an integer of 0 to 3.

q and r each independently represent an integer of 0 to 2.

—S¹-L¹-T¹ (W)

In Formula (W), S¹ represents a single bond, an arylene group, or a heteroarylene group.

L¹ represents an alkylene group, an alkenylene group, an alkynylene group, —O—, —S—, —NR^{L1}—, —CO—, —COO—, —OCO—, —CONR^{L1}—, —NR^{L1}CO—, —SO₂—, —OR^{L2}—, or a group composed of a combination thereof. R^{L1} represents a hydrogen atom or an alkyl group. R^{L2} represents an alkylene group.

T¹ represents an alkyl group, a cyano group, a hydroxy group, a formyl group, a carboxyl group, an amino group, a thiol group, a sulfo group, a phosphoryl group, a boryl group, a vinyl group, an ethynyl group, an aryl group, a heteroaryl group, a trialkylsilyl group, or a trialkoxysilyl group.

In Formula 1-1, R¹ and R² each independently represent an alkyl group, an alkenyl group, an aryl group, a heteroaryl group, or a group represented by Formula (W). At least one of R¹ or R² preferably represents a group represented by Formula (W).

In Formula 1-1, R¹ and R² may be the same or may be different groups. It is more preferable that R¹ and R² are the same groups.

In this specification, the aryl group means an aromatic hydrocarbon group, and the heteroaryl group means an aromatic heterocyclic group.

The number of carbon atoms of the alkyl group represented by R¹ and R² is preferably 1 to 40. The lower limit is more preferably not less than 3, even more preferably not less than 5, still more preferably not less than 10, and particularly preferably not less than 13. The upper limit is more preferably not greater than 35, and even more preferably not greater than 30. The alkyl group may be linear, branched, or cyclic. The alkyl group is preferably linear or branched, and particularly preferably branched. The number of branches of a branched alkyl group is, for example, preferably 2 to 10, and more preferably 2 to 8. Satisfactory solvent solubility is obtained in a case where the number of branches is within the above-described range.

The number of carbon atoms of the alkenyl group represented by R¹ and R² is preferably 2 to 40. The lower limit is, for example, more preferably not less than 3, even more preferably not less than 5, still more preferably not less than 8, and particularly preferably not less than 10. The upper limit is more preferably not greater than 35, and even more preferably not greater than 30. The alkenyl group is preferably linear or branched, and particularly preferably branched. The number of branches of a branched alkenyl group is preferably 2 to 10, and more preferably 2 to 8. Satisfactory solvent solubility is obtained in a case where the number of branches is within the above-described range.

The number of carbon atoms of the aryl group represented by R¹ and R² is preferably 6 to 30, more preferably 6 to 20, and even more preferably 6 to 12.

The heteroaryl group represented by R¹ and R² may be monocyclic or polycyclic. The number of hetero atoms constituting the ring of the heteroaryl group is preferably 1 to 3. As the hetero atom constituting the ring of the heteroaryl group, a nitrogen atom, an oxygen atom, or a sulfur atom is preferable. The number of carbon atoms constituting the ring of the heteroaryl group is preferably 3 to 30, more preferably 3 to 18, and even more preferably 3 to 12.

(Group Represented by Formula (W))

Next, the group represented by Formula (W) will be described.

In Formula (W), S¹ represents a single bond, an arylene group, or a heteroarylene group. From the viewpoint of stability of bonding to a boron atom, an arylene group or a heteroarylene group is preferable, and an arylene group is more preferable.

The arylene group may be monocyclic or polycyclic, and is preferably monocyclic. The number of carbon atoms of the arylene group is preferably 6 to 20, and more preferably 6 to 12.

The heteroaryl group may be monocyclic or polycyclic, and is preferably monocyclic. The number of hetero atoms constituting the ring of the heteroaryl group is preferably 1 to 3. As the hetero atom constituting the ring of the heteroaryl group, a nitrogen atom, an oxygen atom, a sulfur atom, or a selenium atom is preferable. The number of carbon atoms constituting the ring of the heteroaryl group is preferably 3 to 30, more preferably 3 to 18, and even more preferably 3 to 12.

Specific examples of the arylene group or the heteroarylene group represented by S¹ include the following structures.

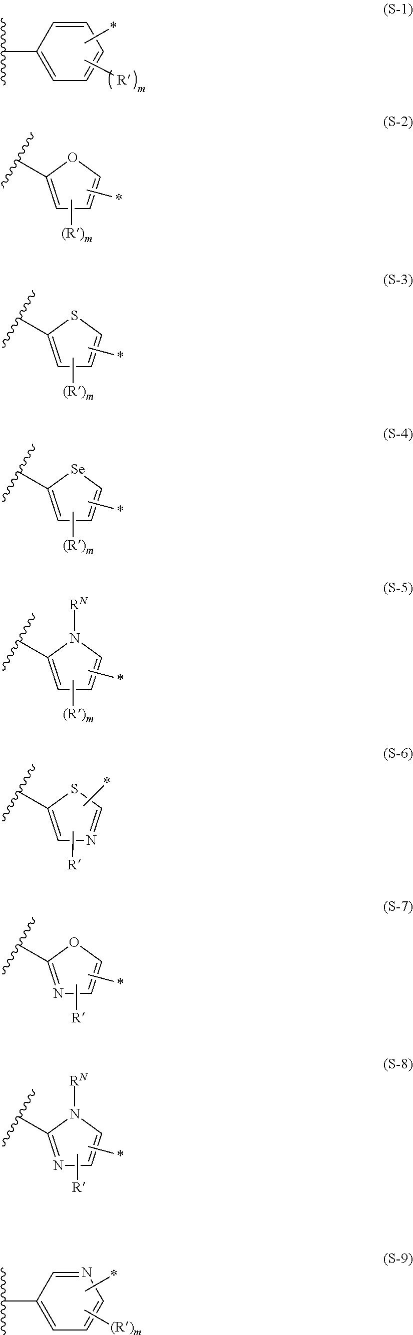

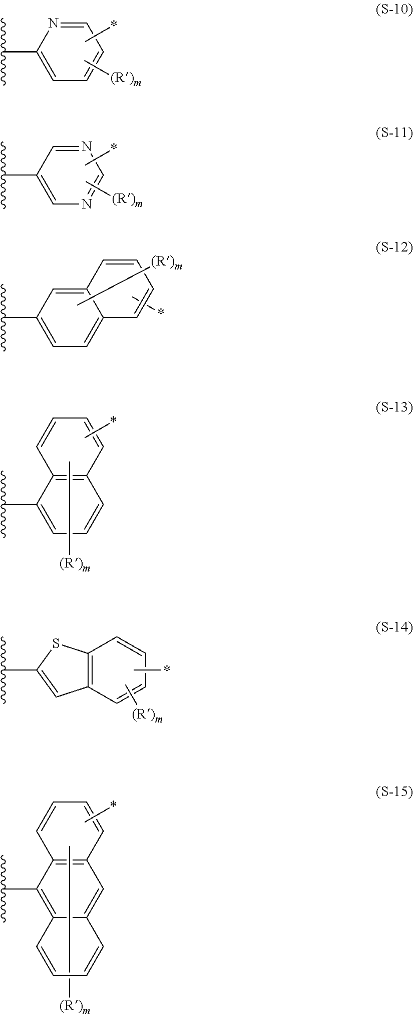

In the formulae, a wavy line portion represents a bonding position of Formula 1-1 to a boron atom. * represents a bonding position to L¹. R′ represents a substituent. R^{N} represents a hydrogen atom or an alkyl group. m represents an integer of 0 or more.

Examples of the substituent represented by R′ include the substituents in the description of G^{A} and G^{B} in Formula 1.

The number of carbon atoms of the alkyl group represented by R^{N} is preferably 1 to 20, more preferably 1 to 10, even more preferably 1 to 4, and particularly preferably 1 or 2. The alkyl group may be linear or branched.

m represents an integer of 0 or more. The upper limit of m is the maximum number of substitutions of each group. m is preferably 0.

In Formula (W), L¹ represents an alkylene group, an alkenylene group, an alkynylene group, —O—, —S—, —NR^{L1}—, —CO—, —COO—, —OCO—, —CONR^{L1}—, —NR^{L1}CO—, —SO₂—, —OR^{L2}—, or a group composed of a combination thereof. R^{L1} represents a hydrogen atom or an alkyl group, and R^{L2} represents an alkylene group.

In Formula (W), L¹ is preferably an alkylene group, an alkenylene group, an alkynylene group, —O—, —S—, —NR^{L1}—, —COO—, —OCO—, —CONR^{L1}—, —SO₂—, —OR^{L2}—, or a group composed of a combination thereof. From the viewpoint of flexibility and solvent solubility, L is more preferably an alkylene group, an alkenylene group, —O—, —OR^{L2}—, or a group composed of a combination thereof, even more preferably an alkylene group, an alkenylene group, —O—, or —OR^{L2}—, and particularly preferably an alkylene group, —O—, or —OR^{L2}—.

The number of carbon atoms of the alkylene group represented by L¹ is preferably 1 to 40. The lower limit is more preferably not less than 3, even more preferably not less than 5, still more preferably not less than 10, and particularly preferably not less than 13. The upper limit is more preferably not greater than 35, and even more preferably not greater than 30. The alkylene group may be linear, branched, or cyclic. The alkylene group is preferably linear or branched, and particularly preferably branched. The number of branches of a branched alkylene group is, for example, preferably 2 to 10, and more preferably 2 to 8. Satisfactory solvent solubility is obtained in a case where the number of branches is within the above-described range.

The number of carbon atoms of the alkenylene group or the alkynylene group represented by L¹ is preferably 2 to 40. The lower limit is, for example, more preferably not less than 3, even more preferably not less than 5, still more preferably not less than 8, and particularly preferably not less than 10. The upper limit is more preferably not greater than 35, and even more preferably not greater than 30. The alkenylene group and the alkynylene group may be linear or branched. The alkenylene group and the alkynylene group are preferably linear or branched, and particularly preferably branched. The number of branches of a branched alkenylene group or alkynylene group is preferably 2 to 10, and more preferably 2 to 8. Satisfactory solvent solubility is obtained in a case where the number of branches is within the above-described range.

R^{L1} represents a hydrogen atom or an alkyl group, and is preferably a hydrogen atom. The number of carbon atoms of the alkyl group is preferably 1 to 20, more preferably 1 to 10, even more preferably 1 to 4, and particularly preferably 1 or 2. The alkyl group may be linear or branched.

R^{L2} represents an alkylene group. The alkylene group represented by R^{L2} is synonymous with the alkylene group in the description of L¹, and its preferable ranges are also similar.

In Formula (W), T¹ represents an alkyl group, a cyano group, a hydroxy group, a formyl group, a carboxyl group, an amino group, a thiol group, a sulfo group, a phosphoryl group, a boryl group, a vinyl group, an ethynyl group, an aryl group, a heteroaryl group, a trialkylsilyl group, or a trialkoxysilyl group.

The number of carbon atoms of the alkyl group, the alkyl group of the trialkylsilyl group, and the alkyl group of the trialkoxysilyl group is preferably 1 to 40. The lower limit is more preferably not less than 3, even more preferably not less than 5, still more preferably not less than 10, and particularly preferably not less than 13. The upper limit is more preferably not greater than 35, and even more preferably not greater than 30. The alkyl group may be linear, branched, or cyclic, and is preferably linear or branched.

The aryl group and the heteroaryl group are synonymous with the aryl group and the heteroaryl group in the description of R¹ and R², and their preferable ranges are also similar.

In Formula (W), in a case where S¹ is a single bond, L¹ is an alkylene group, and T¹ is an alkyl group, the total number of carbon atoms included in L¹ and T¹ is preferably not less than 13, and from the viewpoint of solvent solubility, more preferably not less than 21. The upper limit is, for example, preferably not greater than 40, and more preferably not greater than 35.

In a case where S¹ is an arylene group, the total number of carbon atoms included in L¹ and T¹ is preferably not less than 5. From the viewpoint of solvent solubility, the total number of carbon atoms included in L¹ and T¹ is preferably not less than 9, and more preferably not less than 10. The upper limit is, for example, preferably not greater than 40, and more preferably not greater than 35.

A preferable aspect of Formula (W) is a combination in which S¹ is an arylene group or a heteroarylene group, L¹ is an alkylene group, an alkenylene group, an alkynylene group, —O—, —S—, —NR^{L1}—, —COO—, —OCO—, —CONR^{L1}—, —SO₂—, —OR^{L2}—, or a group composed of a combination thereof, and T¹ is an alkyl group or a trialkylsilyl group. S¹ is more preferably an arylene group. L¹ is more preferably an alkylene group, an alkenylene group, —O—, —OR^{L2}—, or a group composed of a combination thereof, even more preferably an alkylene group, an alkenylene group, —O—, or —OR^{L2}—, and particularly preferably an alkylene group, —O— or —OR^{L2}—. T is more preferably an alkyl group.

In Formula (W), the -L¹-T¹ portion preferably includes a branched alkyl structure. Specifically, the -L¹-T¹ portion is particularly preferably a branched alkyl group or a branched alkoxy group. The number of branches of the -L¹-T¹ portion is preferably 2 to 10, and more preferably 2 to 8. The number of carbon atoms of the -L¹-T¹ portion is preferably not less than 5, more preferably not less than 9, and even more preferably not less than 10. The upper limit is, for example, preferably not greater than 40, and more preferably not greater than 35.

In Formula (W), the -L¹-T¹ portion preferably includes asymmetric carbon. According to this aspect, a compound represented by Formula 1-1 may include a plurality of optical isomers, and as a result, the solvent solubility of the compound can be further improved. The number of asymmetric carbon atoms is preferably not less than 1. The upper limit of the number of asymmetric carbon atoms is not particularly limited, but preferably not greater than 4.

Specific examples of the group represented by Formula (W) are as follows. In the following formulae, A is a connecting portion of Formula (1) to a boron atom. In the following structural formulae, * represents asymmetric carbon, and a wave-like bond represents a racemic body.

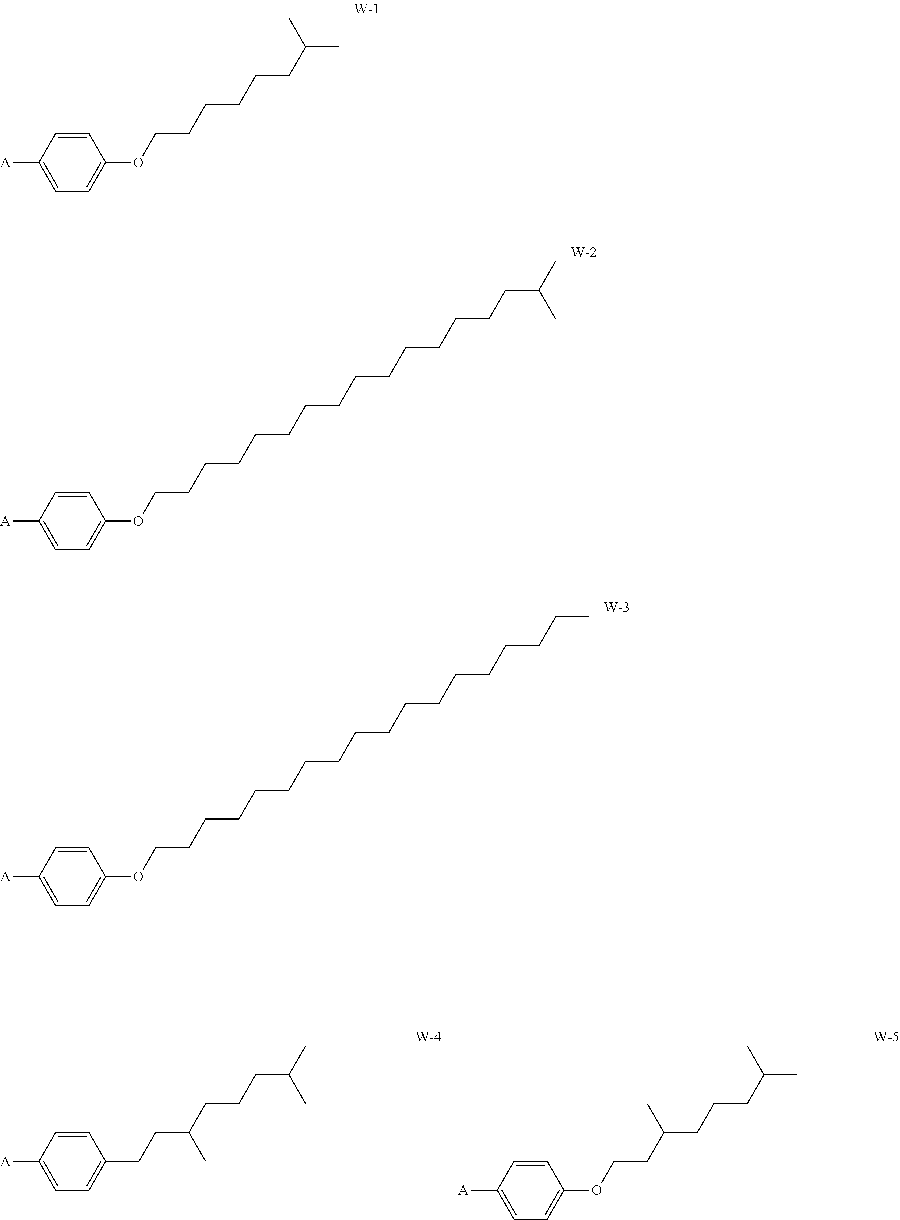

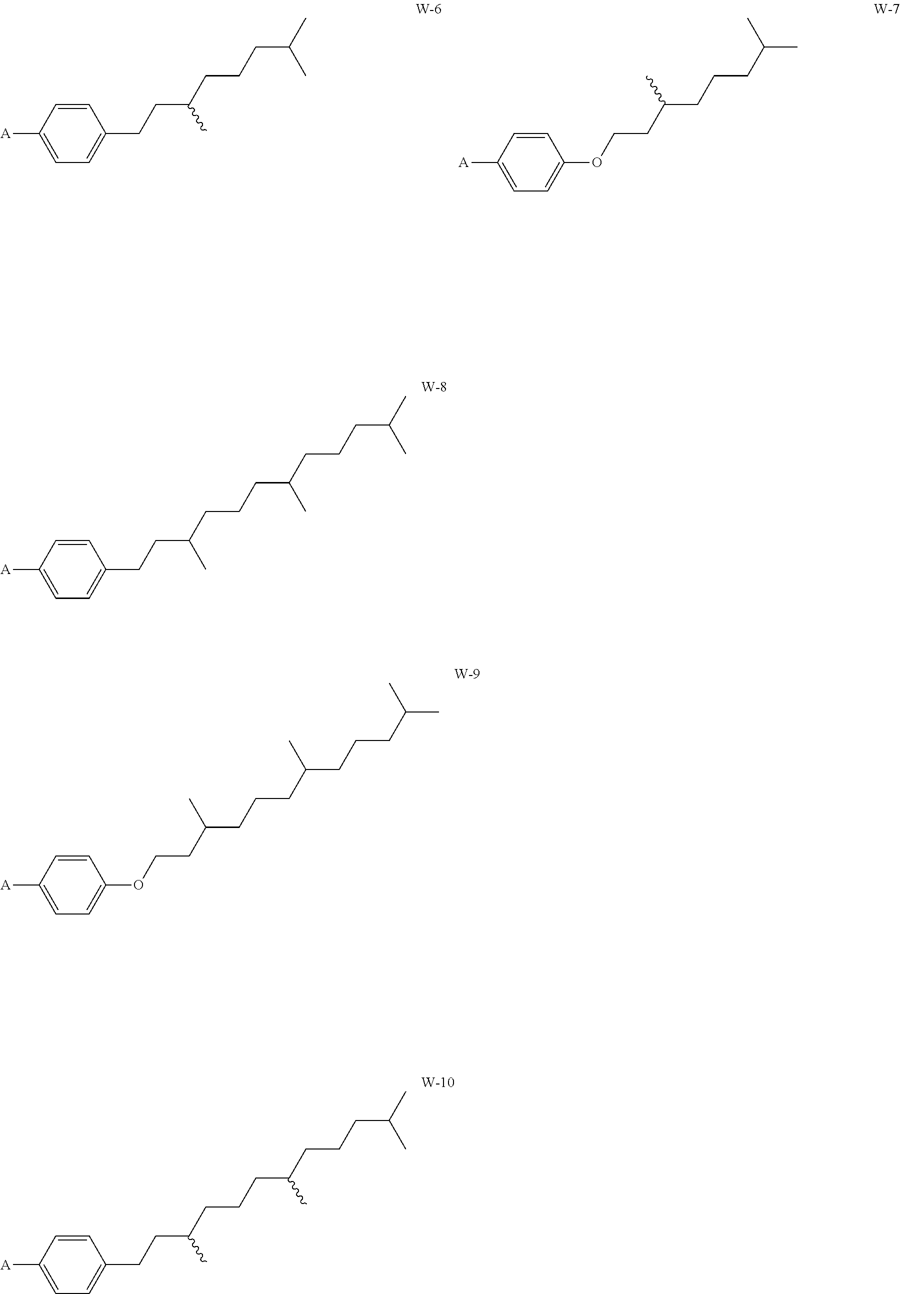

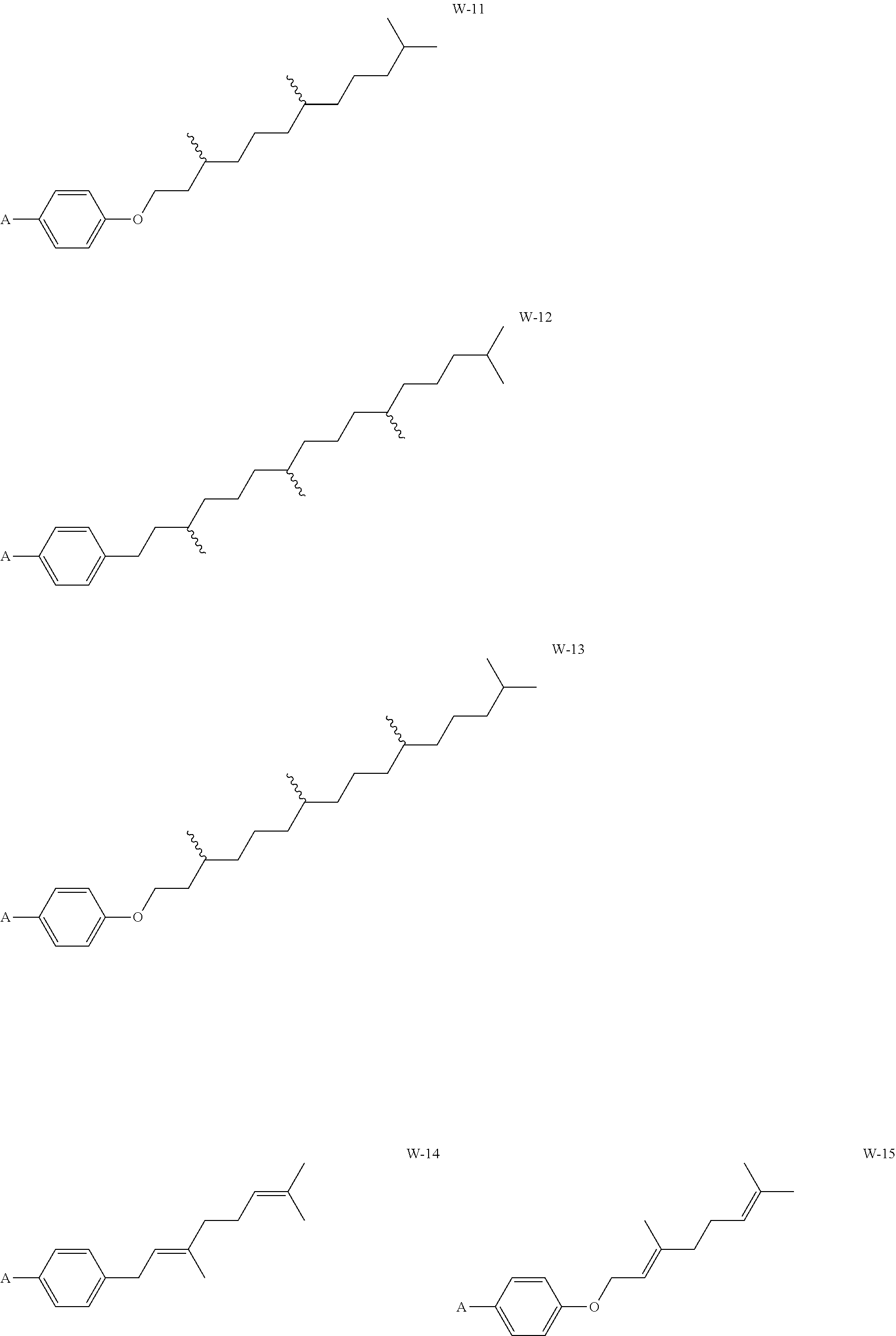

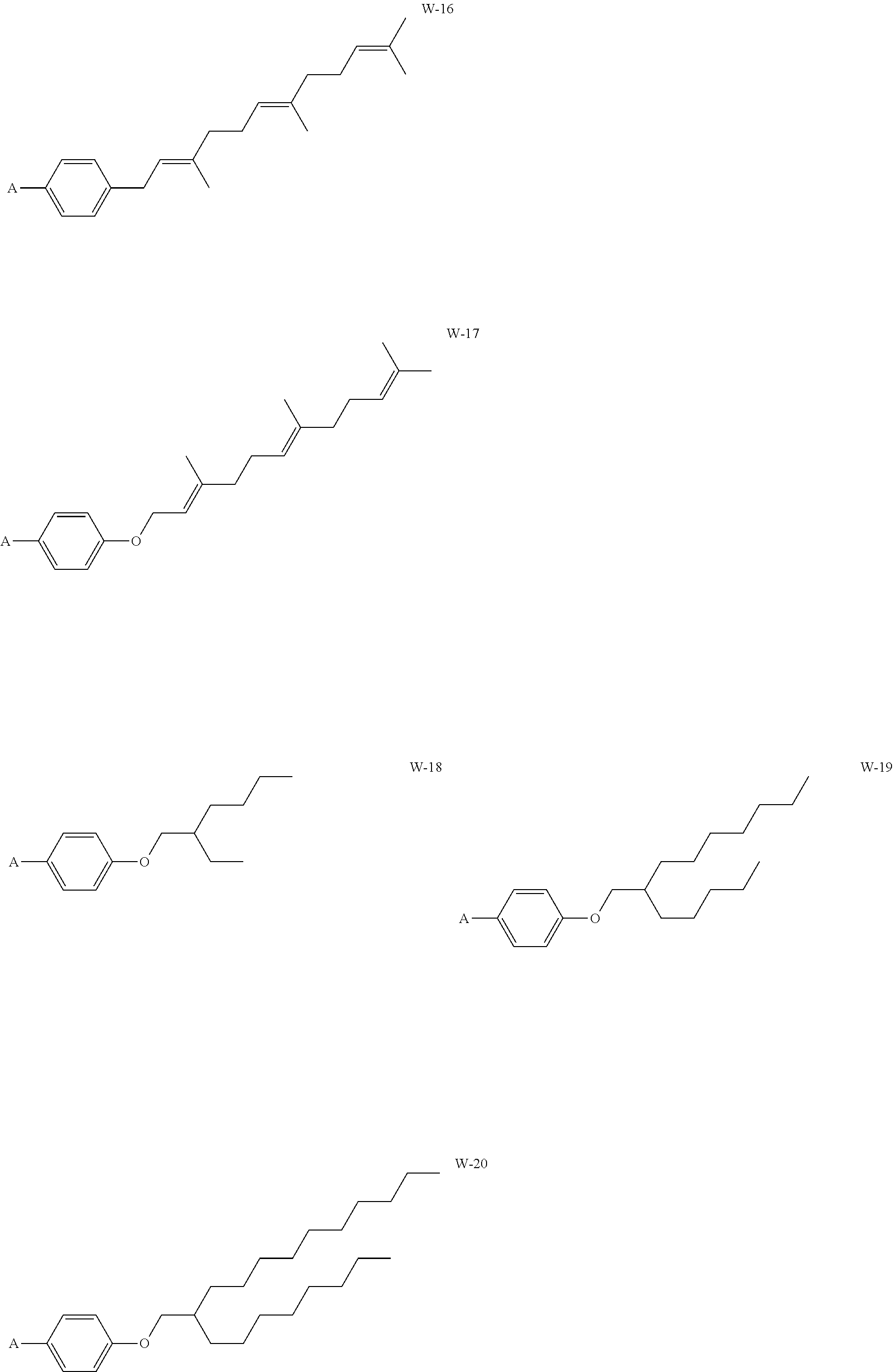

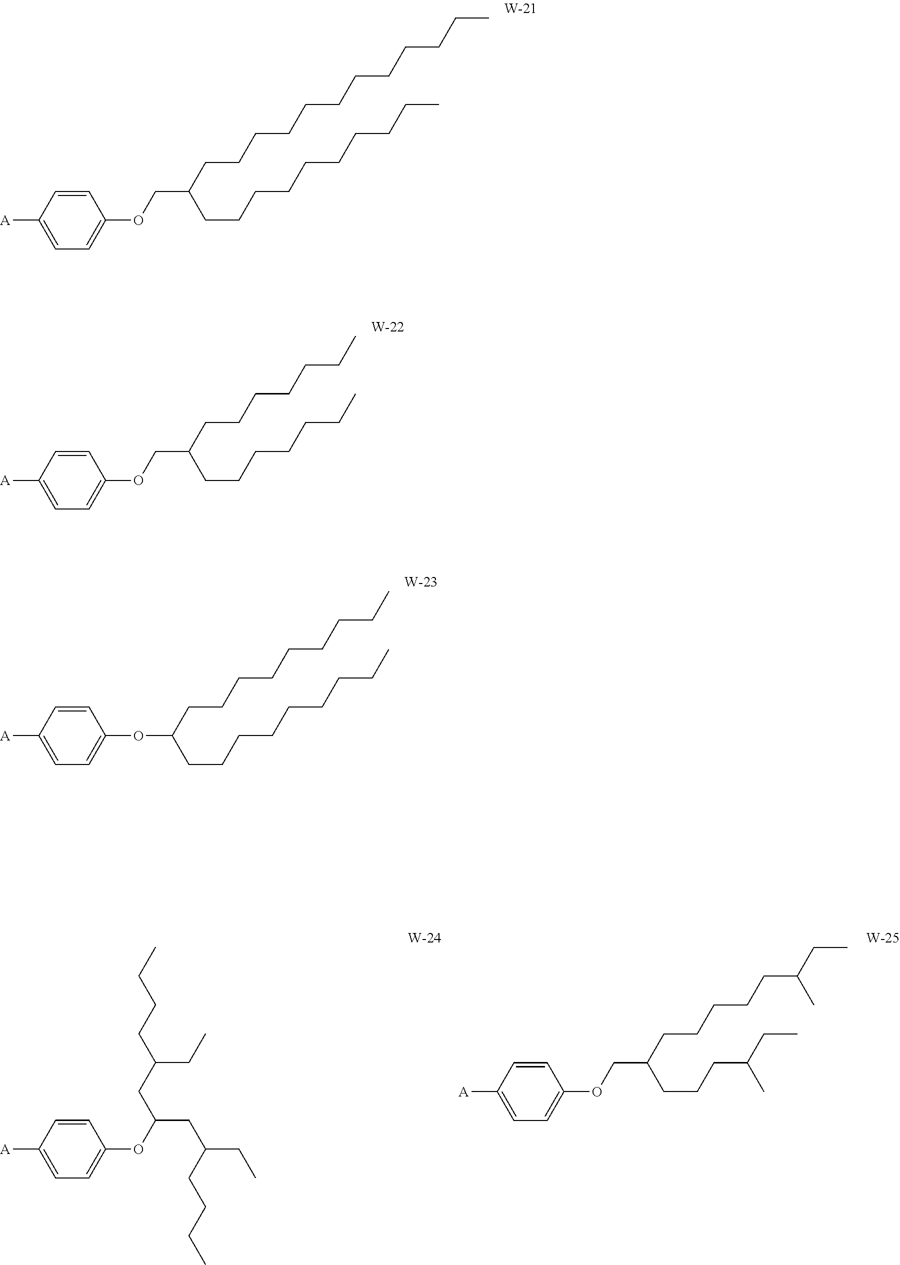

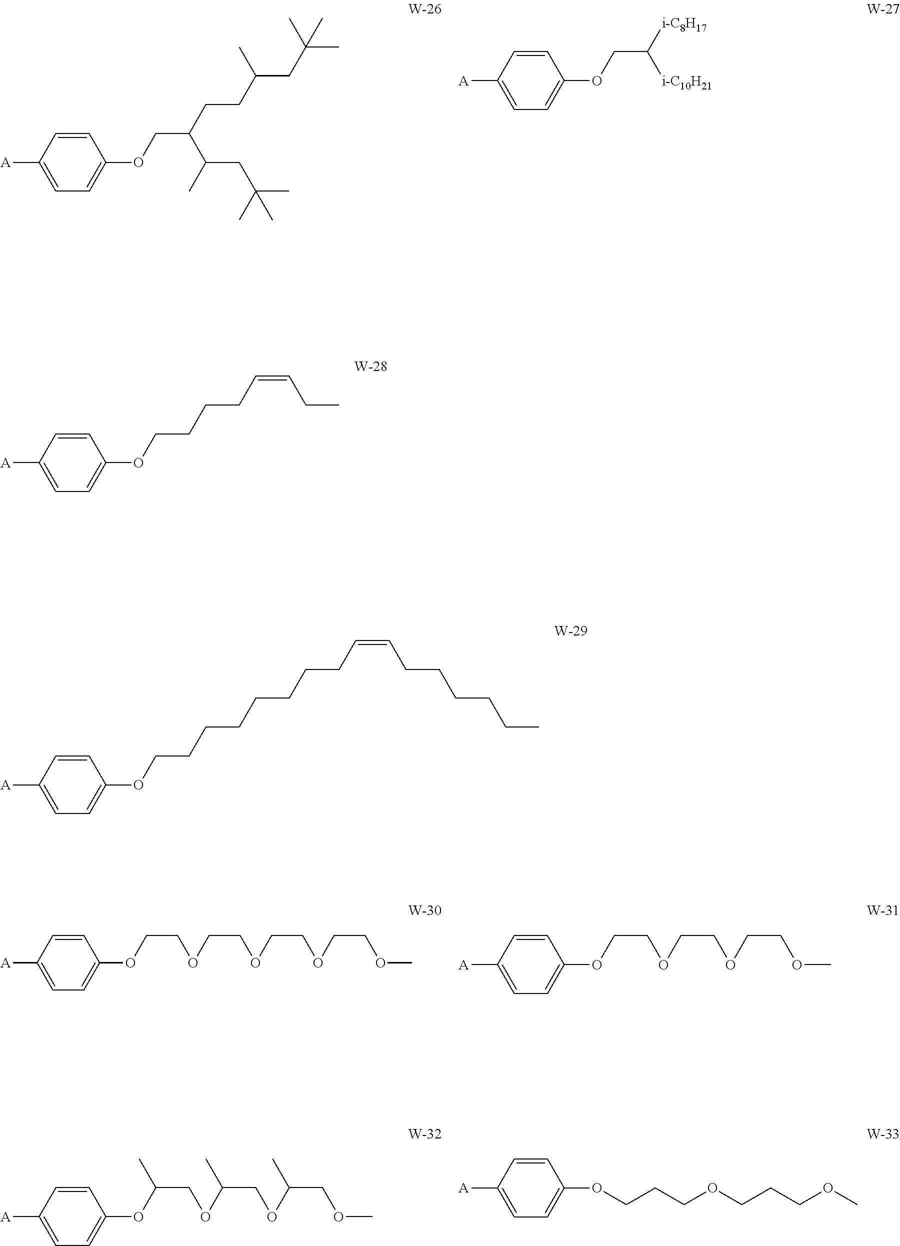

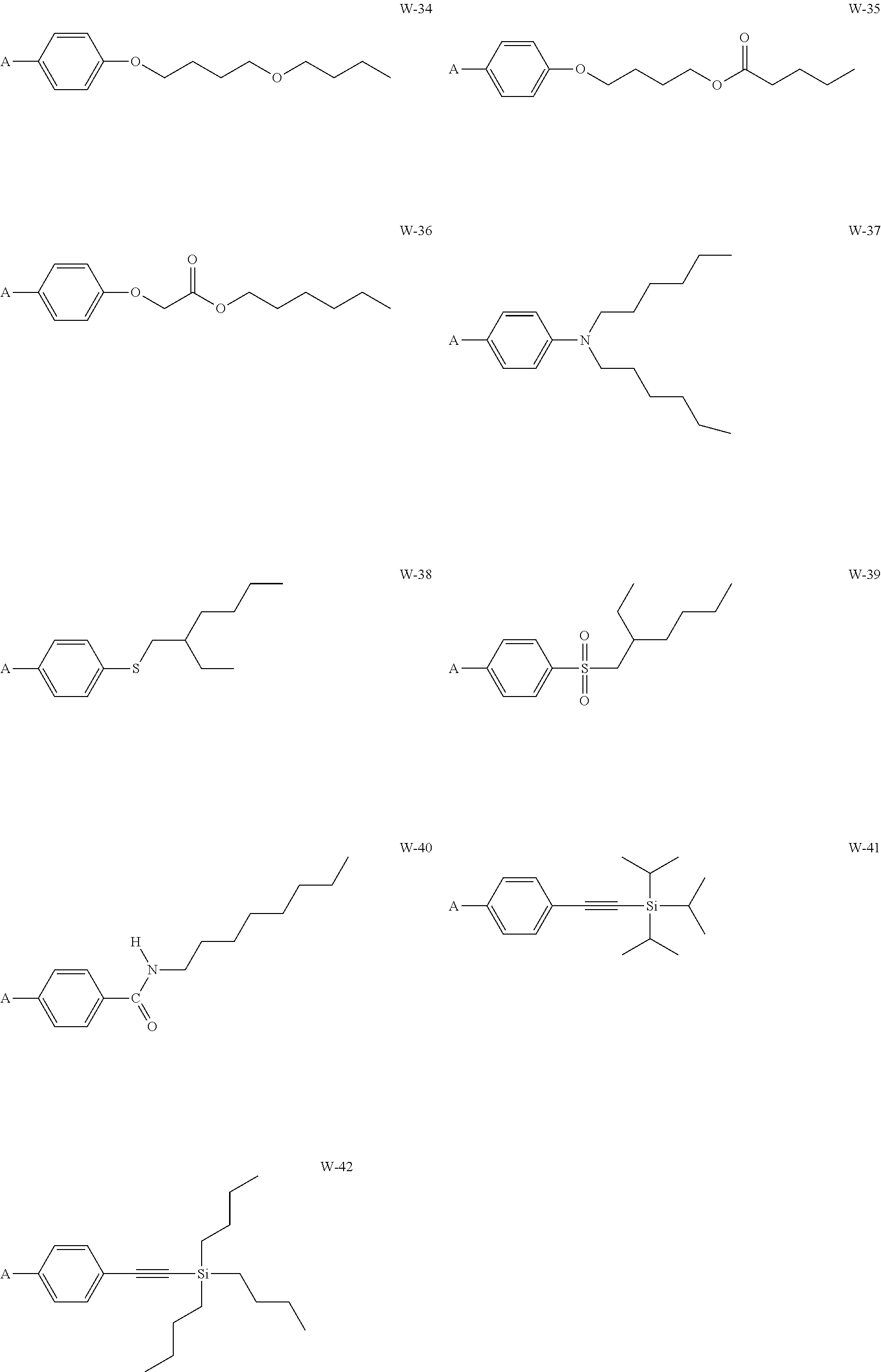

In Formula 1-1, R³ and R⁴ each independently represent a hydrogen atom or an alkyl group. R³ and R⁴ may be the same or may be different groups. It is more preferable that R³ and R⁴ are the same groups.

The number of carbon atoms of the alkyl group represented by R³ and R⁴ is preferably 1 to 20, more preferably 1 to 10, even more preferably 1 to 4, and particularly preferably 1 or 2. The alkyl group may be linear or branched. Specific examples thereof include a methyl group, an ethyl group, a propyl group, an isopropyl group, a butyl group, and an isobutyl group.

R³ and R⁴ each independently are preferably a hydrogen atom, a methyl group, or an ethyl group, more preferably a hydrogen atom or a methyl group, and particularly preferably a hydrogen atom.

In Formula 1-1, X¹ and X² each independently represent an oxygen atom (—O—) or —N(R⁵)—. X¹ and X² may be the same or different, and are preferably the same.

R⁵ represents a hydrogen atom, an alkyl group, an aryl group, or a heteroaryl group.

R⁵ is preferably a hydrogen atom, an alkyl group, or an aryl group. The alkyl group, the aryl group, and the heteroaryl group represented by R⁵ may be unsubstituted or may have a substituent. Examples of the substituent include the substituents in the description of G^{A} and G^{B} in Formula 1.

The number of carbon atoms of the alkyl group is preferably 1 to 20, more preferably 1 to 10, even more preferably 1 to 4, and particularly preferably 1 or 2. The alkyl group may be linear or branched.

The number of carbon atoms of the aryl group is preferably 6 to 20, and more preferably 6 to 12.

The heteroaryl group may be monocyclic or polycyclic. The number of hetero atoms constituting the ring of the heteroaryl group is preferably 1 to 3. As the hetero atom constituting the ring of the heteroaryl group, a nitrogen atom, an oxygen atom, or a sulfur atom is preferable. The number of carbon atoms constituting the ring of the heteroaryl group is preferably 3 to 30, more preferably 3 to 18, and even more preferably 3 to 12.

X¹ and X² each independently are preferably an oxygen atom, or represented by any one of the following formulae.

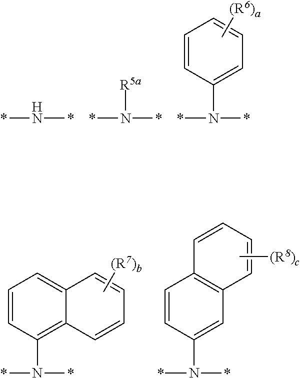

In the formulae, R^{5a} represents an alkyl group. R⁶ to R⁸ each independently represent a substituent. a represents an integer of 0 to 5. b and c each represent an integer of 0 to 7. * represents a connecting portion.

Examples of the substituent represented by R⁶ to R⁸ include the substituents in the description of G^{A} and G^{B} in Formula 1.

In Formula 1-1, Y¹ to Y⁴ each independently represent a substituent.

Examples of the substituent include the substituents in the description of G^{A} and G^{B} in Formula 1.

In Formula 1-1, each of Y¹ and Y², and Y³ and Y⁴ may be bonded to form a ring. For example, Y¹ and Y² may be bonded and may form, for example, a tricyclic ring such as an acenaphthen ring or an acenaphthylene ring together with a naphthalene ring connected to Y¹ and Y².

In a case where there are plural Y¹'s, Y²'s, Y³'s, and Y⁴'s, each of Y's, Y²'s, Y³'s, and Y⁴'s may be bonded to form a ring structure. For example, in a case where there are plural Y¹'s, Y¹'s may be bonded and may form, for example, a tricyclic ring such as an anthracene ring or a phenanthrene ring together with a naphthalene ring connected to Y¹ and Y². In a case where Y¹'s are bonded to form a ring structure, the number of each of Y² to Y⁴, that are substituents other than Y¹, may not be more than one. In addition, Y² to Y⁴ may not exist. These are also the same as in a case where Y²'s, Y³'s, or Y⁴'s are bonded to each other to form a ring structure.

p and s each independently represent an integer of 0 to 3, preferably 0 or 1, and particularly preferably 0.

q and r each independently represent an integer of 0 to 2, preferably 0 or 1, and particularly preferably 0.

In Formula (1), a cation is non-localized as below.

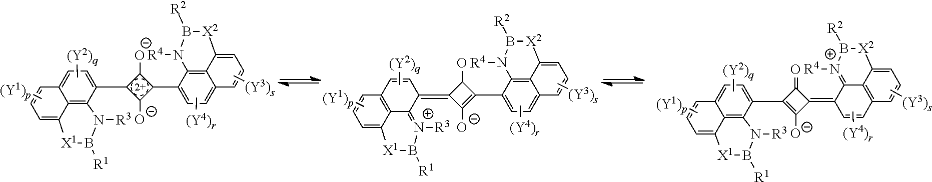

Examples of the squarylium compound represented by Formula 1 include the following compounds. The examples further include the compounds described in paragraphs 0044 to 0049 of JP2011-208101A, and the contents thereof are incorporated into this specification.

In the following specific examples, a wave-like bond in the following formulae represents a racemic body.

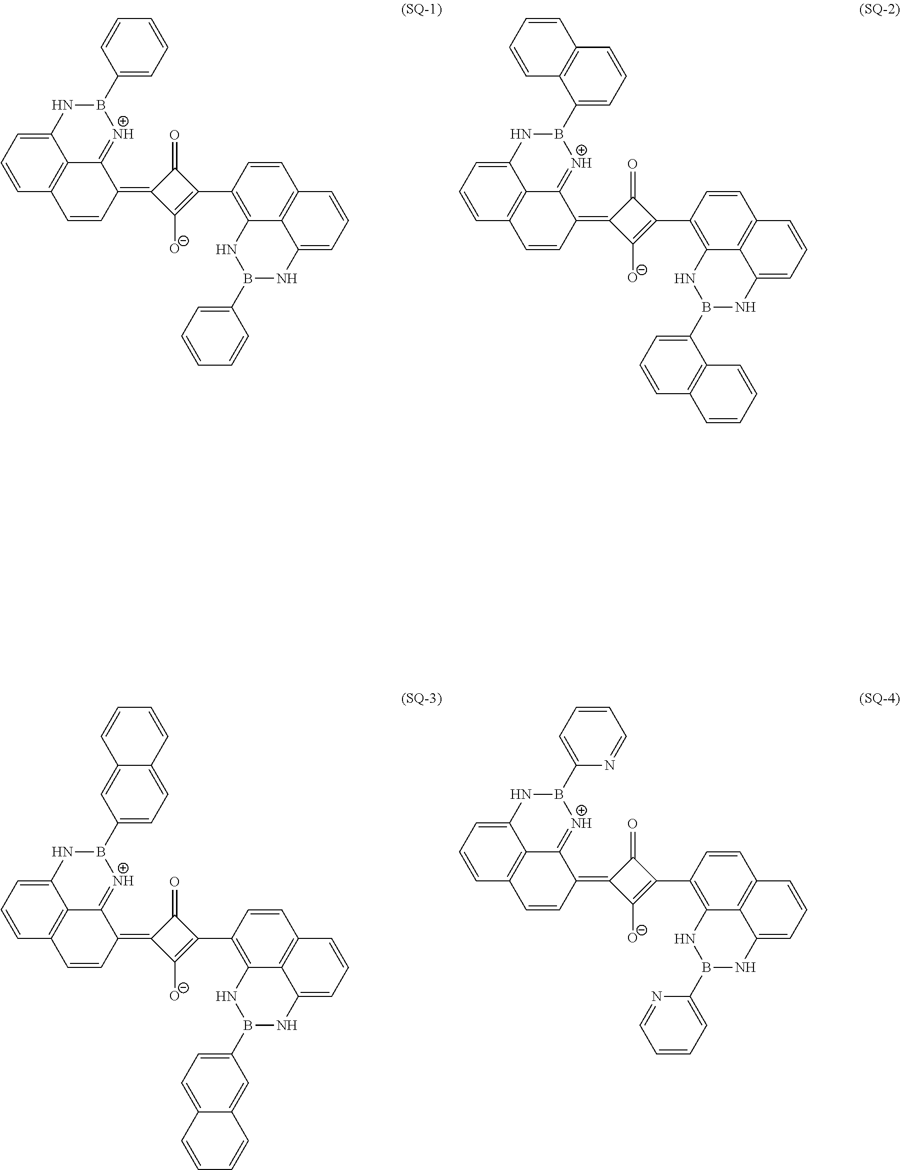 [SMILES: O=C1C(c2ccc3cccc4c3c2NB(c2ccccc2)N4)=C([O-])/C1=c1\ccc2cccc3c2c1=[NH+]B(c1ccccc1)N3 ; O=C1C(c2ccc3cccc4c3c2NB(c2cccc3ccccc23)N4)=C([O-])/C1=c1\ccc2cccc3c2c1=[NH+]B(c1cccc2ccccc12)N3 ; O=C1C(c2ccc3cccc4c3c2NB(c2ccc3ccccc3c2)N4)=C([O-])/C1=c1\ccc2cccc3c2c1=[NH+]B(c1ccc2ccccc2c1)N3 ; O=C1C(c2ccc3cccc4c3c2NB(c2ccccn2)N4)=C([O-])/C1=c1\ccc2cccc3c2c1=[NH+]B(c1ccccn1)N3]

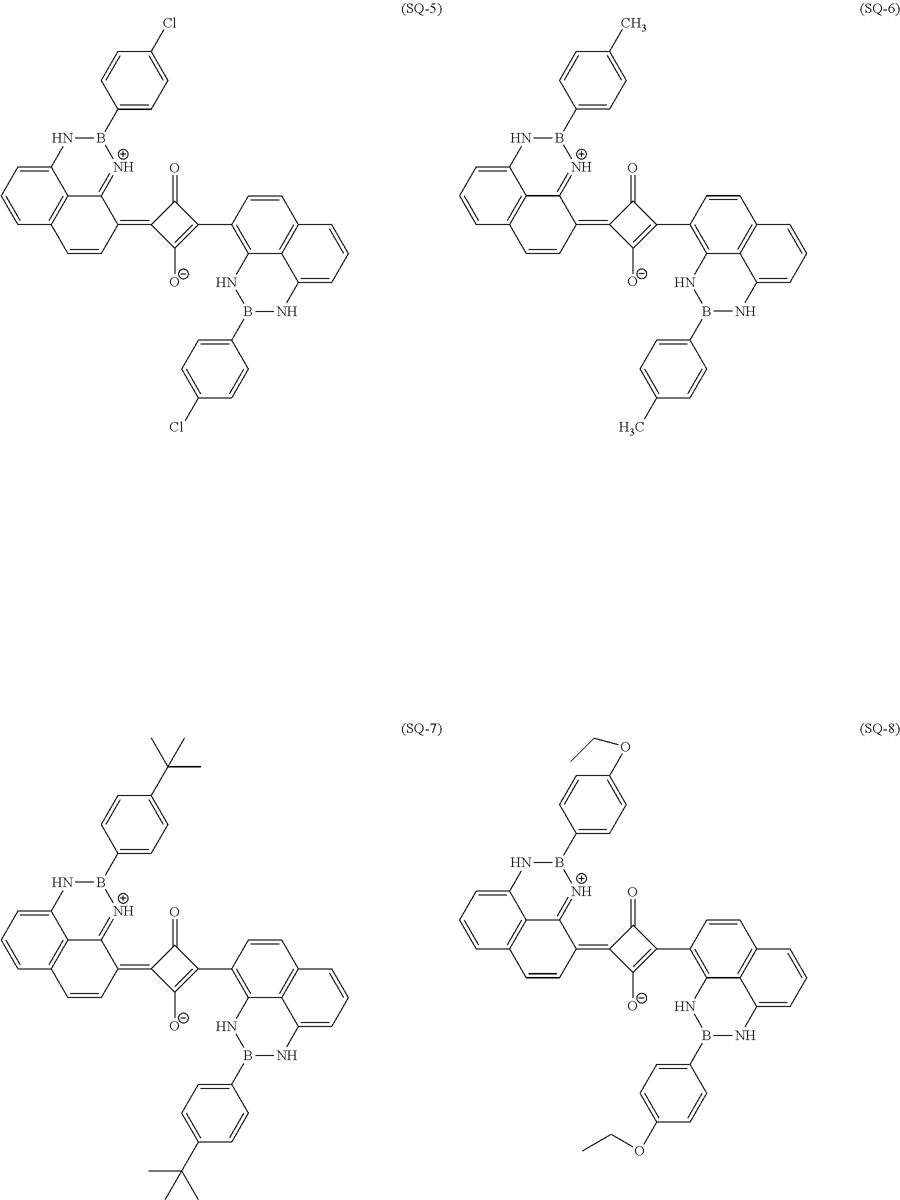 [SMILES: O=C1C(c2ccc3cccc4c3c2NB(c2ccc(Cl)cc2)N4)=C([O-])/C1=c1\ccc2cccc3c2c1=[NH+]B(c1ccc(Cl)cc1)N3 ; Cc1ccc(B2Nc3cccc4ccc(C5=C([O-])/C(=c6\ccc7cccc8c7c6=[NH+]B(c6ccc(C)cc6)N8)C5=O)c(c34)N2)cc1 ; CC(C)(C)c1ccc(B2Nc3cccc4ccc(C5=C([O-])/C(=c6\ccc7cccc8c7c6=[NH+]B(c6ccc(C(C)(C)C)cc6)N8)C5=O)c(c34)N2)cc1 ; CCOc1ccc(B2Nc3cccc4ccc(C5=C([O-])/C(=c6\ccc7cccc8c7c6=[NH+]B(c6ccc(OCC)cc6)N8)C5=O)c(c34)N2)cc1]

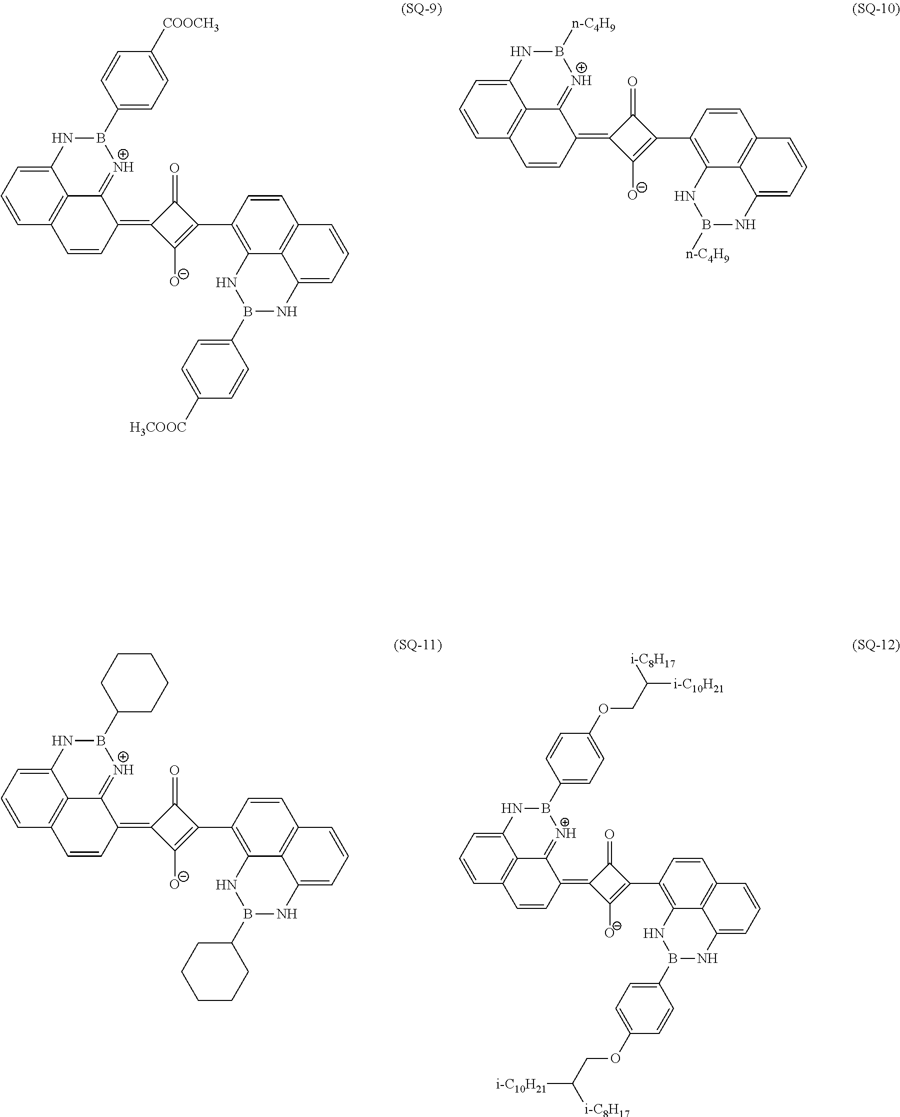

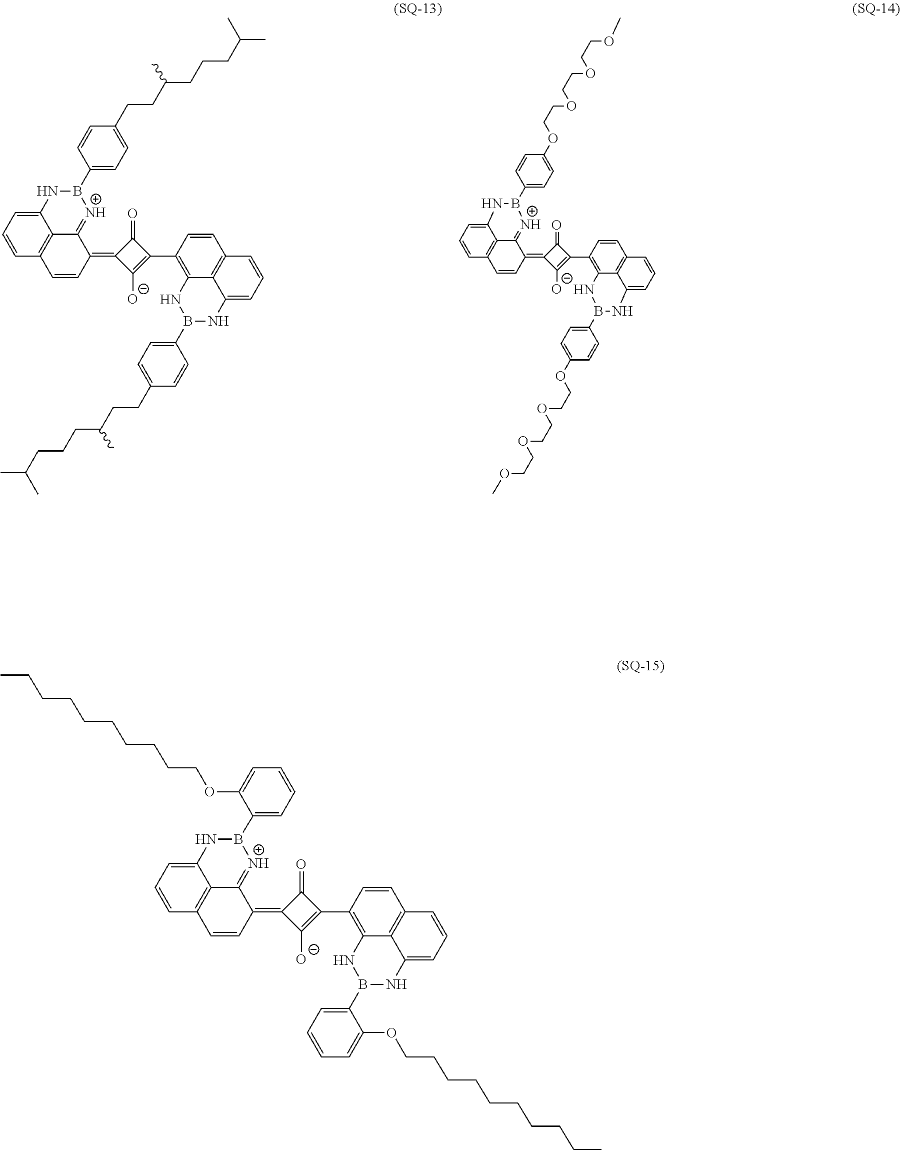

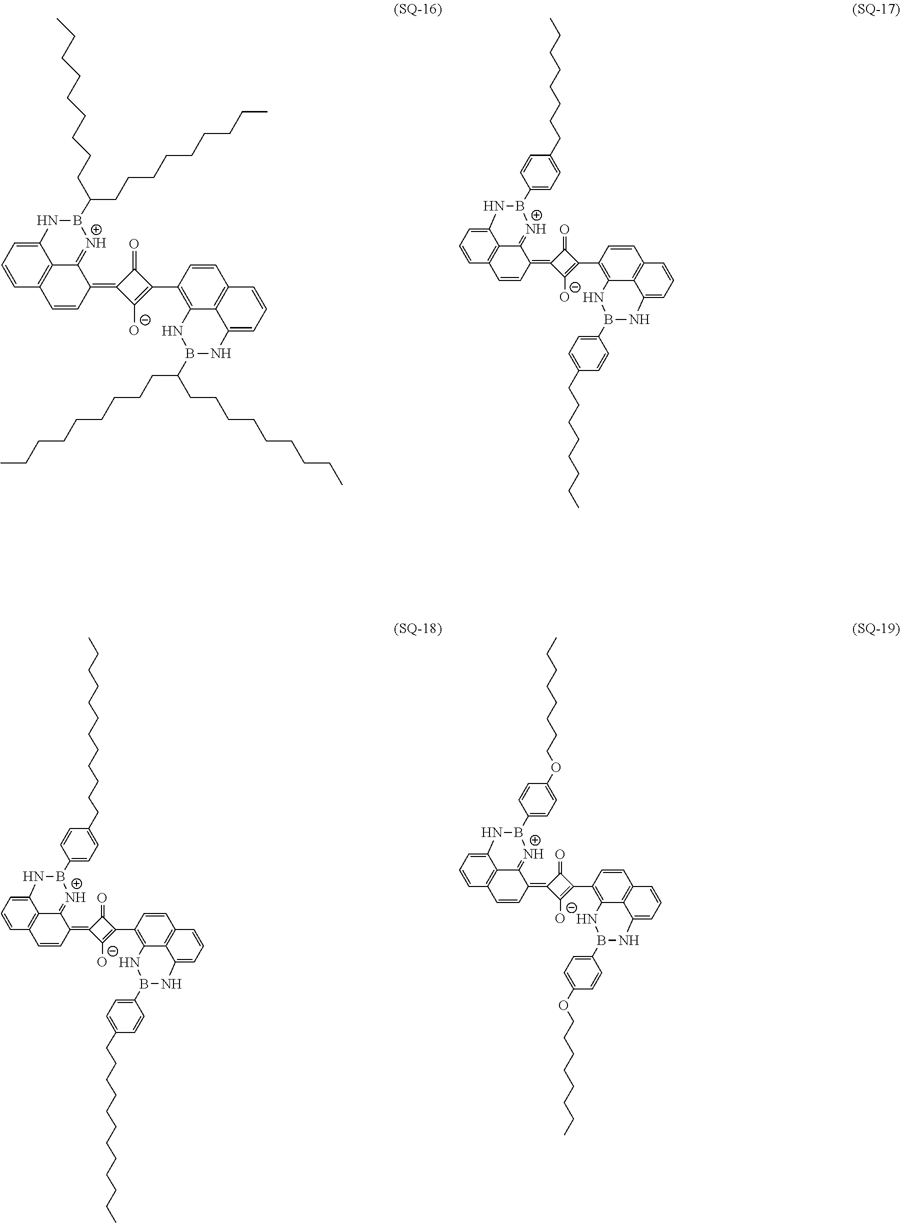 [SMILES: CCCCCCCCCC(CCCCCCCCC)B1Nc2cccc3ccc(C4=C([O-])/C(=c5\ccc6cccc7c6c5=[NH+]B(C(CCCCCCCCC)CCCCCCCCC)N7)C4=O)c(c23)N1 ; CCCCCCCCc1ccc(B2Nc3cccc4ccc(C5=C([O-])/C(=c6\ccc7cccc8c7c6=[NH+]B(c6ccc(CCCCCCCC)cc6)N8)C5=O)c(c34)N2)cc1 ; CCCCCCCCCCCCc1ccc(B2Nc3cccc4ccc(C5=C([O-])/C(=c6\ccc7cccc8c7c6=[NH+]B(c6ccc(CCCCCCCCCCCC)cc6)N8)C5=O)c(c34)N2)cc1 ; CCCCCCCCOc1ccc(B2Nc3cccc4ccc(C5=C([O-])/C(=c6\ccc7cccc8c7c6=[NH+]B(c6ccc(OCCCCCCCC)cc6)N8)C5=O)c(c34)N2)cc1]

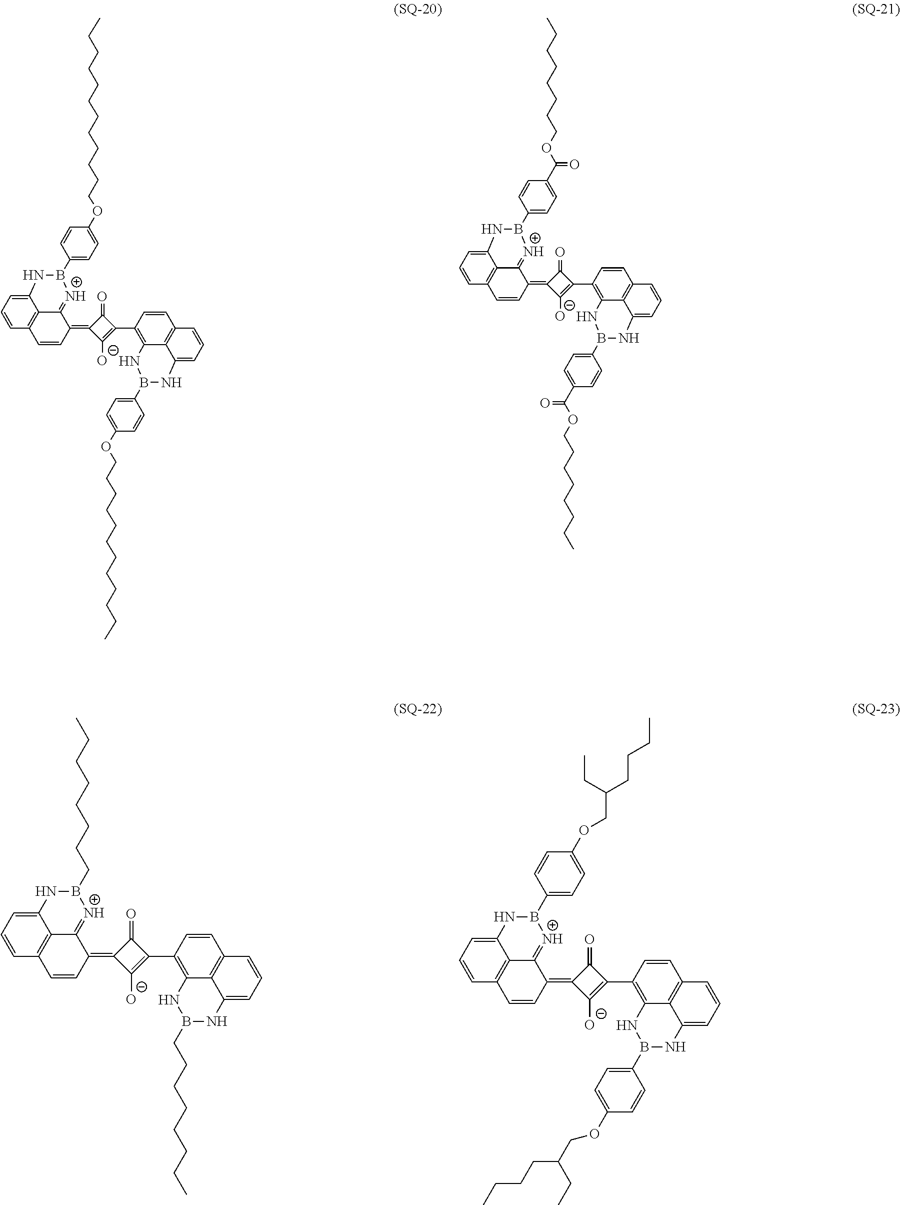 [SMILES: CCCCCCCCCCCCOc1ccc(B2Nc3cccc4ccc(C5=C([O-])/C(=c6\ccc7cccc8c7c6=[NH+]B(c6ccc(OCCCCCCCCCCCC)cc6)N8)C5=O)c(c34)N2)cc1 ; CCCCCCCCOC(=O)c1ccc(B2Nc3cccc4ccc(C5=C([O-])/C(=c6\ccc7cccc8c7c6=[NH+]B(c6ccc(C(=O)OCCCCCCCC)cc6)N8)C5=O)c(c34)N2)cc1 ; CCCCCCCCB1Nc2cccc3ccc(C4=C([O-])/C(=c5\ccc6cccc7c6c5=[NH+]B(CCCCCCCC)N7)C4=O)c(c23)N1 ; CCCCC(CC)COc1ccc(B2Nc3cccc4ccc(C5=C([O-])/C(=c6\ccc7cccc8c7c6=[NH+]B(c6ccc(OCC(CC)CCCC)cc6)N8)C5=O)c(c34)N2)cc1]

<<<Compound Represented by Formula 2 (Pyrrolopyrrole Compound)>>>>

In Formula 2, R^{1a} and R^{1b} each independently represent an alkyl group, an aryl group, or a heteroaryl group. R^{1a} and R^{1b} each independently are preferably an aryl group or a heteroaryl group, and more preferably an aryl group.

The number of carbon atoms of the alkyl group represented by R^{1a} and R^{1b} is preferably 1 to 40, more preferably 1 to 30, and particularly preferably 1 to 25. The alkyl group may be linear, branched, or cyclic. The alkyl group is preferably linear or branched, and particularly preferably branched.

The number of carbon atoms of the aryl group represented by R^{1a} and R^{1b} is preferably 6 to 30, more preferably 6 to 20, and even more preferably 6 to 12. The aryl group is preferably phenyl.

The heteroaryl group represented by R^{1a} and R^{1b} is preferably monocyclic or fused, more preferably monocyclic or fused with a fused number of 2 to 8, and even more preferably monocyclic or fused with a fused number of 2 to 4. The number of hetero atoms constituting the ring of the heteroaryl group is preferably 1 to 3. As the hetero atom constituting the ring of the heteroaryl group, a nitrogen atom, an oxygen atom, or a sulfur atom is preferable. The number of carbon atoms constituting the heteroaryl group is preferably 3 to 30, more preferably 3 to 18, even more preferably 3 to 12, and particularly preferably 3 to 10. The heteroaryl group is preferably a five-membered ring or a six-membered ring.

The above-described aryl group and heteroaryl group may have a substituent or may be unsubstituted. From the viewpoint of improving solubility to a solvent, the aryl group and the heteroaryl group preferably have a substituent.

Examples of the substituent include a hydrocarbon group that may include an oxygen atom, an amino group, an acylamino group, a sulfonylamino group, a sulfamoyl group, a carbamoyl group, an alkylthio group, an alkylsulfonyl group, a sulfinyl group, an ureido group, a phosphoric acid amide group, a mercapto group, a sulfo group, a carboxyl group, a nitro group, a hydroxamic acid group, a sulfino group, a hydrazino group, an imino group, a silyl group, a hydroxy group, a halogen atom, and a cyano group.

Examples of the halogen atom include a fluorine atom, a chlorine atom, a bromine atom, and an iodine atom.

Examples of the hydrocarbon group include an alkyl group, an alkenyl group, and an aryl group.

The number of carbon atoms of the alkyl group is preferably 1 to 40. The lower limit is more preferably not less than 3, even more preferably not less than 5, still more preferably not less than 8, and particularly preferably not less than 10. The upper limit is more preferably not greater than 35, and even more preferably not greater than 30. The alkyl group may be linear, branched, or cyclic. The alkyl group is preferably linear or branched, and particularly preferably branched. The number of carbon atoms of a branched alkyl group is preferably 3 to 40. The lower limit is, for example, more preferably not less than 5, even more preferably not less than 8, and still more preferably not less than 10. The upper limit is more preferably not greater than 35, and even more preferably not greater than 30. The number of branches of a branched alkyl group is, for example, preferably 2 to 10, and more preferably 2 to 8. Satisfactory solvent solubility is obtained in a case where the number of branches is within the above-described range.

The number of carbon atoms of the alkenyl group is preferably 2 to 40. The lower limit is, for example, more preferably not less than 3, even more preferably not less than 5, still more preferably not less than 8, and particularly preferably not less than 10. The upper limit is more preferably not greater than 35, and even more preferably not greater than 30. The alkenyl group may be linear, branched, or cyclic. The alkenyl group is preferably linear or branched, and particularly preferably branched. The number of carbon atoms of a branched alkenyl group is preferably 3 to 40. The lower limit is, for example, more preferably not less than 5, even more preferably not less than 8, and still more preferably not less than 10. The upper limit is more preferably not greater than 35, and even more preferably not greater than 30. The number of branches of a branched alkenyl group is preferably 2 to 10, and more preferably 2 to 8. Satisfactory solvent solubility is obtained in a case where the number of branches is within the above-described range.

The number of carbon atoms of the aryl group is preferably 6 to 30, more preferably 6 to 20, and even more preferably 6 to 12.

Examples of the hydrocarbon group including an oxygen atom include a group represented by -L-R^{x1}.

L represents —O—, —CO—, —COO—, —OCO—, —(OR^{x2})ₘ—, or —(R^{x2}O)ₘ—. R^{x1} represents an alkyl group, an alkenyl group, or an aryl group. R^{x2} represents an alkylene group or an arylene group. m represents an integer of 2 or more. m R^{x2}'s may be the same or different.

L is preferably —O—, —(OR^{x2})ₘ—, or —(R^{x2}O)ₘ—, and more preferably —O—.

The alkyl group, the alkenyl group, and the aryl group represented by R^{x1} are synonymous those in the above description, and their preferable ranges are also similar. R^{x1} is preferably an alkyl group or an alkenyl group, and more preferably an alkyl group.

The number of carbon atoms of the alkylene group represented by R^{x2} is preferably 1 to 20, more preferably 1 to 10, and even more preferably 1 to 5. The alkylene group may be linear, branched, or cyclic, and is preferably linear or branched. The number of carbon atoms of the arylene group represented by R^{x2} is preferably 6 to 20, and more preferably 6 to 12. R^{x2} is preferably an alkylene group.

m represents an integer of 2 or more. m is preferably 2 to 20, and more preferably 2 to 10.

The substituent that the aryl group and the heteroaryl group may have is preferably a group having a branched alkyl structure. According to this aspect, solvent solubility is further improved. In addition, the substituent is preferably a hydrocarbon group that may include an oxygen atom, and more preferably a hydrocarbon group including an oxygen atom. The hydrocarbon group including an oxygen atom is preferably a group represented by —O—R^{x1}. R^{x1} is preferably an alkyl group or an alkenyl group, more preferably an alkyl group, and particularly preferably a branched alkyl group. That is, the substituent is more preferably an alkoxy group, and particularly preferably a branched alkoxy group. In a case where the substituent is an alkoxy group, it is possible to obtain an infrared absorbing agent having excellent heat resistance and light resistance. In addition, in a case where the substituent is a branched alkoxy group, satisfactory solvent solubility is obtained.

The number of carbon atoms of the alkoxy group is preferably 1 to 40. The lower limit is, for example, more preferably not less than 3, even more preferably not less than 5, still more preferably not less than 8, and particularly preferably not less than 10. The upper limit is more preferably not greater than 35, and even more preferably not greater than 30. The alkoxy group may be linear, branched, or cyclic. The alkoxy group is preferably linear or branched, and particularly preferably branched. The number of carbon atoms of a branched alkoxy group is preferably 3 to 40. The lower limit is, for example, more preferably not less than 5, even more preferably not less than 8, and still more preferably not less than 10. The upper limit is more preferably not greater than 35, and even more preferably not greater than 30. The number of branches of a branched alkoxy group is preferably 2 to 10, and more preferably 2 to 8.

R² to R⁵ each independently represent a hydrogen atom or a substituent. Examples of the substituent include an alkyl group, an alkenyl group, an alkynyl group, an aryl group, a heteroaryl group, an amino group (including an alkylamino group, an arylamino group, and a heterocyclic amino group), an alkoxy group, an aryloxy group, a heteroaryloxy group, an acyl group, an alkylcarbonyl group, an arylcarbonyl group, an alkoxycarbonyl group, an aryloxycarbonyl group, an acyloxy group, an acylamino group, an alkoxycarbonylamino group, an aryloxycarbonylamino group, a sulfonylamino group, a sulfamoyl group, a carbamoyl group, an alkylthio group, an arylthio group, a heteroarylthio group, an alkylsulfonyl group, an arylsulfonyl group, a sulfinyl group, an ureido group, a phosphoric acid amide group, a hydroxy group, a mercapto group, a halogen atom, a cyano group, a sulfo group, a carboxyl group, a nitro group, a hydroxamic acid group, a sulfino group, a hydrazino group, an imino group, and a silyl group.

Any one of R² and R³ and any one of R⁴ and R⁵ are preferably electron-withdrawing groups.

A substituent having a positive Hammett sigma para value (σp value) acts as an electron-withdrawing group.

In the invention, a substituent having a Hammett σp value of 0.2 or greater can be exemplified as an electron-withdrawing group. The σp value is preferably 0.25 or greater, more preferably 0.3 or greater, and particularly preferably 0.35 or greater. The upper limit is not particularly limited, but preferably 0.80.

Specific examples of the electron-withdrawing group include a cyano group (σp value=0.66), a carboxyl group (for example, —COOH: σp value=0.45), an alkoxycarbonyl group (for example, —COOMe: σp value=0.45), an aryloxycarbonyl group (for example, —COOPh: σp value=0.44), a carbamoyl group (for example, —CONH₂: σp value=0.36), an alkylcarbonyl group (for example, —COMe: σp value=0.50), an arylcarbonyl group (for example, —COPh: σp value=0.43), an alkylsulfonyl group (for example, —SO₂Me: σp value=0.72), and an arylsulfonyl group (for example, —SO₂Ph: σp value=0.68). A cyano group is particularly preferable. Here, Me represents a methyl group and Ph represents a phenyl group.

Regarding the Hammett σp value, for example, paragraphs 0024 and 0025 of JP2009-263614A can be referred to, and the contents thereof are incorporated into this specification.

Any one of R² and R³ and any one of R⁴ and R⁵ are preferably heteroaryl groups.

The heteroaryl group is preferably monocyclic or fused, more preferably monocyclic or fused with a fused number of 2 to 8, and even more preferably monocyclic or fused with a fused number of 2 to 4. The number of hetero atoms constituting the heteroaryl group is preferably 1 to 3. As the hetero atom constituting the heteroaryl group, a nitrogen atom, an oxygen atom, or a sulfur atom is preferable. The heteroaryl group preferably has one or more nitrogen atoms. The number of carbon atoms constituting the heteroaryl group is preferably 3 to 30, more preferably 3 to 18, even more preferably 3 to 12, and particularly preferably 3 to 10. The heteroaryl group is preferably a five-membered ring or a six-membered ring. Specific examples of the heteroaryl group include an imidazolyl group, a pyridyl group, a pyrazyl group, a pyrimidyl group, a pyridazyl group, a triazile group, a quinolyl group, a quinoxalyl group, an isoquinolyl group, an indolenyl group, a furyl group, a thienyl group, a benzoxazolyl group, a benzimidazolyl group, a benzothiazolyl group, a naphthothiazolyl group, a benzoxazoly group, a m-carbazolyl group, an azepinyl group, and a benzo-condensed or naphtho-condensed group of these groups.

The heteroaryl group may have a substituent or may be unsubstituted. Examples of the substituent include the above-described substituents represented by R² to R⁵. A halogen atom, an alkyl group, an alkoxy group, or an aryl group is preferable.

As the halogen atom, a fluorine atom, a chlorine atom, a bromine atom, or an iodine atom is preferable, and a chlorine atom is particularly preferable.

The number of carbon atoms of the alkyl group or the alkoxy group is preferably 1 to 40, more preferably 1 to 30, and particularly preferably 1 to 25. The alkyl group and the alkoxy group are preferably linear or branched, and particularly preferably linear.

The number of carbon atoms of the aryl group is preferably 6 to 30, more preferably 6 to 20, and even more preferably 6 to 12.

In Formula 2, each of R² and R³, and R⁴ and R⁵ may be bonded to form a ring. In a case where each of R² and R³, and R⁴ and R⁵ are bonded to form a ring, a five- to seven-membered ring (preferably five- or six-membered ring) is preferably formed that is used as an acidic nucleus in a merocyanine dye. Specific examples thereof include the structures described in paragraph 0026 of JP2010-222557A, and the contents thereof are incorporated into this specification.

The ring that is formed by bonding of R² and R³, or R⁴ and R⁵ is preferably 1,3-dicarbonyl nucleus, a pyrazolinone nucleus, a 2,4,6-triketohexahydropyrimidine nucleus (including a thioketone form), a 2-thio-2,4-thiazolidinedione nucleus, a 2-thio-2,4-oxazolidinedione nucleus, a 2-thio-2,5-thiazolidinedione nucleus, a 2,4-thiazolidinedione nucleus, a 2,4-imidazolidinedione nucleus, a 2-thio-2,4-imidazolidinedione nucleus, a 2-imidazolin-5-one nucleus, a 3,5-pyrazolidinedione nucleus, a benzothiophen-3-one nucleus, or an indanone nucleus; and more preferably a 1,3-dicarbonyl nucleus, a 2,4,6-triketohexahydropyrimidine nucleus (including a thioketone form), a 3,5-pyrazolidinedione nucleus, a benzothiophen-3-one nucleus or an indanone nucleus.

R⁶ and R⁷ each independently represent a hydrogen atom, an alkyl group, an aryl group, a heteroaryl group, —BR^{A}R^{B}, or a metal atom, and —BR^{A}R^{B} is preferable.

The number of carbon atoms of the alkyl group represented by R⁶ and R⁷ is preferably 1 to 40, more preferably 1 to 30, and particularly preferably 1 to 25. The alkyl group may be linear, branched, or cyclic. The alkyl group is preferably linear or branched, and particularly preferably linear. The alkyl group may be unsubstituted or may have a substituent. Examples of the substituent include the above-described substituents represented by R² to R⁵.

The number of carbon atoms of the aryl group represented by R⁶ and R⁷ is preferably 6 to 30, more preferably 6 to 20, and even more preferably 6 to 12. The aryl group may be unsubstituted or may have a substituent. Examples of the substituent include the above-described substituents represented by R² to R⁵.

The heteroaryl group represented by R⁶ and R⁷ is preferably monocyclic or fused, and more preferably monocyclic. The number of hetero atoms constituting the ring of the heteroaryl group is preferably 1 to 3. As the hetero atom constituting the ring of the heteroaryl group, a nitrogen atom, an oxygen atom, or a sulfur atom is preferable. The number of carbon atoms constituting the ring of the heteroaryl group is preferably 3 to 30, more preferably 3 to 18, even more preferably 3 to 12, and particularly preferably 3 to 5. The heteroaryl group is preferably a five-membered ring or a six-membered ring. The heteroaryl group may be unsubstituted or may have a substituent. Examples of the substituent include the above-described substituents represented by R² to R⁵.

The metal atom represented by R⁶ and R⁷ is preferably a magnesium, aluminum, calcium, barium, zinc, tint, vanadium, iron, cobalt, nickel, copper, palladium, iridium, or platinum atom, and particularly preferably an aluminum, zinc, vanadium, iron, copper, palladium, iridium, or platinum atom.

In a group represented by —BR^{A}R^{B}, R^{A} and R^{B} each independently represent a hydrogen atom or a substituent.

Examples of the substituent represented by R^{A} and R^{B} include the above-described substituents represented by R² to R⁵. A halogen atom, an alkyl group, an alkoxy group, an aryl group, and a heteroaryl group are preferable.

As the halogen atom, a fluorine atom, a chlorine atom, a bromine atom, or an iodine atom is preferable, and a fluorine atom is particularly preferable.

The number of carbon atoms of the alkyl group or the alkoxy group is preferably 1 to 40, more preferably 1 to 30, and particularly preferably 1 to 25. The alkyl group and the alkoxy group are preferably linear or branched, and particularly preferably linear. The alkyl group and the alkoxy group may have a substituent or may be unsubstituted. Examples of the substituent include an aryl group, a heteroaryl group, and a halogen atom.

The number of carbon atoms of the aryl group is preferably 6 to 20, and more preferably 6 to 12. The aryl group may have a substituent or may be unsubstituted. Examples of the substituent include an alkyl group, an alkoxy group, and a halogen atom.

The heteroaryl group may be monocyclic or polycyclic. The number of hetero atoms constituting the heteroaryl group is preferably 1 to 3. As the hetero atom constituting the heteroaryl group, a nitrogen atom, an oxygen atom, or a sulfur atom is preferable. The number of carbon atoms constituting the heteroaryl group is preferably 3 to 30, more preferably 3 to 18, even more preferably 3 to 12, and particularly preferably 3 to 5. The heteroaryl group is preferably a five-membered ring or a six-membered ring. The heteroaryl group may have a substituent or may be unsubstituted. Examples of the substituent include an alkyl group, an alkoxy group, and a halogen atom.

In Formula 2, R⁶ may be bonded to R^{1a} or R³ by a covalent bond or a coordination bond. R⁷ may be bonded to R^{1b} or R⁵ by a covalent bond or a coordination bond.

Examples of the pyrrolopyrrole compound represented by Formula 2 include the following compounds. The examples further include the compounds D-1 to D-162 described in paragraphs 0049 to 0062 of JP2010-222557A, and the contents thereof are incorporated into this specification. In the following formulae, Ph represents a phenyl group.

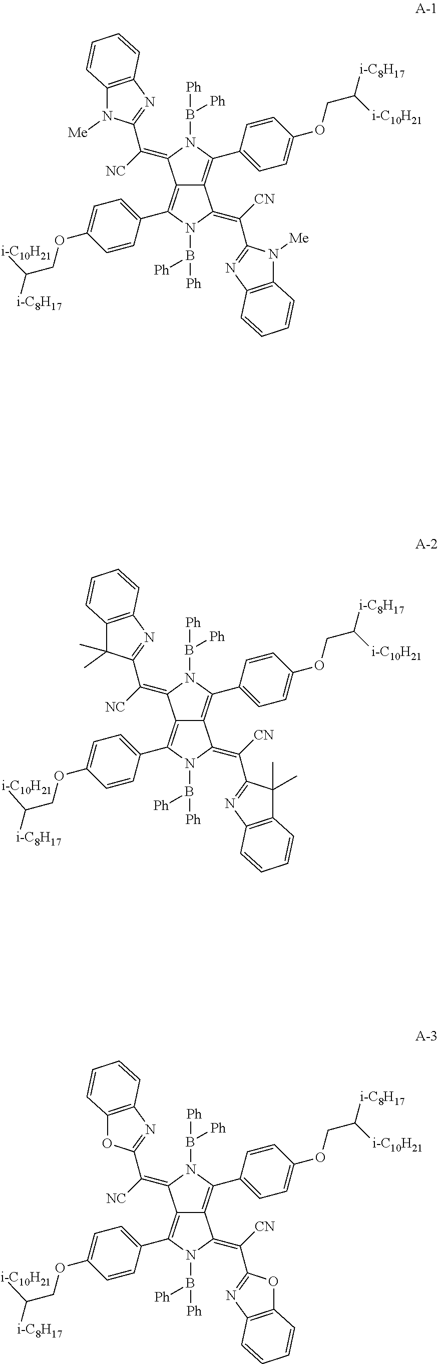

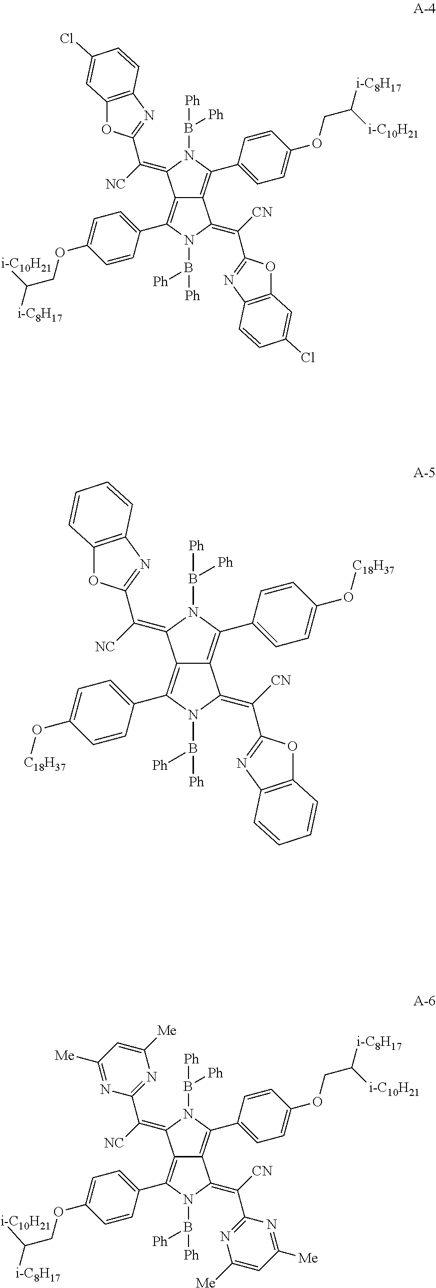

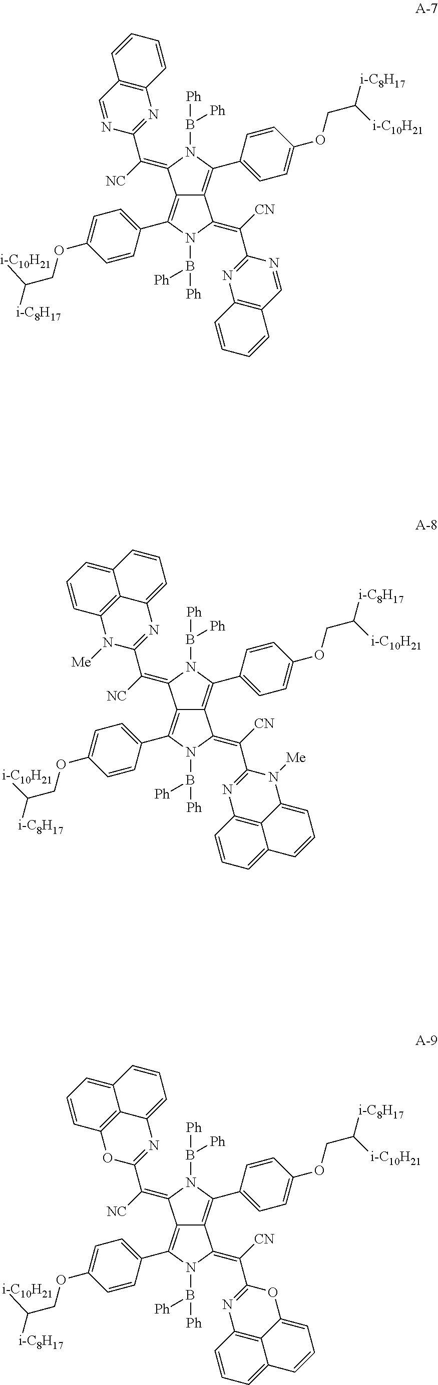

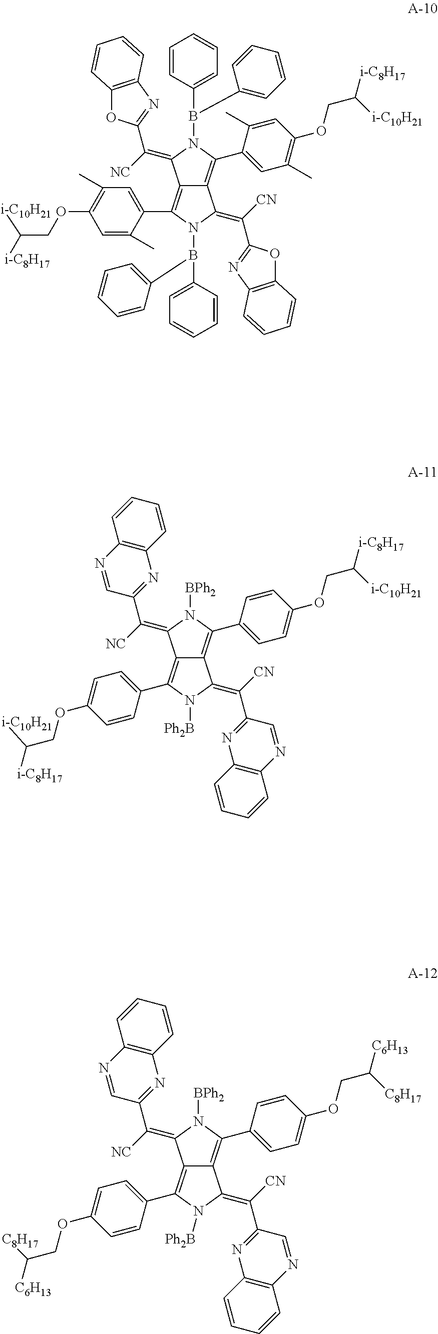

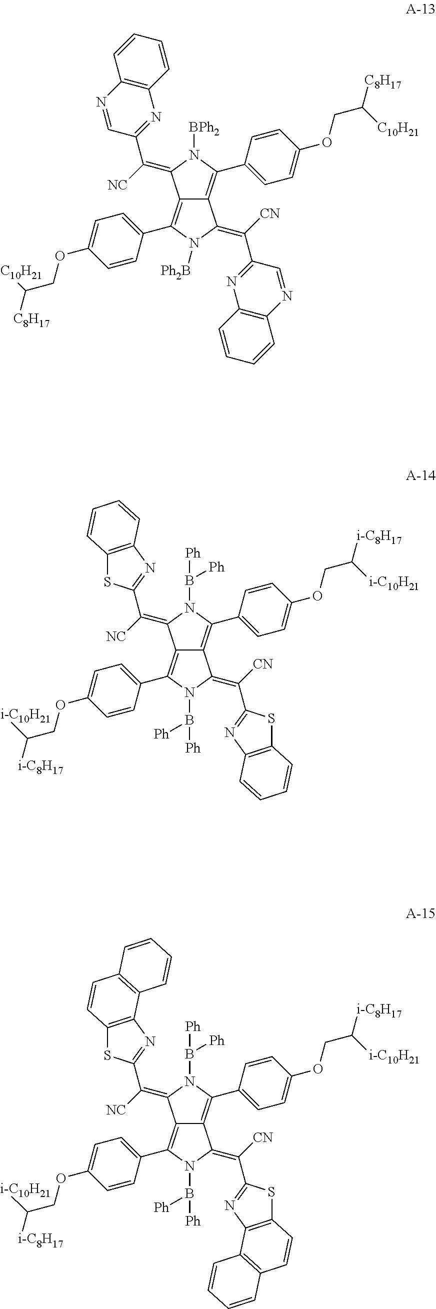

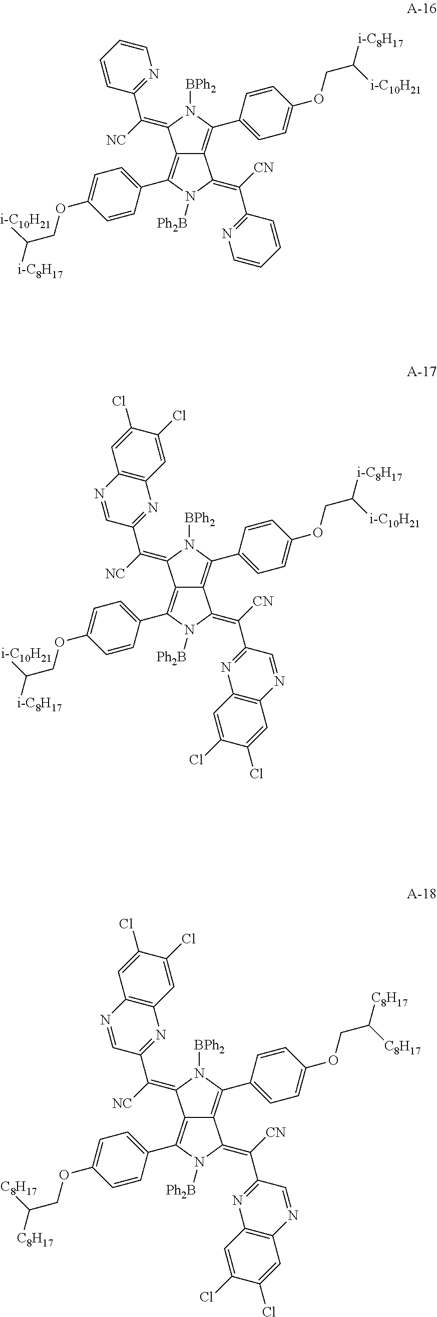

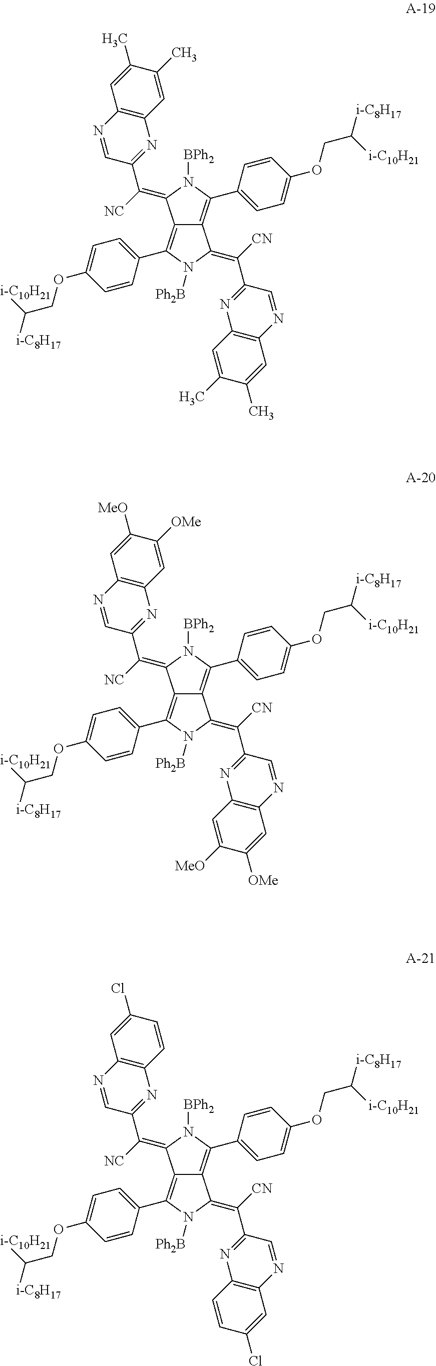

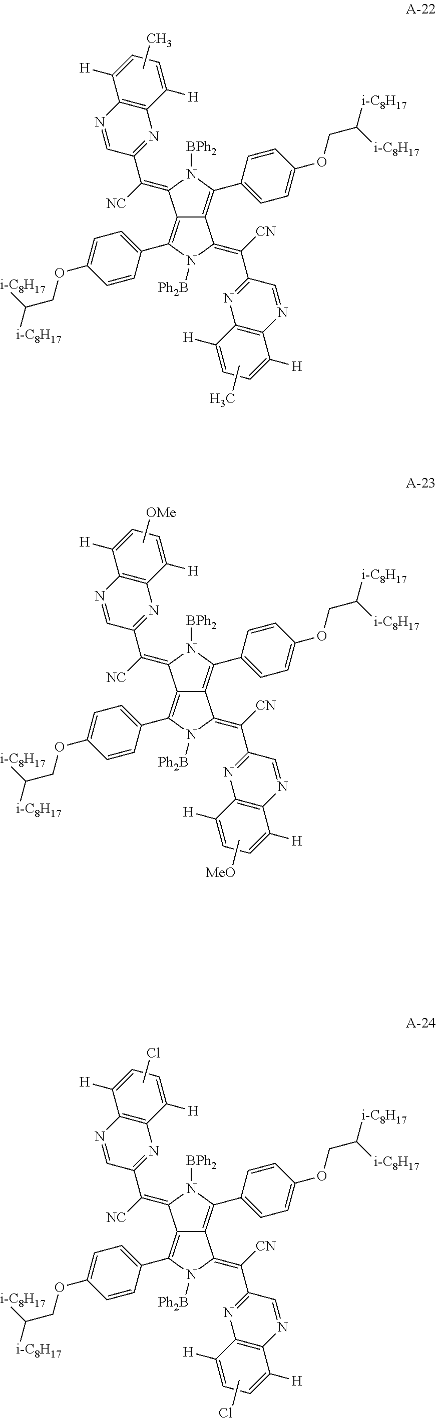

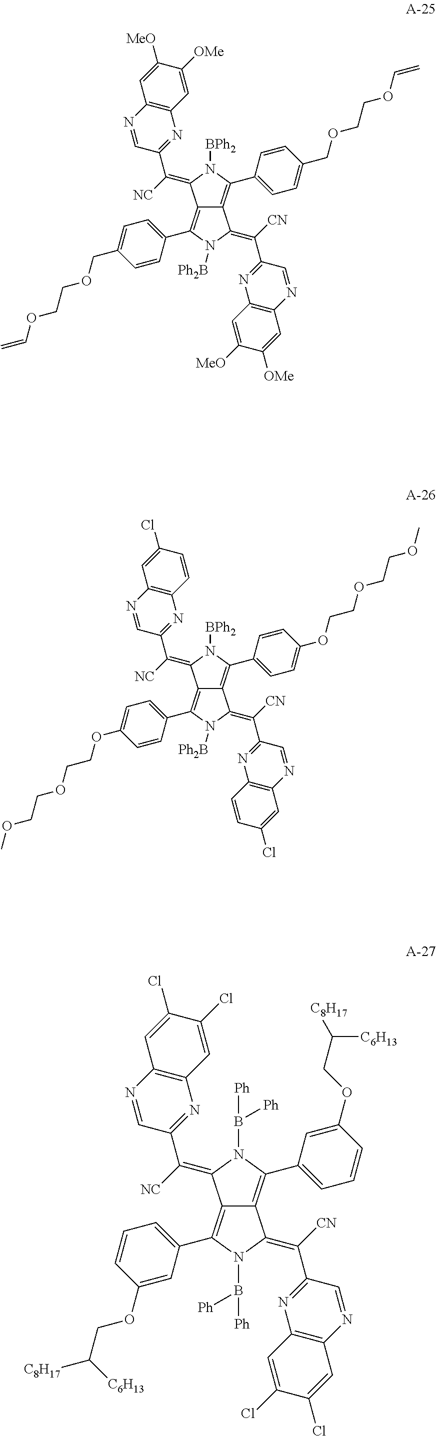

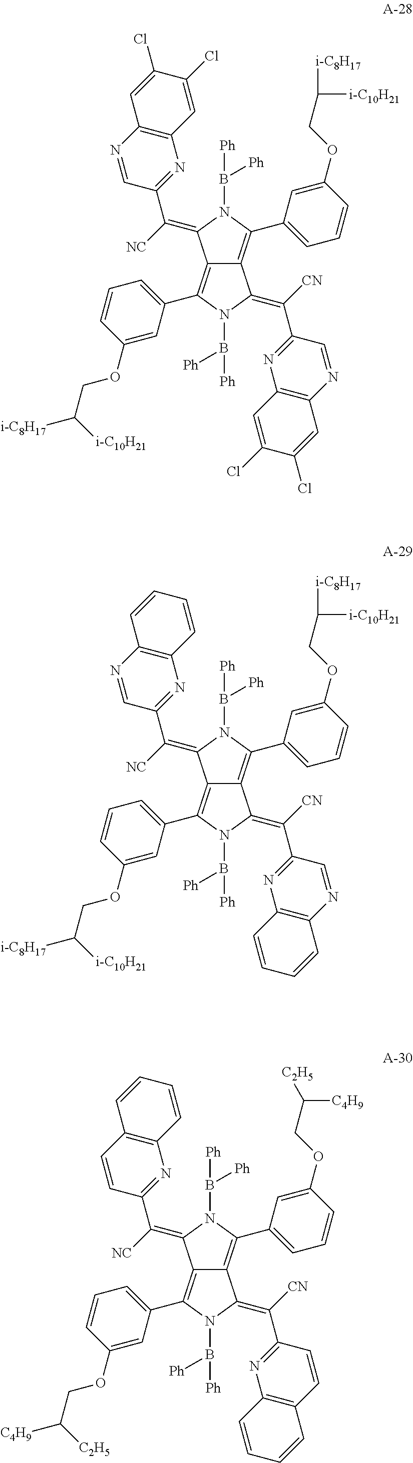

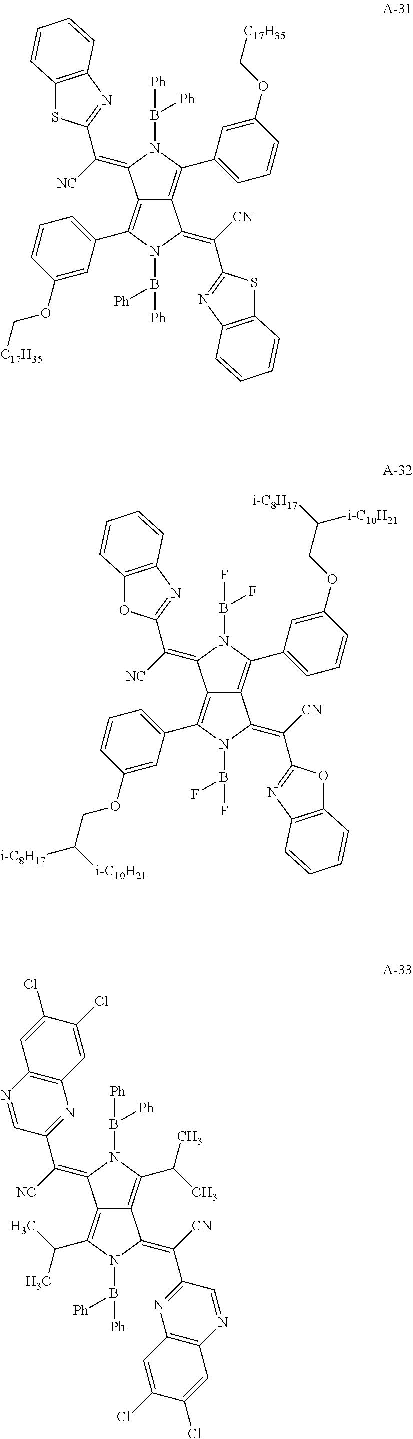

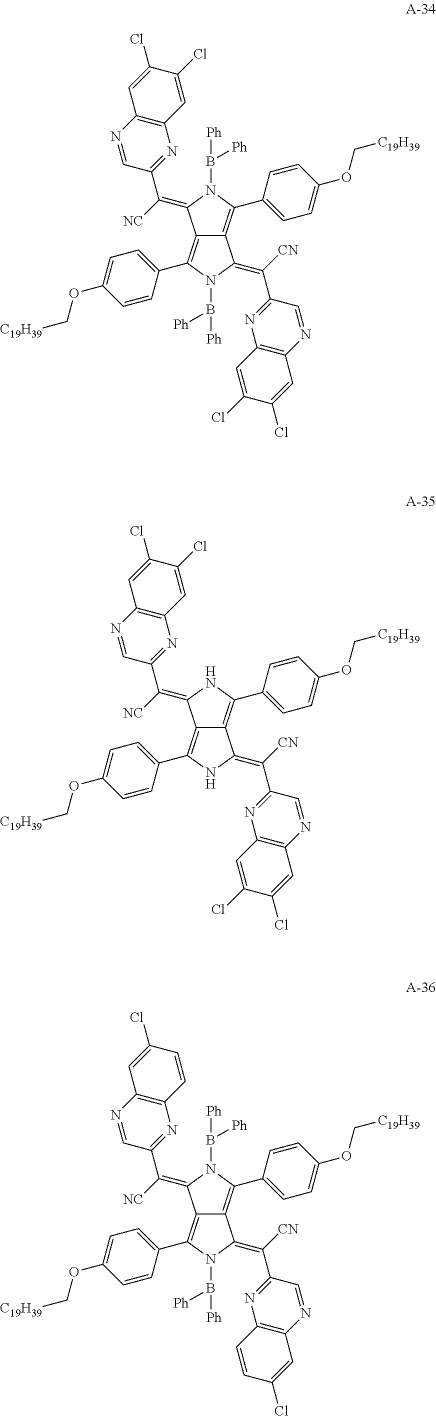

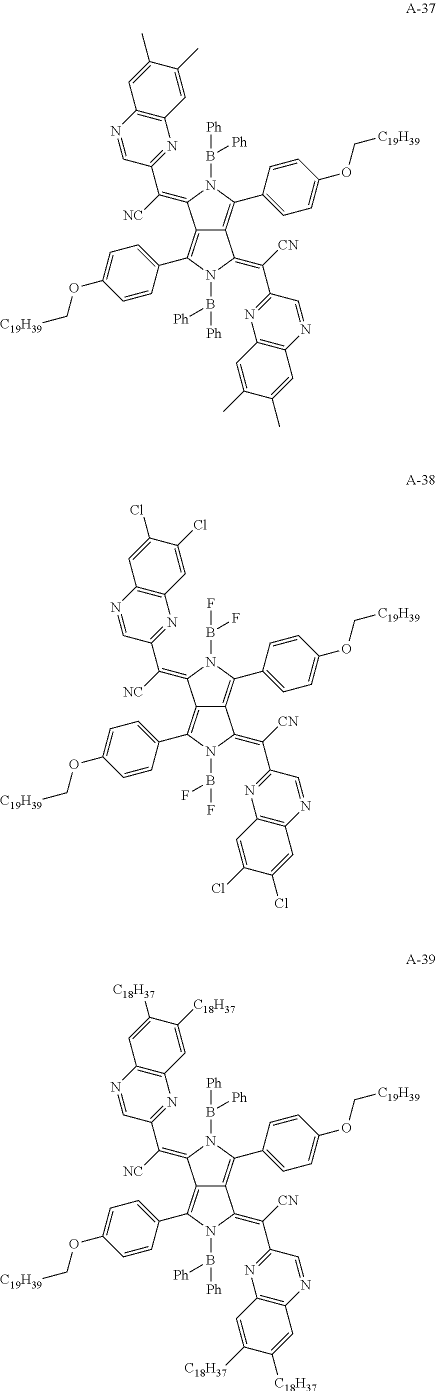

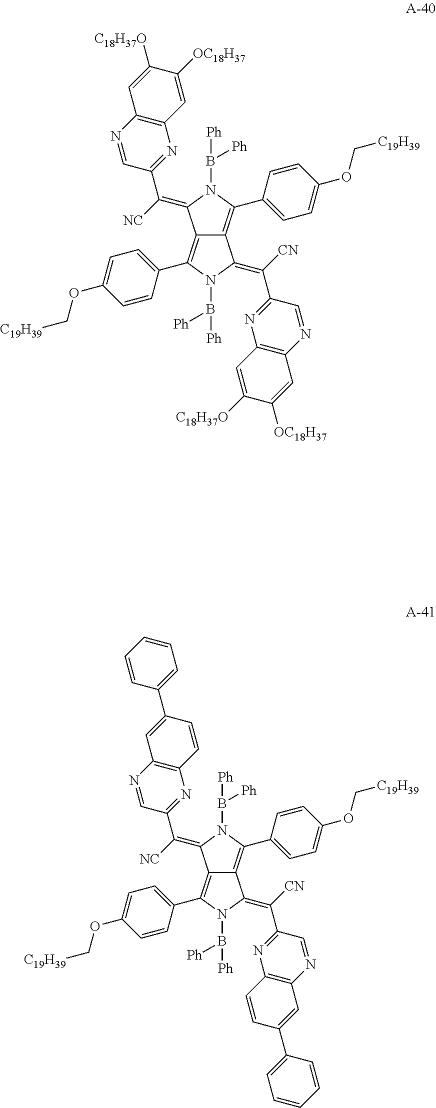

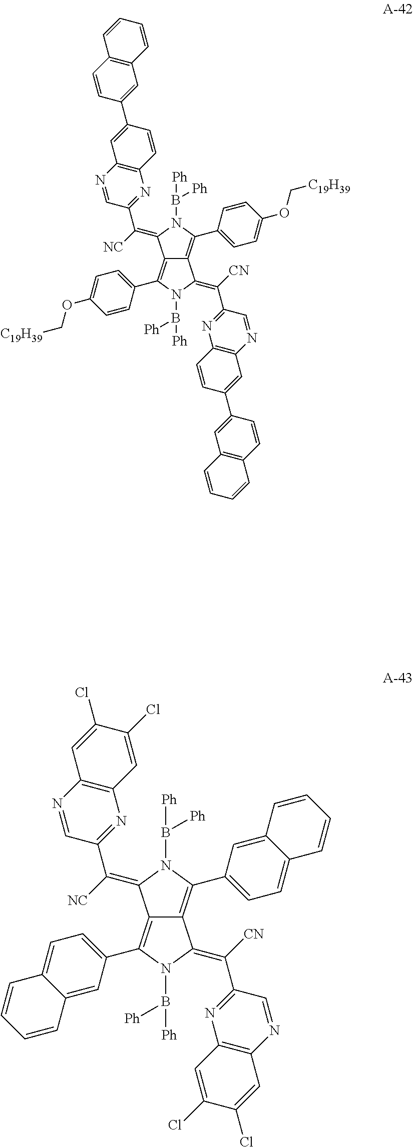

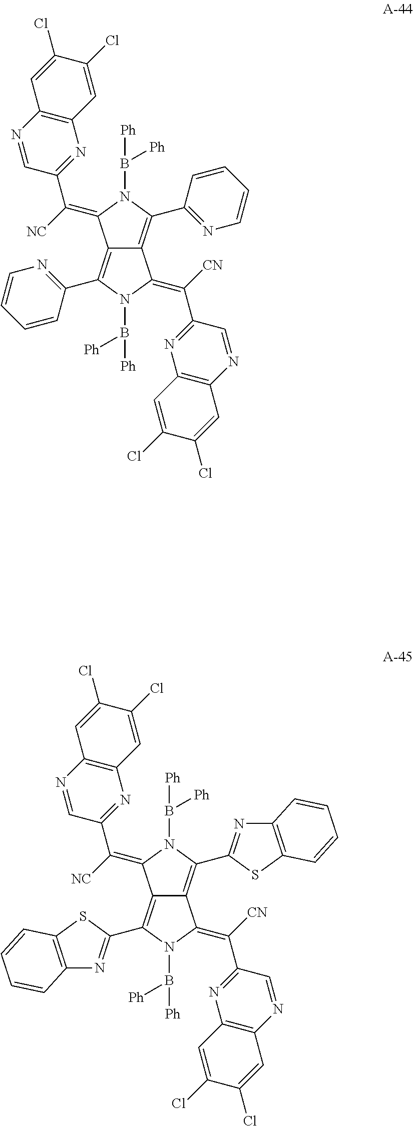 [SMILES: N#C/C(c1cnc2cc(Cl)c(Cl)cc2n1)=c1\c2c(-c3ccccn3)n(B(c3ccccc3)c3ccccc3)/c(=C(/C#N)c3cnc4cc(Cl)c(Cl)cc4n3)c2c(-c2ccccn2)n1B(c1ccccc1)c1ccccc1 ; N#C/C(c1cnc2cc(Cl)c(Cl)cc2n1)=c1\c2c(-c3nc4ccccc4s3)n(B(c3ccccc3)c3ccccc3)/c(=C(/C#N)c3cnc4cc(Cl)c(Cl)cc4n3)c2c(-c2nc3ccccc3s2)n1B(c1ccccc1)c1ccccc1]

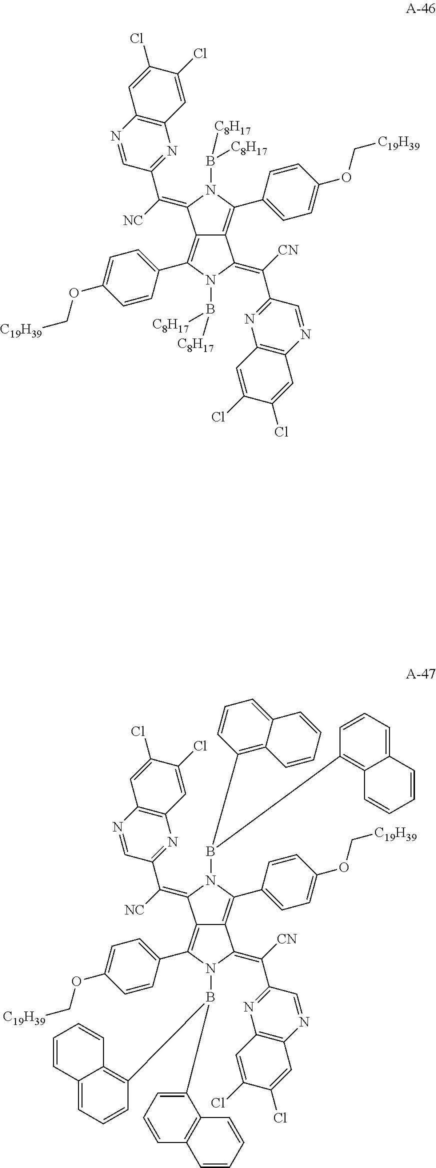

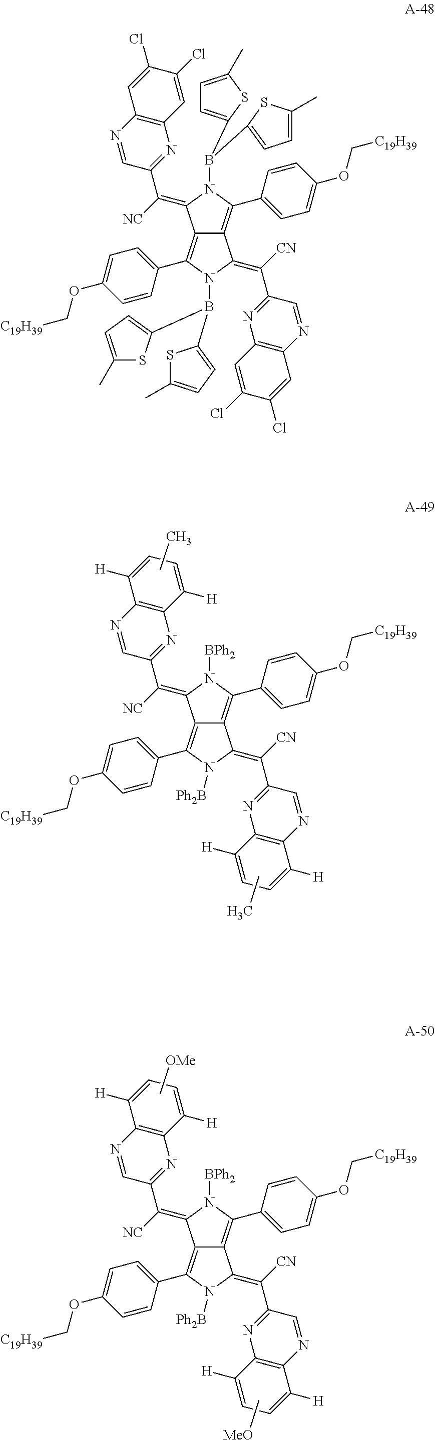

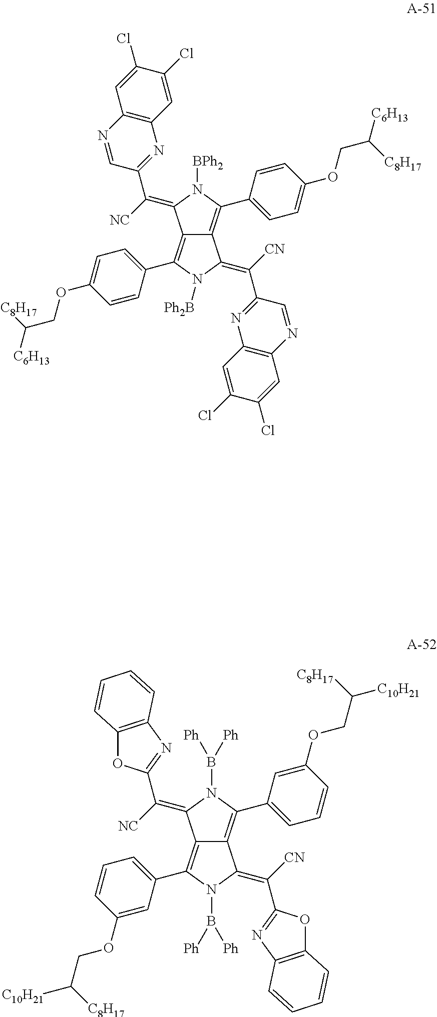

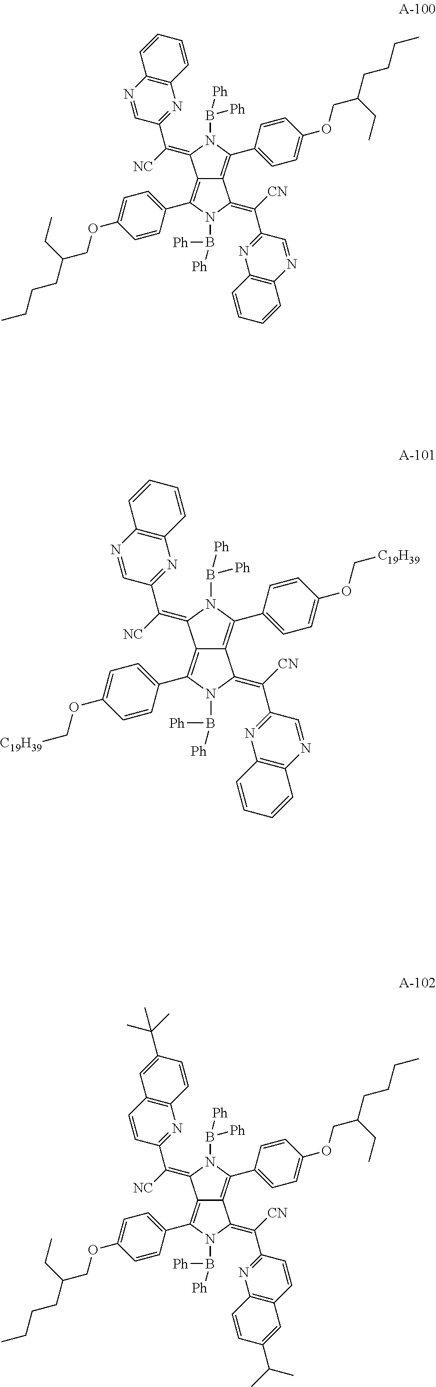

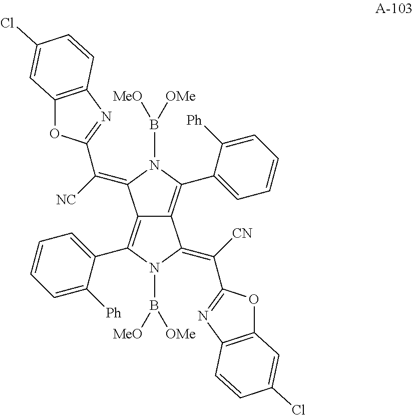 [SMILES: COB(OC)n1c(-c2ccccc2-c2ccccc2)c2/c(=C(\C#N)c3nc4ccc(Cl)cc4o3)n(B(OC)OC)c(-c3ccccc3-c3ccccc3)c2/c1=C(\C#N)c1nc2ccc(Cl)cc2o1]

<<<<Compound Represented by Formula 3 (Cyanine Compound)>>>>

In Formula 3, Z¹ and Z² each independently represent a non-metallic atomic group necessary for forming a five-membered or six-membered nitrogen-containing heterocyclic ring that may be condensed.

Another heterocyclic ring, aromatic ring, or aliphatic ring may be condensed with the nitrogen-containing heterocyclic ring. The nitrogen-containing heterocyclic ring is preferably a five-membered ring, and a structure in which a benzene ring or a naphthalene ring is condensed with a five-membered nitrogen-containing heterocyclic ring is more preferable. Specific examples of the nitrogen-containing heterocyclic ring include an oxazole ring, an isoxazole ring, a benzoxazole ring, a naphthxazole ring, an oxazolocarbazole ring, an oxazolodibenzofuran ring, a thiazole ring, a benzothiazole ring, a naphthothiazole ring, an indolenine ring, a benzoindolenine ring, an imidazole ring, a benzimidazole ring, a naphthoimidazole ring, a quinoline ring, a pyridine ring, a pyrrolopyridine ring, a furopyrrole ring, an indolizine ring, an imidazoquinoxaline ring, and a quinoxaline ring. A quinoline ring, an indolenine ring, a benzoindolenine ring, a benzoxazole ring, a benzothiazole ring, and a benzimidazole ring are preferable, and an indolenine ring, a benzothiazole ring, and a benzimidazole ring are particularly preferable.

The nitrogen-containing heterocyclic ring and the ring condensed therewith may have a substituent. Examples of the substituent include a halogen atom, a cyano group, a nitro group, an alkyl group, an alkenyl group, an alkynyl group, an aralkyl group, an aryl group, a heteroaryl group, —OR^{c1}, —COR^{c2}, —COOR^{c3}, —OCOR^{c4}, —NR^{c5}R^{c6}, —NHCOR^{c7}, —CONR^{c8}R^{c9}, —NHCONR^{c10}R^{c11}, —NHCOOR^{c12}, —SR^{c13}, —SO₂R^{c14}, —SO₂OR^{c15}, —NHSO₂R^{c16}, and —SO₂NR^{c17}R^{c18}. R^{c1} to R^{c18} each independently represent a hydrogen atom, an alkyl group, an alkenyl group, an alkynyl group, an aryl group, or a heteroaryl group. In a case where R^{c3} in —COOR^{c3} is a hydrogen atom (that is, a carboxyl group), the hydrogen atom may be dissociated or the group may be in a state of salt. In a case where R^{c15} in —SO₂OR^{c15} is a hydrogen atom (that is, a sulfo group), the hydrogen atom may be dissociated or the group may be in a state of salt.

Examples of the halogen atom include a fluorine atom, a chlorine atom, a bromine atom, and an iodine atom.

The number of carbon atoms of the alkyl group is preferably 1 to 20, more preferably 1 to 12, and particularly preferably 1 to 8. The alkyl group may be linear, branched, or cyclic. The alkyl group may be unsubstituted or may have a substituent. Examples of the substituent include a halogen atom, a hydroxyl group, a carboxyl group, a sulfo group, an alkoxy group, and an amino group. A carboxyl group and a sulfo group are preferable, and a sulfo group is particularly preferable. A hydrogen atom in a carboxyl group and a sulfo group may be dissociated, or the carboxyl group and the sulfo group may be in a state of salt.

The number of carbon atoms of the alkenyl group is preferably 2 to 20, more preferably 2 to 12, and particularly preferably 2 to 8. The alkenyl group may be linear, branched, or cyclic. The alkenyl group may be unsubstituted or may have a substituent. Examples of the substituent include the above-described substituents that the alkyl group may have, and their preferable ranges are also similar.

The number of carbon atoms of the alkynyl group is preferably 2 to 20, more preferably 2 to 12, and particularly preferably 2 to 8. The alkynyl group may be linear, branched, or cyclic. The alkynyl group may be unsubstituted or may have a substituent. Examples of the substituent include the above-described substituents that the alkyl group may have, and their preferable ranges are also similar.

The number of carbon atoms of the aryl group is preferably 6 to 25, more preferably 6 to 15, and most preferably 6 to 10. The aryl group may be unsubstituted or may have a substituent. Examples of the substituent include the above-described substituents that the alkyl group may have, and their preferable ranges are also similar.

The alkyl portion of the aralkyl group is the same as the alkyl group. The aryl portion of the aralkyl group is the same as the aryl group. The number of carbon atoms of the aralkyl group is preferably 7 to 40, more preferably 7 to 30, and even more preferably 7 to 25.

The heteroaryl group is preferably monocyclic or fused, more preferably monocyclic or fused with a fused number of 2 to 8, and even more preferably monocyclic or fused with a fused number of 2 to 4. The number of hetero atoms constituting the ring of the heteroaryl group is preferably 1 to 3. As the hetero atom constituting the ring of the heteroaryl group, a nitrogen atom, an oxygen atom, or a sulfur atom is preferable. The heteroaryl group is preferably a five-membered ring or a six-membered ring. The number of carbon atoms constituting the ring of the heteroaryl group is preferably 3 to 30, more preferably 3 to 18, and even more preferably 3 to 12. The heteroaryl group may be unsubstituted or may have a substituent. Examples of the substituent include the above-described substituents that the alkyl group may have, and their preferable ranges are also similar.

In Formula 3, R¹⁰¹ and R¹⁰² each independently represent an alkyl group, an alkenyl group, an alkynyl group, an aralkyl group, or an aryl group. Examples of each of the alkyl group, the alkenyl group, the alkynyl group, the aralkyl group, and the aryl group include those in the description of the substituent, and their preferable ranges are also similar. The alkyl group, the alkenyl group, the alkynyl group, the aralkyl group, and the aryl group may have a substituent or may be unsubstituted. Examples of the substituent include a halogen atom, a hydroxyl group, a carboxyl group, a sulfo group, an alkoxy group, and an amino group. A carboxyl group and a sulfo group are preferable, and a sulfo group is particularly preferable. A hydrogen atom in a carboxyl group and a sulfo group may be dissociated, or the carboxyl group and the sulfo group may be in a state of salt.

In Formula 3, L¹ represents a methine chain composed of an odd number of methines. L¹ is preferably a methine chain composed of three, five, or seven methine groups.

The methine group may have a substituent. The methine group having a substituent is preferably a central methin group (at a meso position). Specific examples of the substituent include a substituent that the nitrogen-containing heterocyclic ring of Z¹ or Z² may have and a group represented by Formula (a). In addition, two substituents of the methine chain may be bonded to form a five- or six-membered ring.

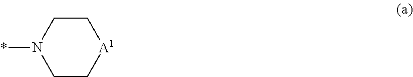

In Formula (a), * represents a connecting portion to a methine chain, and A¹ represents an oxygen atom or a sulfur atom.

In Formula 3, a and b each independently represent 0 or 1. In a case where a is 0, a carbon atom and a nitrogen atom are bonded by a double bond, and in a case where b is 0, a carbon atom and a nitrogen atom are bonded by a single bond. It is preferable that both a and b are 0. In a case where both a and b are 0, Formula 3 is represented as follows.

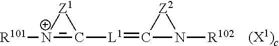

In Formula 3, in a case where a site represented by Cy in the formula is a cationic portion, X¹ represents an anion, and c represents the number necessary for keeping a balance of electric charges. Examples of the anion include halide ions (Cl⁻, Br⁻, and I⁻), p-toluenesulfonic acid ions, ethyl sulfate ions, PF₆⁻, BF₄⁻, ClO₄⁻, tris(halogenoalkylsulfonyl)methide anions (for example, (CF₃SO₂)₃C⁻), di(halogenoalkylsulfonyl)imide anions (for example, (CF₃SO₂)₂N⁻), and tetracyanoborate anions.

In Formula 3, in a case where a site represented by Cy in the formula is an anionic portion, X¹ represents a cation, and c represents the number necessary for keeping a balance of electric charges. Examples of the cation include alkali metal ions (Li⁺, Na⁺, K⁺, and the like), alkaline earth metal ions (Mg²⁺, Ca²⁺, Ba²⁺, Sr²⁺, and the like), transition metal ions (Age, Fe²⁺, Co²⁺, Ni²⁺, Cu²⁺, Zn²⁺, and the like), other metal ions (Al³⁺ and the like), ammonium ions, triethylammonium ions, tributylammonum ions, pyridinium ions, tetrabutylammonium ions, guanidinium ions, tetramethylguanidinium ions, and diazabicycloundecenium. As the cation, Na⁺, K⁺, Mg²⁺, Ca²⁺, Zn²⁺, or diazabicycloundecenium is preferable.

In Formula 3, in a case where the electric charge of a site represented by Cy in the formula is neutralized in the molecule, X¹ does not exist. That is, c is 0.

The compound represented by Formula 3 is preferably a compound represented by the following formula (3-1) or (3-2). This compound has excellent heat resistance.

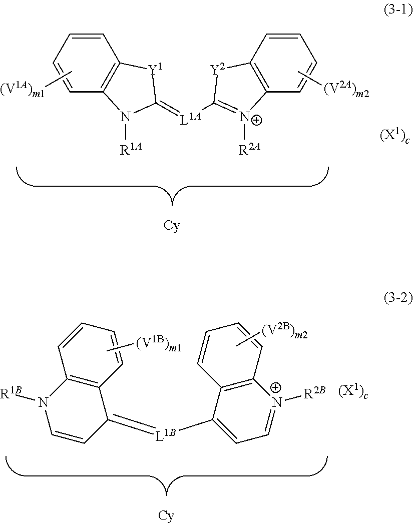

In Formulae (3-1) and (3-2), R^{1A}, R^{2A}, R^{1B}, and R^{2B} each independently represent an alkyl group, an alkenyl group, an alkynyl group, an aralkyl group, or an aryl group.

L^{1A} and L^{1B} each independently represent a methine chain composed of an odd number of methines.

Y¹ and Y² each independently represent —S—, —O—, —NR^{X1}—, or —CR^{X2}R^{X3}—.

R^{X1}, R^{X2}, and R^{X3} each independently represent a hydrogen atom or an alkyl group.

V^{1A}, V^{2A}, V^{1B}, and V^{2B} each independently represent a halogen atom, a cyano group, a nitro group, an alkyl group, an alkenyl group, an alkynyl group, an aralkyl group, an aryl group, a heteroaryl group, —OR^{c1}, —COR^{c2}, —COOR^{c3}, —OCOR^{c4}, —NR^{c5}R^{c6}, —NHCOR^{c7}, —CONR^{c8}R^{c9}, —NHCONR^{c10}R^{c11}, —NHCOOR^{c12}, —SR^{c13}, —SO₂R^{c14}, —SO₂OR^{c15}, —NHSO₂R^{c16}, or —SO₂NR^{c17}R^{c18}. V^{1A}, V^{2A}, V^{1B}, and V^{2B} may form a fused ring.

R^{c1} to R^{c18} each independently represent a hydrogen atom, an alkyl group, an alkenyl group, an alkynyl group, an aryl group, or a heteroaryl group.

In a case where R^{c3} in —COOR^{c3} or R^{c15} in —SO₂OR^{c15} is a hydrogen atom, the hydrogen atom may be dissociated or the group may be in a state of salt.

m1 and m2 each independently represent 0, 1, 2, 3, or 4.

In a case where a site represented by Cy in the formula is a cationic portion, X¹ represents an anion, and c represents the number necessary for keeping a balance of electric charges.

In a case where a site represented by Cy in the formula is an anionic portion, X¹ represents a cation, and c represents the number necessary for keeping a balance of electric charges.

In a case where the electric charge of a site represented by Cy in the formula is neutralized in the molecule, X¹ does not exist.

The groups represented by R^{1A}, R^{2A}, R^{1B}, and R^{2B} are synonymous with the alkyl group, the alkenyl group, the alkynyl group, the aralkyl group, and the aryl group in the description of R¹⁰¹ and R¹⁰² in Formula 3, and their preferable ranges are also similar. These groups may be unsubstituted or may have a substituent. Examples of the substituent include a halogen atom, a hydroxyl group, a carboxyl group, a sulfo group, an alkoxy group, and an amino group. A carboxyl group and a sulfo group are preferable, and a sulfo group is particularly preferable. A hydrogen atom in a carboxyl group and a sulfo group may be dissociated, or the carboxyl group and the sulfo group may be in a state of salt.

In a case where each of R^{1A}, R^{2A}, R^{1B}, and R^{2B} represents an alkyl group, these are preferably linear alkyl groups.

Y¹ and Y² each independently represent —S—, —O—, —NR^{X1}—, or —CR^{X2}R^{X3}—, and —NR^{X1}— is preferable.

R^{X1}, R^{X2}, and R^{X3} each independently represent a hydrogen atom or an alkyl group, and an alkyl group is preferable. The number of carbon atoms of the alkyl group is preferably 1 to 10, more preferably 1 to 5, and particularly preferably 1 to 3. The alkyl group may be linear, branched, or cyclic. The alkyl group is preferably linear or branched, and particularly preferably linear. As the alkyl group, a methyl group or an ethyl group is particularly preferable.

L^{1A} and L^{1B} are synonymous with L¹ in Formula 3, and their preferable ranges are also similar.

The groups represented by V^{1A}, V^{2A}, V^{1B}, and V^{2B} are synonymous with the ranges in the description of the substituent that the nitrogen-containing heterocyclic ring of Z¹ or Z² in Formula 3 may have, and their preferable ranges are also similar.

m1 and m2 each independently represent 0, 1, 2, 3, or 4, and 0 to 2 are preferable.

The anion and the cation represented by X¹ are synonymous with the ranges in the description of X¹ in Formula 3, and their preferable ranges are also similar.

Examples of the compound represented by Formula 3 include the following compounds. The examples further include the compounds described in paragraphs 0044 and 0045 of JP2009-108267A, and the contents thereof are incorporated into this specification. In the following tables, Me represents a methyl group, Et represents an ethyl group, Bu represents a butyl group, Bn represents a benzyl group, Ph represents a phenyl group, PRS represents C₃H₆SO³⁻, and BUS represents C₄H₉SO³⁻.

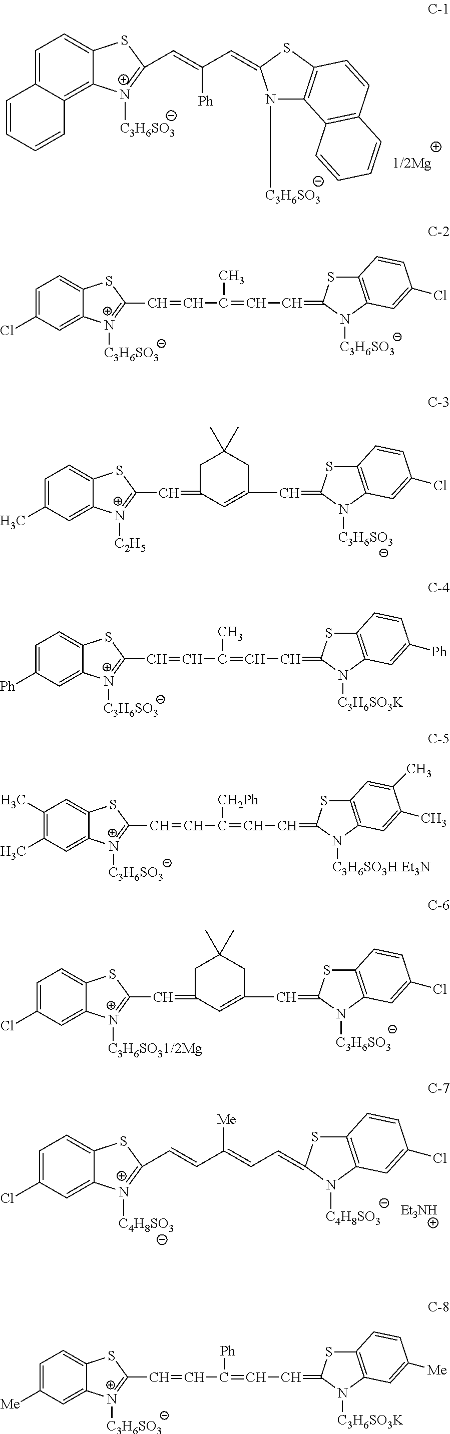

TABLE 2

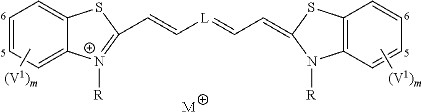

| Compound | | | | | |
|---|---|---|---|---|---|
| No. | R | L | V¹ | m | M |
| C-9 | PRS | 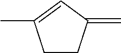 | 5:Cl | 1 | K |
| C-10 | PRS | 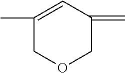 | 5:Cl | 1 | K |
| C-11 | PRS | 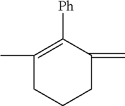 | 6:Cl | 1 | K |
| C-12 | BUS | 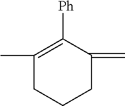 | 5:COOH | 1 | K |
| C-13 | PRS | 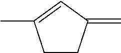 | 5:Cl | 1 | Na |
| C-14 | PRS | 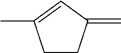 | 5:Cl | 1 | 1/2 Mg |

TABLE 3

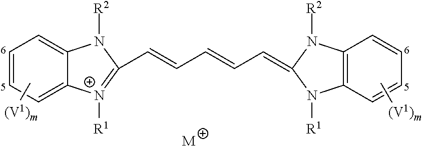

| Compound | | | | | |
|---|---|---|---|---|---|
| No. | R1 | R2 | V¹ | m | M |
| C-15 | PRS | Et | 5:Cl | 2 | Na |
| | | | 6:Cl | | |
| C-16 | PRS | Me | 5:Cl | 2 | K |
| | | | 6:Cl | | |
| C-17 | BUS | Et | 5:Cl | 2 | K |
| | | | 6:Cl | | |
| C-18 | BUS | CF₃CH₂ | 5:Cl | 2 | 1/2 Ca |
| | | | 6:Cl | | |
| C-19 | PRS | Et | 5:Cl | 2 | K |
| | | | 6:Cl | | |
| C-20 | PRS | Et | 5:Cl | 2 | 1/2 Mg |
| | | | 6:Cl | | |
| C-21 | BUS | Et | 5:Cl | 2 | Na |
| | | | 6:Cl | | |
| C-22 | PRS | Me | 5:Cl 6:Cl | 2 | 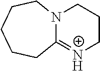 |
| C-23 | PRS | 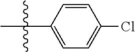 [SMILES: *c1ccc(Cl)cc1] | 5:Cl 6:Cl | 2 | Na |

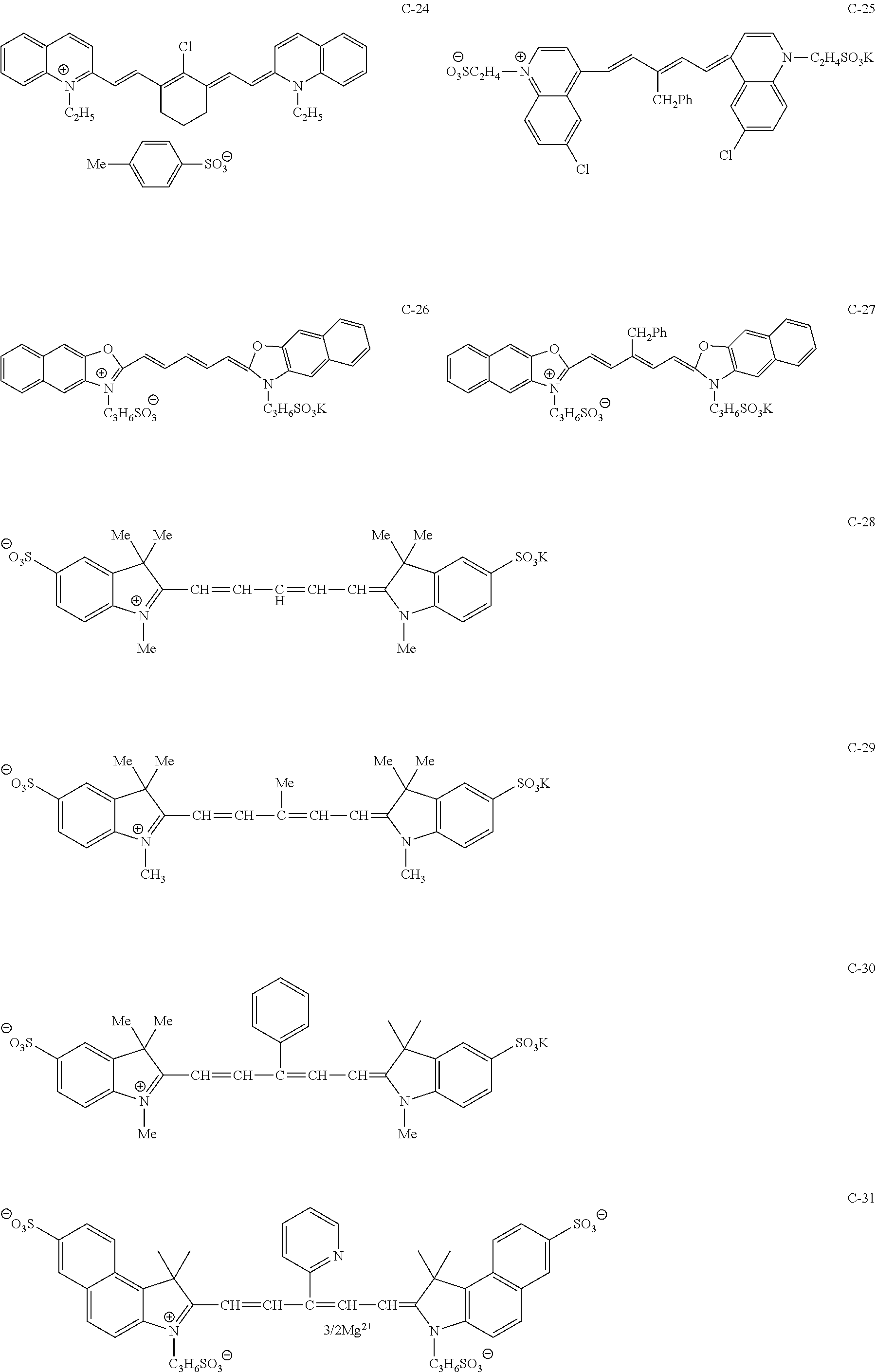

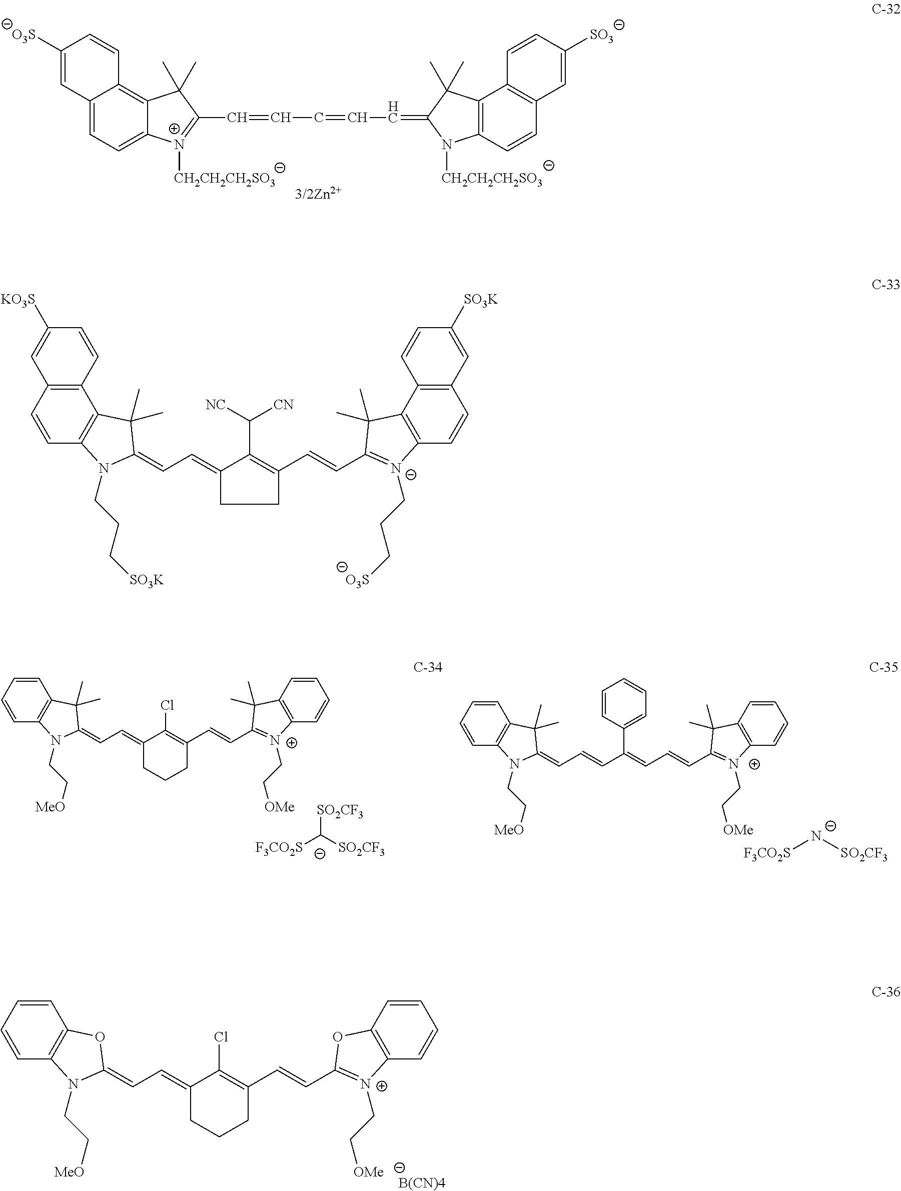

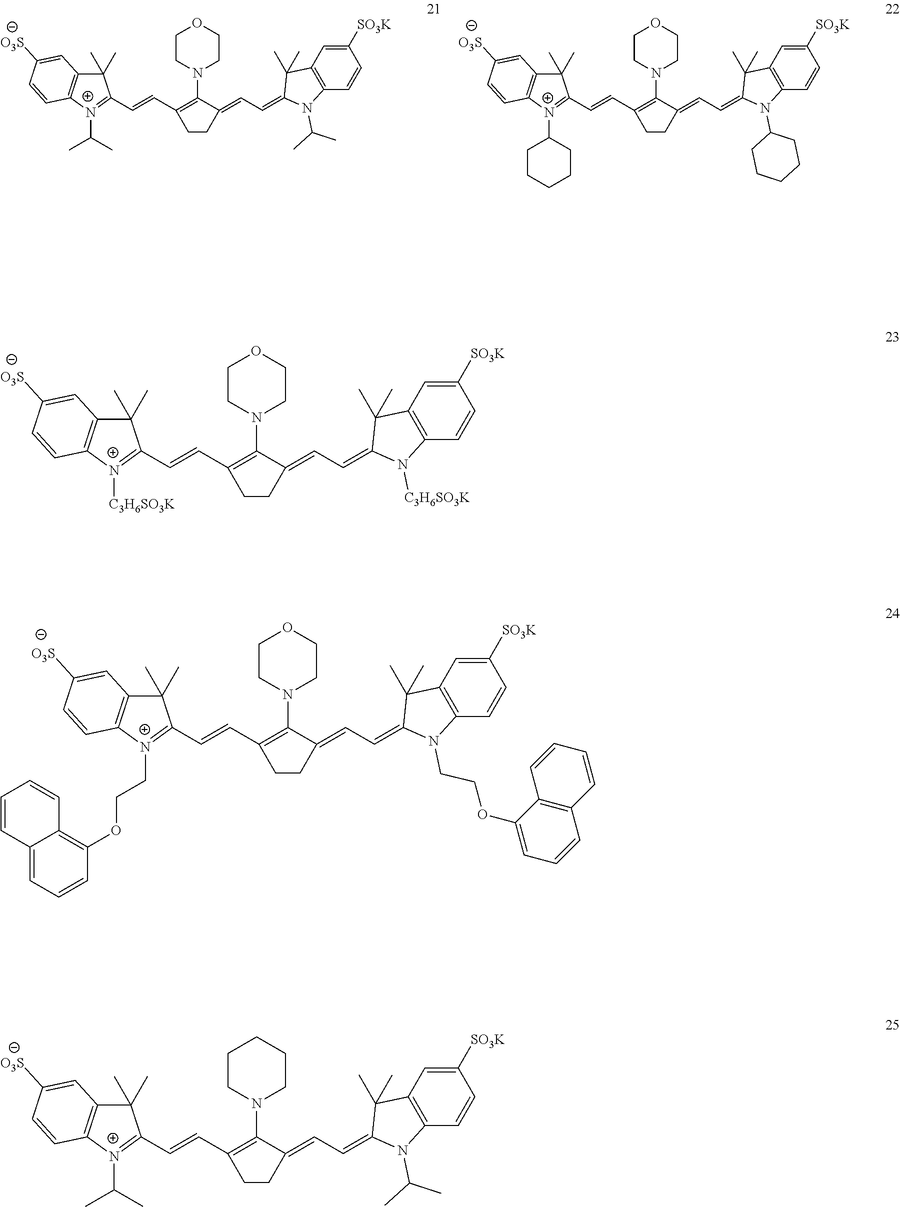

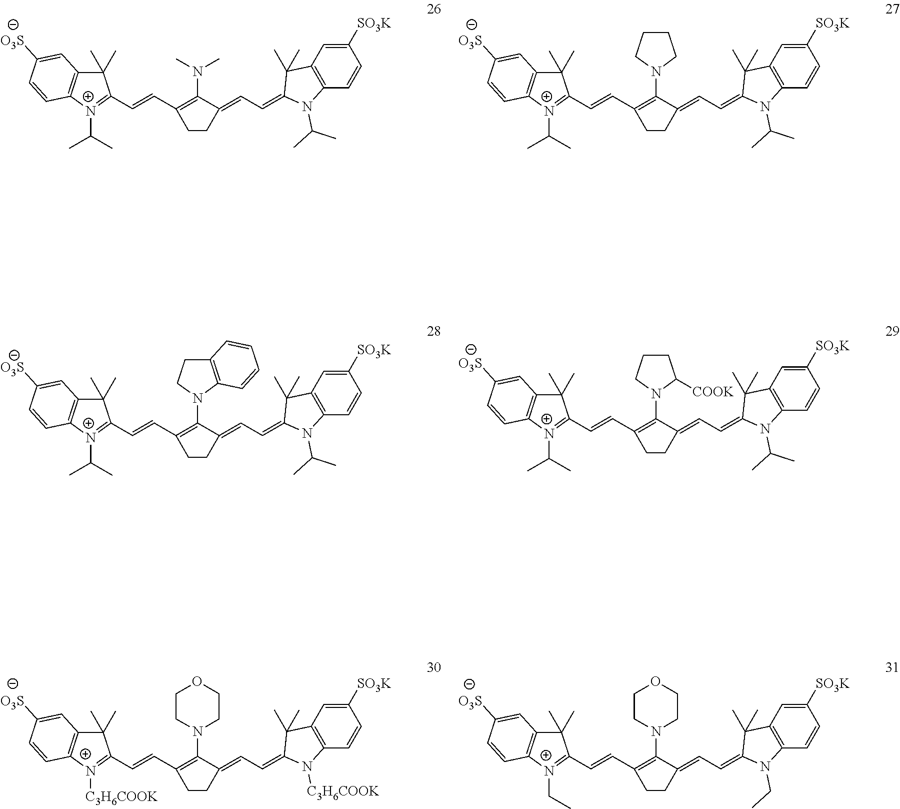

The compound represented by Formula 3 can be easily synthesized with reference to “Heterocyclic Compounds-Cyanine Dyes and Related Compounds” written by F. M. Harmer, John Wiley & Sons, New York, London, published in 1964, “Heterocyclic Compounds-Special topics in heterocyclic chemistry” written by D. M. Sturmer, Chapter 18, Section 14, pages 482 to 515, John Wiley & Sons, New York, London, published in 1977, “Rodd's Chemistry of Carbon Compounds” 2nd. Ed. vol. IV, part B, published in 1977, chapter 15, pages 369 to 422, Elsevier Science Publishing Company Inc., New York, JP1994-313939A (JP-H06-313939A), JP1993-88293A (JP-H05-88293A), and the like.

<<<<Resin, Gelatin, and Polymerizable Compound>>>>

The infrared absorbing composition preferably contains at least one selected from a resin, gelatin, and a polymerizable compound, and particularly preferably contains at least one selected from gelatin and a polymerizable compound. According to this aspect, an infrared absorbing layer having excellent heat resistance and solvent resistance is easily manufactured. In addition, in a case where a polymerizable compound is used, the polymerizable compound is preferably used in combination with a photopolymerization initiator.

(Resin)

Examples of the resin include a (meth)acrylic resin, an epoxy resin, an ene-thiol resin, a polycarbonate resin, a polyether resin, a polyarylate resin, a polysulfone resin, a polyethersulfone resin, a polyphenylene resin, a polyarylene ether phosphine oxide resin, a polyimide resin, a polyamide-imide resin, a polyolefin resin, a cyclic olefin resin, and a polyester resin. These resins may be used singly, or as a mixture of two or more types thereof.

The weight average molecular weight (Mw) of the resin is preferably 2,000 to 2,000,000. The upper limit is preferably not greater than 1,000,000, and more preferably not greater than 500,000. The lower limit is preferably not less than 3,000, and more preferably not less than 5,000.

In a case of an epoxy resin, the weight average molecular weight (Mw) of the epoxy resin is preferably not less than 100, and more preferably 200 to 2,000,000. The upper limit is preferably not greater than 1,000,000, and more preferably not greater than 500,000. The lower limit is preferably not less than 100, and more preferably not less than 200.

Regarding the resin, a 5% thermal mass-reduction temperature increased at 20° C./min from 25° C. is preferably 200° C. or higher, and more preferably 260° C. or higher.

Examples of the (meth)acrylic resin include a polymer including a repeating unit derived from a (meth)acrylic acid and/or its esters. Specific examples thereof include a polymer obtained by polymerizing at least one selected from a (meth)acrylic acid, (meth)acrylic acid esters, (meth)acrylamide, and (meth)acrylonitrile.

Examples of the polyester resin include polymers obtained by the reaction between polyols (for example, ethylene glycol, propylene glycol, glycerin, and trimethylolpropane) and polybasic acids (for example, aromatic dicarboxylic acids such as a terephthalic acid, an isophthalic acid, and a naphthalene dicarboxylic acid, aromatic dicarboxylic acids in which a hydrogen atom of these aromatic rings is substituted with a methyl group, an ethyl group, a phenyl group, or the like, aliphatic dicarboxylic acids having 2 to 20 carbon atoms such as an adipic acid, a sebacic acid, and a dodecanedicarboxylic acid, and alicyclic dicarboxylic acids such as a cyclohexane dicarboxylic acid), and polymers (for example, polycaprolactone) obtained by ring-opening polymerization of circular ester compounds such as a caprolactone monomer.

Examples of the epoxy resin include bisphenol A epoxy resins, bisphenol F epoxy resins, phenol novolac epoxy resins, cresol novolac epoxy resins, and aliphatic epoxy resins. Commercially available products thereof are as follows.

Examples of the bisphenol A epoxy resins include JER 827, JER 828, JER 834, JER 1001, JER 1002, JER 1003, JER 1055, JER 1007, JER 1009, JER 1010 (all manufactured by Mitsubishi Chemical Corporation), EPICLON 860, EPICLON 1050, EPICLON 1051, and EPICLON 1055 (all manufactured by DIC Corporation).

Examples of the bisphenol F epoxy resins include JER 806, JER 807, JER 4004, JER 4005, JER 4007, JER 4010 (all manufactured by Mitsubishi Chemical Corporation), EPICLON 830, EPICLON 835 (all manufactured by DIC Corporation), LCE-21, and RE-602S (all manufactured by Nippon Kayaku Co., Ltd.).

Examples of the phenol novolac epoxy resins include JER 152, JER 154, JER 157S70, JER 157S65 (all manufactured by Mitsubishi Chemical Corporation), EPICLON N-740, EPICLON N-770, and EPICLON N-775 (all manufactured by DIC Corporation).

Examples of the cresol novolac epoxy resins include EPICLON N-660, EPICLON N-665, EPICLON N-670, EPICLON N-673, EPICLON N-680, EPICLON N-690, EPICLON N-695 (all manufactured by DIC Corporation), and EOCN-1020 (all manufactured by Nippon Kayaku Co., Ltd.).

Examples of the aliphatic epoxy resins include ADEKA RESIN EP-4080S, ADEKA RESIN EP-4085S, ADEKA RESIN EP-4088S (all manufactured by ADEKA Corporation), CELLOXIDE 2021P, CELLOXIDE 2081, CELLOXIDE 2083, CELLOXIDE 2085, EHPE3150, EPOLEAD PB 3600, EPOLEAD PB 4700 (all manufactured by DAICEL Corporation), DENACOL EX-212L, EX-214L, EX-216L, EX-321L, and EX-850L (all manufactured by Nagase ChemteX Corporation).

ADEKA RESIN EP-4000S, ADEKA RESIN EP-4003S, ADEKA RESIN EP-4010S, ADEKA RESIN EP-4011S (all manufactured by ADEKA Corporation), NC-2000, NC-3000, NC-7300, XD-1000, EPPN-501, EPPN-502 (all manufactured by ADEKA Corporation), and JER 1031S (manufactured by Mitsubishi Chemical Corporation) are also included.

The resin may have an acid group. Examples of the acid group include a carboxyl group, a phosphate group, a sulfonate group, and a phenolic hydroxyl group. These acid groups may be used singly, or two or more types thereof may be used.

As the resin having an acid group, a polymer having a carboxyl group on a side chain is preferable, and examples thereof include a methacrylic acid copolymer, an acrylic acid copolymer, an itaconic acid copolymer, a crotonic acid copolymer, a maleic acid copolymer, a partially esterified maleic acid copolymer, alkali-soluble phenolic resins such as a novolac resin, acid cellulose derivatives having a carboxyl group on a side chain, and polymers having a hydroxyl group with an acid anhydride added thereto. Particularly, copolymers of a (meth)acrylic acid with other monomers copolymerizable with the (meth)acrylic acid are preferable. Examples of other monomers copolymerizable with a (meth)acrylic acid include alkyl (meth)acrylate, aryl (meth)acrylate, and a vinyl compound. Examples of the alkyl (meth)acrylate and the aryl (meth)acrylate include methyl (meth)acrylate, ethyl (meth)acrylate, propyl (meth)acrylate, butyl (meth)acrylate, isobutyl (meth)acrylate, pentyl (meth)acrylate, hexyl (meth)acrylate, octyl (meth)acrylate, phenyl (meth)acrylate, benzyl (meth)acrylate, tolyl (meth)acrylate, naphthyl (meth)acrylate, and cyclohexyl (meth)acrylate. Examples of the vinyl compound include styrene, α-methylstyrene, vinyl toluene, glycidyl methacrylate, acrylonitrile, vinyl acetate, N-vinylpyrrolidone, tetrahydrofurfuryl methacrylate, polystyrene macromonomer, and polymethyl methacrylate macromonomer. Examples of other monomers further include N-phenylmaleimide and N-cyclohexylmaleimide as a N-substituted maleimide monomer described in JP1998-300922A (JP-H10-300922A). These other monomers copolymerizable with a (meth)acrylic acid may be used singly, or two or more types thereof may be used.

As the resin having an acid group, benzyl (meth)acrylate/(meth)acrylic acid copolymers, benzyl (meth)acrylate/(meth)acrylic acid/2-hydroxyethyl (meth)acrylate copolymers, and multicomponent copolymers consisting of benzyl (meth)acrylate/(meth)acrylic acid/other monomers can be preferably used. In addition, 2-hydroxypropyl (meth)acrylate/polystyrene macromonomer/benzyl methacrylate/methacrylic acid copolymers, 2-hydroxy-3-phenoxypropyl acrylate/polymethyl methacrylate macromonomer/benzyl methacrylate/methacrylic acid copolymers, 2-hydroxyethyl methacrylate/polystyrene macromonomer/methyl methacrylate/methacrylic acid copolymers, 2-hydroxyethyl methacrylate/polystyrene macromonomer/benzyl methacrylate/methacrylic acid copolymers, and the like that are obtained by copolymerizing a 2-hydroxyethyl (meth)acrylate as described in JP1995-140654A (JP-H7-140654A) can also be preferably used.

The resin having an acid group preferably includes a polymer (a) obtained by polymerizing a monomer component including a compound represented by Formula (ED1) and/or a compound represented by Formula (ED2) (hereinafter, these compounds may be referred to as “ether dimer”).

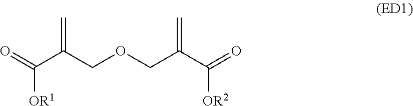

In Formula (ED1), R¹ and R² each independently represent a hydrocarbon group having 1 to 25 carbon atoms that may have a hydrogen atom or a substituent.

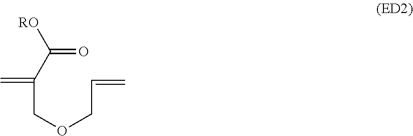

In Formula (ED2), R represents a hydrogen atom or an organic group having 1 to 30 carbon atoms. Regarding specific examples of Formula (ED2), the description in JP2010-168539A can be referred to.

In Formula (ED1), the hydrocarbon group having 1 to 25 carbon atoms that may have a substituent, represented by R¹ and R², is not particularly limited, and examples thereof include linear or branched alkyl groups such as methyl, ethyl, n-propyl, isopropyl, n-butyl, isobutyl, tert-butyl, tert-amyl, stearyl, lauryl, and 2-ethylhexyl; aryl groups such as phenyl; alicyclic groups such as cyclohexyl, tert-butylcyclohexyl, dicyclopentadienyl, tricyclodecanyl, isobornyl, adamantyl, and 2-methyl-2-adamantyl; alkyl groups substituted with alkoxy such as 1-methoxyethyl and 1-ethoxyethyl; and alkyl groups substituted with an aryl group such as benzyl. Among these, particularly, a substituent of a primary or secondary carbon that hardly separates due to an acid or heat, such as methyl, ethyl, cyclohexyl, or benzyl, is preferable in view of heat resistance.

Regarding specific examples of the ether dimer, for example, paragraph 0317 of JP2013-29760A can be referred to, and the contents thereof are incorporated into this specification. The ether dimer may be used singly, or two or more types thereof may be used. The structure derived from the compound represented by Formula (ED) may be copolymerized with other monomers.

The resin having an acid group may include a repeating unit derived from a compound represented by Formula (X).

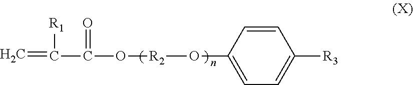

In Formula (X), R₁ represents a hydrogen atom or a methyl group. R₂ represents an alkylene group having 2 to 10 carbon atoms. R₃ represents a hydrogen atom or an alkyl group having 1 to 20 carbon atoms that may include a benzene ring. n represents an integer of 1 to 15.

In Formula (X), the number of carbon atoms of the alkylene group of R₂ is preferably 2 or 3. The number of carbon atoms of the alkyl group of R₃ is 1 to 20, and is preferably 1 to 10. The alkyl group of R₃ may include a benzene ring. Examples of the alkyl group represented by R₃ that includes a benzene ring include a benzyl group and a 2-phenyl(iso)propyl group.

Specific examples of the resin having an acid group include the following structures.

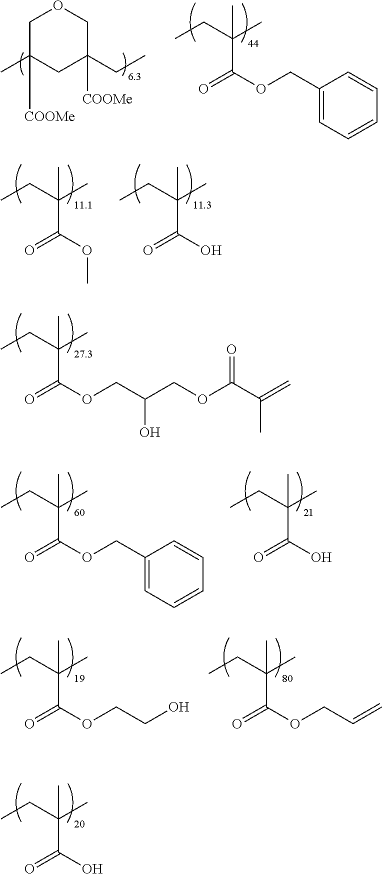

Regarding the resin having an acid group, the description in paragraphs 0558 to 0571 of JP2012-208494A ([0685] to [0700] of US2012/0235099A corresponding thereto) and the description in paragraphs 0076 to 0099 of JP2012-198408A can be referred to, and the contents thereof are incorporated into this specification.

The acid value of the resin having an acid group is preferably 30 to 200 mgKOH/g. The lower limit is preferably not less than 50 mgKOH/g, and more preferably not less than 70 mgKOH/g. The upper limit is preferably not greater than 150 mgKOH/g, and more preferably not greater than 120 mgKOH/g.

In addition, the resin may have a polymerizable group. In a case where the resin has a polymerizable group, it is possible to form a hard film.

Examples of the polymerizable group include a (meth)allyl group and a (meth)acryloyl group. Examples of the resin containing a polymerizable group include DIANAL NR series (manufactured by Mitsubishi Rayon Co., Ltd.), Photomer 6173 (COOH-containing polyurethane acrylic oligomer, manufactured by Diamond Shamrock Co., Ltd.), VISCOAT R-264, KS RESIST 106 (all manufactured by OSAKA ORGANIC CHEMICAL INDUSTRY LTD.), CYCLOMER P series (for example, ACA230AA), PLACCEL CF 200 series (all manufactured by Daicel Chemical Industries, Ltd.), Ebecryl 3800 (manufactured by Daicel-UCB Co., Ltd.), and ACRYCURE RD-F8 (manufactured by NIPPON SHOKUBAI CO., LTD.). The above-described epoxy resins are also included.

In the infrared absorbing composition, the content of the resin is preferably 1 to 80 mass % with respect to the total solid content of the infrared absorbing composition. The lower limit is preferably not less than 5 mass %, and more preferably not less than 10 mass %. The upper limit is preferably not greater than 60 mass %, and more preferably not greater than 50 mass %.

(Gelatin)

The infrared absorbing composition may contain gelatin. In a case where gelatin is contained, an infrared absorbing layer having excellent heat resistance is easily formed. The detailed mechanism thereof is not clear, but the reason for this is presumed to be that aggregates are easily formed by the infrared absorbing agent and the gelatin. Particularly, in a case where a cyanine compound is used as the infrared absorbing agent, an infrared absorbing layer having excellent heat resistance is easily formed.

In the invention, gelatin is classified into acid-treated gelatin and alkali-treated gelatin (a lime treatment or the like) depending on the synthesis method, and both types of gelatin can be preferably used. The molecular weight of the gelatin is preferably 10,000 to 1,000,000. In addition, denatured gelatin that has been denaturation-treated using an amino group or a carboxyl group in gelatin can also be used (for example, phthalated gelatin or the like). As the gelatin, inert gelatin (for example, Nitta Gelatin 750), phthalated gelatin (for example, Nitta Gelatin 801), and the like can be used.

In order to increase water resistance and mechanical strength of the infrared absorbing layer, gelatin is preferably cured using various compounds. A conventionally known curing agent can be used, and examples thereof include aldehyde-based compounds such as formaldehyde and glutaraldehyde, the compounds having reactive halogen as described in U.S. Pat. No. 3,288,775A and the like, the compounds having a reactive ethylenically unsaturated bond as described in U.S. Pat. No. 3,642,486A, JP1974-13563B (JP-S49-13563B), and the like, the aziridine-based compounds as described in U.S. Pat. No. 3,017,280A and the like, the epoxy-based compounds as described in U.S. Pat. No. 3,091,537A and the like, halogen-carboxylaldehydes such as a mucochloric acid, dioxanes such as dihydroxydioxane and dichlorodioxane, and inorganic hardeners such as chrome alum and zirconium sulfate.

In the infrared absorbing composition, the content of the gelatin is preferably 1 to 99 mass % with respect to the total solid content of the infrared absorbing composition. The lower limit is preferably not less than 10 mass %, and more preferably not less than 20 mass %. The upper limit is preferably not greater than 95 mass %, and more preferably not greater than 90 mass %.

(Polymerizable Compound)

The infrared absorbing composition preferably contains a polymerizable compound. Examples of the polymerizable compound include a compound having a group having an ethylenically unsaturated bond, a cyclic ether (epoxy or oxetane) group, a methylol group, or the like, and a compound having a group having an ethylenically unsaturated bond is preferable. Examples of the group having an ethylenically unsaturated bond include a vinyl group, a (meth)allyl group, and a (meth)acryloyl group.

The polymerizable compound may be monofunctional or polyfunctional, and is preferably polyfunctional (a polymerizable compound having two or more polymerizable groups). In a case where a polyfunctional compound is included, an infrared absorbing layer having a three-dimensional crosslinked material can be formed. In a case where the infrared absorbing layer has a three-dimensional crosslinked material, heat resistance and solvent resistance can be improved. The number of functional groups of the polymerizable compound is not particularly limited, but the compound is preferably bi- to octa-functional, and more preferably tri- to hexa-functional.

The polymerizable compound may have any chemical form such as a monomer, a prepolymer, an oligomer, or a mixture or polymer thereof.

The polymerizable compound is preferably a tri- to pentadeca-functional (meth)acrylate compound, and more preferably a tri- to hexa-functional (meth)acrylate compound.

The molecular weight of the polymerizable compound is preferably less than 2,000, more preferably not less than 100 and less than 2,000, and even more preferably not less than 200 and less than 2,000.

The polymerizable compound is preferably a compound including a group having an ethylenically unsaturated bond.

Regarding examples of the compound including a group having an ethylenically unsaturated bond, the description in paragraphs 0033 and 0034 of JP2013-253224A can be referred to, and the contents thereof are incorporated into this specification.

Specific preferable examples thereof include ethyleneoxy-modified pentaerythritol tetraacrylate (as a commercially available product, NK ester ATM-35E; manufactured by Shin-Nakamura Chemical Co., Ltd.), dipentaerythritol triacrylate (as a commercially available product, KAYARAD D-330; manufactured by Nippon Kayaku Co., Ltd.), dipentaerythritol tetraacrylate (as a commercially available product, KAYARAD D-320; manufactured by Nippon Kayaku Co., Ltd.), dipentaerythritol penta(meth)acrylate (as a commercially available product, KAYARAD D-310; manufactured by Nippon Kayaku Co., Ltd.), dipentaerythritol hexa(meth)acrylate (as commercially available products, KAYARAD DPHA; manufactured by Nippon Kayaku Co., Ltd., A-DPH-12E; manufactured by Shin-Nakamura Chemical Co., Ltd.), and structures in which these (meth)acryloyl groups are bonded via an ethylene glycol or a propylene glycol residue. In addition, oligomer types thereof can also be used.

In addition, the description of the polymerizable compound in paragraphs 0034 to 0038 of JP2013-253224A can be referred to, and the contents thereof are incorporated into this specification.

In addition, the polymerizable monomers described in paragraph 0477 of JP2012-208494A ([0585] of US2012/0235099A corresponding thereto) are also included, and the contents thereof are incorporated into this specification.

In addition, diglycerine ethyleneoxide (EO)-modified (meth)acrylate (as a commercially available product, M-460; manufactured by Toagosei Co., Ltd.) is preferable. Pentaerythritol tetraacrylate (manufactured by Shin-Nakamura Chemical Co., Ltd., A-TMMT) and 1,6-hexanediol diacrylate (manufactured by Nippon Kayaku Co., Ltd., KAYARAD HDDA) are also preferable. Oligomer types thereof can also be used. Examples thereof include RP-1040 (manufactured by Nippon Kayaku Co., Ltd.).

The compound including a group having an ethylenically unsaturated bond may further have an acid group such as a carboxyl group, a sulfonate group, and a phosphate group.

Examples of the compound having an acid group include an ester of an aliphatic polyhydroxy compound with an unsaturated carboxylic acid. A polyfunctional monomer allowed to have an acid group by reacting a non-aromatic carboxylic acid anhydride with an unreacted hydroxyl group of an aliphatic polyhydroxy compound is preferable. Particularly preferably, an aliphatic polyhydroxy compound is pentaerythritol and/or dipentaerythritol. Examples of commercially available products thereof include M-305, M-510, and M-520 of ARONIX series, as polybasic acid-modified acrylic oligomers manufactured by Toagosei Co., Ltd.

The acid value of the compound having an acid group is preferably 0.1 to 40 mgKOH/g. The lower limit is preferably not less than 5 mgKOH/g. The upper limit is preferably not greater than 30 mgKOH/g.

It is also preferable that the polymerizable compound is a compound having a caprolactone structure.

Regarding the compound having a caprolactone structure, the description in paragraphs 0042 to 0045 of JP2013-253224A can be referred to, and the contents thereof are incorporated into this specification.

Examples of commercially available products thereof include SR-494 that is a tetra-functional acrylate having four ethyleneoxy chains manufactured by Sartomer Inc., DPCA-60 that is a hexa-functional acrylate having six pentyleneoxy chains manufactured by Nippon Kayaku Co., Ltd., and TPA-330 that is a tri-functional acrylate having three isobutyleneoxy chains.

In addition, as the polymerizable compound, a polymerizable compound having a fluorine atom (fluorine-containing polymerizable compound) can be used. It is more preferable that the fluorine-containing polymerizable compound is a (meth)acrylate polymer having a fluorine atom.

The fluorine-containing polymerizable compound preferably has at least one selected from the group consisting of an alkylene group substituted with a fluorine atom, an alkyl group substituted with a fluorine atom, and an aryl group substituted with a fluorine atom.

The alkylene group substituted with a fluorine atom is preferably a linear, branched, or cyclic alkylene group in which at least one hydrogen atom is substituted with a fluorine atom.

The alkyl group substituted with a fluorine atom is preferably a linear, branched, or cyclic alkyl group in which at least one hydrogen atom is substituted with a fluorine atom.

The number of carbon atoms in the alkylene group substituted with a fluorine atom or in the alkyl group substituted with a fluorine atom is preferably 1 to 20, more preferably 1 to 10, and even more preferably 1 to 5.

Regarding the aryl group substituted with a fluorine atom, it is preferable that the aryl group is directly substituted with a fluorine atom, or substituted with a trifluoromethyl group.

The alkylene group substituted with a fluorine atom, the alkyl group substituted with a fluorine atom, and the aryl group substituted with a fluorine atom may further have a substituent other than a fluorine atom.

Regarding examples of the alkyl group substituted with a fluorine atom and examples of the aryl group substituted with a fluorine atom, for example, paragraphs 0266 to 0272 of JP2011-100089A can be referred to, and the contents thereof are incorporated into this specification.

The fluorine-containing polymerizable compound preferably includes a group X in which an alkylene group substituted with a fluorine atom and an oxygen atom are connected (group represented by Formula (X) (repeating unit)), and more preferably includes a perfluoroalkylene ether group.

-(L_{A}-O)— Formula (X)

L_{A} represents an alkylene group substituted with a fluorine atom. The number of carbon atoms in the alkylene group is preferably 1 to 20, more preferably 1 to 10, and even more preferably 1 to 5. The alkylene group substituted with a fluorine atom may include an oxygen atom.

The alkylene group substituted with a fluorine atom may be linear or branched.

The perfluoroalkylene ether group is a group in which L_{A} is a perfluoroalkylene group. The perfluoroalkylene group is a group in which all hydrogen atoms in an alkylene group are substituted with fluorine atoms.

The group represented by Formula (X) (repeating unit) may be repeatedly connected, and the number of repeating units is not particularly limited, but preferably 1 to 50, and more preferably 1 to 20 in view of more excellent effects of the invention.

Namely, a group represented by Formula (X-1) is preferable.

-(L_{A}-O)ᵣ— Formula (X-1)

In Formula (X-1), L_{A} is as described above. r represents the number of repeating units, and its preferable range is as described above.

In a plurality of groups -(L_{A}-O)—, L_{A}'S may be the same or different.

In a case where the fluorine-containing polymerizable compound is a monomer, the number of at least one type of group selected from the group consisting of a fluorine atom, a silicon atom, a linear alkyl group having 8 or more carbon atoms, and a branched alkyl group having 3 or more carbon atoms in one molecule is preferably 1 to 20, and more preferably 3 to 15.

In a case where the fluorine-containing polymerizable compound is a polymer, the polymer preferably has at least one of a repeating unit represented by Formula (B1), a repeating unit represented by Formula (B2), or a repeating unit represented by Formula (B3).

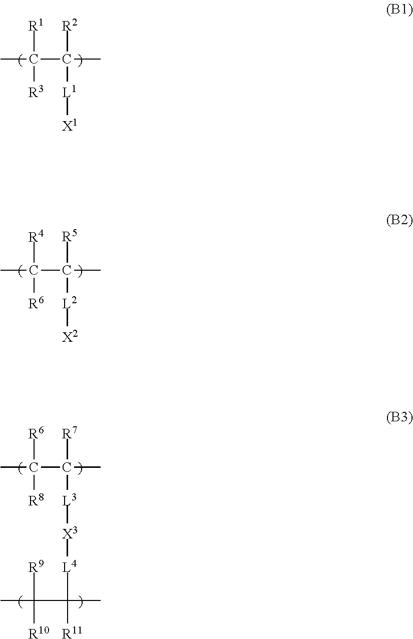

In Formulae (B1) to (B3), R¹ to R¹¹ each independently represent a hydrogen atom, an alkyl group, or a halogen atom. L¹ to L⁴ each independently represent a single bond or a divalent linking group. X¹ represents a (meth)acryloyloxy group, an epoxy group, or an oxetanyl group. X² represents an alkyl group substituted with a fluorine atom or an aryl group substituted with a fluorine atom. X³ represents a repeating unit represented by Formula (X-1).

In Formulae (B1) to (B3), R¹ to R¹¹ each independently are preferably a hydrogen atom or an alkyl group. In a case where R¹ to R¹¹ represent alkyl groups, an alkyl group having 1 to 3 carbon atoms is preferable. In a case where R¹ to R¹¹ represent halogen atoms, a fluorine atom is preferable.

In a case where L¹ to L⁴ represent divalent linking groups in Formulae (B1) to (B3), examples of the divalent linking group include an alkylene group in which a halogen atom may be substituted, an arylene group in which a halogen atom may be substituted, —NR¹²—, —CONR¹²—, —CO—, —CO₂—, SO₂NR¹²—, —O—, —S—, —SO₂—, and combinations thereof. Among these, at least one selected from the group consisting of an alkylene group having 2 to 10 carbon atoms in which a halogen atom may be substituted and an arylene group having 6 to 12 carbon atoms in which a halogen atom may be substituted, or a group composed of a combination of these groups with at least one group selected from the group consisting of —NR¹²—, —CONR¹²—, —CO—, —CO₂—, SO₂NR¹²—, —O—, —S—, and SO₂— is preferable, and an alkylene group having 2 to 10 carbon atoms in which a halogen atom may be substituted, —CO₂—, —O—, —CO—, —CONR¹²—, or a group composed of a combination of these groups is more preferable. Here, R¹² represents a hydrogen atom or a methyl group.

The content of the repeating unit represented by Formula (B1) is preferably 30 to 95 mol %, and more preferably 45 to 90 mol % with respect to all the repeating units in the fluorine-containing polymerizable compound. The content of the repeating unit represented by Formula (B1) is preferably 30 mol % or greater, and more preferably 45 mol % or greater with respect to all the repeating units in the fluorine-containing polymerizable compound.

The total content of the repeating unit represented by Formula (B2) and the repeating unit represented by Formula (B3) is preferably 5 to 70 mol %, and more preferably 10 to 60 mol % with respect to all the repeating units in the fluorine-containing polymerizable compound. The total content of the repeating unit represented by Formula (B2) and the repeating unit represented by Formula (B3) is preferably 5 mol % or greater, and more preferably 10 mol % or greater with respect to all the repeating units in the fluorine-containing polymerizable compound.

In a case where the repeating unit represented by Formula (B2) is not included, but the repeating unit represented by Formula (B3) is included, it is preferable that the content of the repeating unit represented by Formula (B2) is 0 mol %, and the content of the repeating unit represented by Formula (B3) is within the above-described range.

The fluorine-containing polymerizable compound may have a different repeating unit other than the repeating units represented by Formulae (B1) to (B3). The content of the different repeating unit is preferably 10 mol % or less, and more preferably 1 mol % or less with respect to all the repeating units in the fluorine-containing polymerizable compound.

In a case where the fluorine-containing polymerizable compound is a polymer, the weight average molecular weight (Mw: in terms of polystyrene) thereof is preferably 5,000 to 100,000, and more preferably 7,000 to 50,000. In a case where a curable compound A is a polymer, the weight average molecular weight thereof is preferably 5,000 or greater, and more preferably 7,000 or greater.

In a case where the fluorine-containing polymerizable compound is a polymer, the dispersion degree (weight average molecular weight/number average molecular weight) is preferably 1.80 to 3.00, and more preferably 2.00 to 2.90.

Gel permeation chromatography (GPC) is based on a method using HLC-8020 GPC (manufactured by Tosoh Corporation), TSKgel SuperHZM-H, TSKgel SuperHZ4000, and TSKgel SuperHZ2000 (manufactured by Tosoh Corporation, 4.6 mm ID×15 cm) as columns, and tetrahydrofuran (THF) as an eluent.

As a commercially available product of the fluorine-containing polymerizable compound, for example, MEGAFAC RS-72-K, MEGAFAC RS-75, MEGAFAC RS-76-E, MEGAFAC RS-76-NS, MEGAFAC RS-77, or the like manufactured by DIC Corporation can be used.

The content of the polymerizable compound is preferably 1 to 50 mass % with respect to the total solid content of the infrared absorbing composition. The lower limit is preferably not less than 2 mass %, and more. preferably not less than 3 mass %. The upper limit is preferably not greater than 40 mass %, and more preferably not greater than 30 mass %.

<<Photopolymerization Initiator>>

The infrared absorbing composition may contain a photopolymerization initiator.

The content of the photopolymerization initiator is preferably 0.01 to 30 mass % with respect to the total solid content of the infrared absorbing composition. The lower limit is preferably not less than 0.1 mass %, and more preferably not less than 0.5 mass %. The upper limit is preferably not greater than 20 mass %, and more preferably not greater than 15 mass %.

The photopolymerization initiator may be used singly, or two or more types thereof may be used. In a case where two or more types are used, the total amount thereof is preferably within the above-described range.

The photopolymerization initiator is not particularly limited as long as it has properties of initiating polymerization of a curable compound by light, whereby it can be appropriately selected according to the purpose. In a case where polymerization is initiated by light, a photopolymerization initiator having photosensitivity to light rays from an ultraviolet region to a visible region is preferable.

The photopolymerization initiator is preferably a compound having at least an aromatic group, and examples thereof include an acylphosphine compound, an acetophenone-based compound, an α-aminoketone compound, a benzophenone-based compound, a benzoin ether-based compound, a ketal derivative compound, a thioxanthone compound, an oxime compound, a hexaarylbiimidazole compound, a trihalomethyl compound, an azo compound, an organic peroxide, an onium salt compound such as a diazonium compound, an iodonium compound, a sulfonium compound, an azinium compound, a benzoin ether-based compound, a ketal derivative compound, and a metallocene compound, an organic boron salt compound, a disulfone compound, and a thiol compound.

Regarding the photopolymerization initiator, the description in paragraphs 0217 to 0228 of JP2013-253224A can be referred to, and the contents thereof are incorporated into this specification.

As the oxime compound, IRGACURE-OXE01 (manufactured by BASF SE), IRGACURE-OXE02 (manufactured by BASF SE), TR-PBG-304 (manufactured by Changzhou Tronly New Electronic Materials CO., LTD.), ADEKA ARKLS NCI-831 (manufactured by ADEKA Corporation), and ADEKA ARKLS NCI-930 (manufactured by ADEKA Corporation), and the like, that are commercially available products, can be used.

As the acetophenone-based compound, IRGACURE-907, IRGACURE-369, and IRGACURE-379 (trade name: all manufactured by BASF SE), that are commercially available products, can be used. As the acylphosphine compound, IRGACURE-819 and DAROCUR-TPO (trade name: all manufactured by BASF SE), that are commercially available products, can be used.

According to the invention, an oxime compound having a fluorine atom can also be used as the photopolymerization initiator. Specific examples of the oxime compound having a fluorine atom include the compounds described in JP2010-262028A, the compounds 24 and 36 to 40 described in JP2014-500852A, and the compound (C-3) described in JP2013-164471A. The contents thereof are incorporated into this specification.

<<Solvent>>

The infrared absorbing composition may contain a solvent. The solvent is not particularly limited, and can be appropriately selected according to the purpose as long as respective components of the infrared absorbing composition can be evenly dissolved or dispersed. For example, water or an organic solvent can be used, and an organic solvent is preferable.

Preferable examples of the organic solvent include alcohols (for example, methanol), ketones, esters, aromatic hydrocarbons, halogenated hydrocarbons, dimethylformamide, dimethylacetamide, dimethylsulfoxide, and sulfolane. These may be used singly, or two or more types thereof may be used in combination. In a case where two or more types of solvents are used in combination, a mixed solution formed of two or more selected from methyl 3-ethoxypropionate, ethyl 3-ethoxypropionate, ethyl cellosolve acetate, ethyl lactate, diethylene glycol dimethyl ether, butyl acetate, methyl 3-methoxypropionate, 2-heptanone, cyclohexanone, ethyl carbitol acetate, butyl carbitol acetate, ethylene glycol monobutyl ether acetate, propylene glycol monomethyl ether, and propylene glycol monomethyl ether acetate is preferable.

Specific examples of the alcohols, the aromatic hydrocarbons, and the halogenated hydrocarbons include those described in paragraph 0136 of JP2012-194534A, and the contents thereof are incorporated into this specification. In addition, specific examples of the esters, the ketones, and the ethers include those described in paragraph 0497 of JP2012-208494A ([0609] of US2012/0235099A corresponding thereto), and further include n-amyl acetate, ethyl propionate, dimethyl phthalate, ethyl benzoate, methyl sulfate, acetone, methyl isobutyl ketone, diethyl ether, and ethylene glycol monobutyl ether acetate.

The amount of the solvent in the infrared absorbing composition is preferably set such that a solid content becomes 10 to 90 mass %. The lower limit is preferably not less than 20 mass %. The upper limit is preferably not greater than 80 mass %.

<<Surfactant>>

The infrared absorbing composition may contain a surfactant. The surfactant may be used singly, or two or more types thereof may be used in combination. The content of the surfactant is preferably 0.0001 to 5 mass % with respect to the total solid content of the infrared absorbing composition. The lower limit is preferably not less than 0.005 mass %, and more preferably not less than 0.01 mass %. The upper limit is preferably not greater than 2 mass %, and more preferably not greater than 1 mass %.

As the surfactant, various surfactants such as a fluorine-based surfactant, a nonionic surfactant, a cationic surfactant, an anionic surfactant, and a silicone-based surfactant can be used. The infrared absorbing composition preferably contains at least one of a fluorine-based surfactant or a silicone-based surfactant. The interface tension between a coating surface and a coating liquid is lowered, and wettability to the coating surface is thus improved. Therefore, liquid characteristics (particularly, fluidity) of the composition is improved, and uniformity of a coating thickness and liquid saving properties are further improved. As a result, even in a case where a film having a small thickness of approximately several micrometers is formed with a small amount of a liquid, a film having a uniform thickness with little thickness unevenness can be formed.

The fluorine content of the fluorine-based surfactant is preferably 3 to 40 mass %. The lower limit is preferably not less than 5 mass %, and more preferably not less than 7 mass %. The upper limit is preferably not greater than 30 mass %, and more preferably not greater than 25 mass %. A fluorine-based surfactant having a fluorine content within the above-described range is effective in view of uniformity of a thickness of a coating film and liquid saving properties, and satisfactory solubility is obtained.

Specific examples of the fluorine-based surfactant include the surfactants described in paragraphs 0060 to 0064 of JP2014-41318A (paragraphs 0060 to 0064 of WO2014/17669A corresponding thereto), and the contents thereof are incorporated into this specification. Examples of commercially available products of the fluorine-based surfactant include MEGAFAC F-171, MEGAFAC F-172, MEGAFAC F-173, MEGAFAC F-176, MEGAFAC F-177, MEGAFAC F-141, MEGAFAC F-142, MEGAFAC F-143, MEGAFAC F-144, MEGAFAC R30, MEGAFAC F-437, MEGAFAC F-475, MEGAFAC F-479, MEGAFAC F-482, MEGAFAC F-554, MEGAFAC F-780, (all manufactured by DIC Corporation), FLUORAD FC430, FLUORAD FC431, FLUORAD FC171 (all manufactured by Sumitomo 3M Limited.), SURFLON S-382, SURFLON SC-101, SURFLON SC-103, SURFLON SC-104, SURFLON SC-105, SURFLON SC-1068, SURFLON SC-381, SURFLON SC-383, SURFLON S393, and SURFLON KH-40 (all manufactured by Asahi Glass Co., Ltd.).

The following compound is also exemplified as the fluorine-based surfactant that is used in the invention.

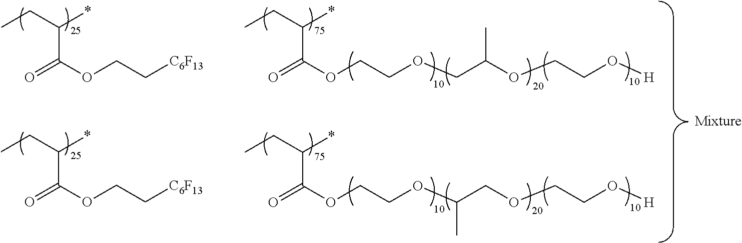

The weight average molecular weight of the above compound is, for example, 14,000.

Specific examples of the nonionic surfactant include the nonionic surfactants described in paragraph 0553 of JP2012-208494A ([0679] of US2012/0235099A corresponding thereto), and the contents thereof are incorporated into this specification.

Specific examples of the cationic surfactant include the cationic surfactants described in paragraph 0554 of JP2012-208494A ([0680] of US2012/0235099A corresponding thereto), and the contents thereof are incorporated into this specification.

Specific examples of the anionic surfactant include W004, W005, and W017 (manufactured by Yusho Co., Ltd.).

Examples of the silicone-based surfactant include the silicone-based surfactants described in paragraph 0556 of JP2012-208494A ([0682] of US2012/0235099A corresponding thereto), and the contents thereof are incorporated into this specification.

<<Polymerization Inhibitor>>

The infrared absorbing composition may contain a small amount of a polymerization inhibitor.

Examples of the polymerization inhibitor include hydroquinone, p-methoxyphenol, di-t-butyl-p-cresol, pyrogallol, t-butylcatechol, benzoquinone, 4,4′-thiobis(3-methyl-6-t-butylphenol), 2,2′-methylenebis(4-methyl-6-t-butylphenol), and N-nitrosophenylhydroxyamine cerous salt, and p-methoxyphenol is preferable.

The content of the polymerization inhibitor is preferably 0.01 to 5 mass % with respect to the total solid content of the infrared absorbing composition.

<<Ultraviolet Absorbing Agent>>

The infrared absorbing composition may contain an ultraviolet absorbing agent.

A known compound can be used as the ultraviolet absorbing agent. Examples of commercially available products thereof include UV503 (Daito Chemical Co., Ltd.).

The content of the ultraviolet absorbing agent is preferably 0.01 to 10 mass %, and more preferably 0.01 to 5 mass % with respect to the total solid content of the infrared absorbing composition.

<<<<Other Components>>>>

The infrared absorbing composition may further contain, for example, a dispersing agent, a sensitizer, a crosslinking agent, a curing accelerator, a filler, a thermal curing accelerator, a thermal polymerization inhibitor, a plasticizer, an adhesion promoter, and other auxiliary agents (for example, conductive particles, a filler, an antifoaming agent, a flame retardant, a leveling agent, a peeling promoter, an antioxidant, a fragrance material, a surface tension adjuster, and a chain transfer agent).

Regarding these components, for example, the description in paragraphs 0183 to 0228 of JP2012-003225A ([0237] to [0309] of US2013/0034812A corresponding thereto), paragraphs 0101 to 0104 and 0107 to 0109 of JP2008-250074A, paragraphs 0159 to 0184 of JP2013-195480A, and the like can be referred to, and the contents thereof are incorporated into this specification.

<Method of Preparing Infrared Absorbing Composition>

The infrared absorbing composition can be prepared by mixing the above-described components.

For the purpose of removing foreign substances, reducing defects, or the like, the infrared absorbing composition is preferably filtrated with a filter. The filter can be used without particular limitation, as long as it has been used for the filtration use. Examples thereof include filters made of a fluorine resin such as polytetrafluoroethylene (PTFE), a polyamide-based resin such as nylon-6 or nylon-6,6, or a polyolefin resin (with high density and ultrahigh molecular weight) such as polyethylene or polypropylene (PP). Among these materials, polypropylene (including high-density polypropylene) is preferable.

The hole diameter of the filter is preferably 0.01 to 7.0 μm, more preferably 0.01 to 2.5 μm, and even more preferably about 0.01 to 1.5 μm. In a case where the hole diameter of the filter is within the above-described range, it is possible to securely remove fine foreign substances.

When the filter is used, a different filter may be combined therewith. In this case, the filtering in a first filter may be performed once, or twice or more times. In a case where the filtering is performed twice or more times by combining a different filter, the hole diameters of a second filter or thereafter are preferably larger than a hole diameter of a first filter. In addition, a first filter having a different hole diameter within the above-described range may be combined. Regarding the hole diameters herein, nominal values of filter manufacturers can be referred to. A commercially available filter can be selected from various filters provided by, for example, Nihon Pall Ltd., Toyo Roshi Kaisha, Ltd., Entegris Japan Co., Ltd. (formerly, Mykrolis Corporation), or Kitz Microfilter Corporation.

As a second filter, a filter formed with the same material as the above-described first filter can be used. The hole diameter of the second filter is preferably 0.5 to 7.0 μm, more preferably 2.5 to 7.0 μm, and even more preferably 4.5 to 6.0 μm. In a case where the hole diameter of the filter is within the above-described range, it is possible to remove foreign substances disturbing the preparation of a uniform and smooth light shielding composition in a post-steps while leaving component particles contained in the composition mixture.

For example, after filtering in the first filter, other components may be added and second filtering may be then performed.

The viscosity of the infrared absorbing composition is preferably in a range of 1 to 3,000 mPa·s in a case where, for example, the infrared absorbing layer is formed by coating. The lower limit is preferably not less than 10 mPa·s, and more preferably not less than 100 mPa·s. The upper limit is preferably not greater than 2,000 mPa·s, and more preferably not greater than 1,500 mPa·s.

<Method of Forming Infrared Absorbing Layer>

The infrared absorbing layer can be formed by: applying the above-described infrared absorbing composition to a copper-containing transparent layer, a support, a dielectric multi-layer film to be described later, or the like; and drying the composition. The film thickness can be appropriately selected according to the purpose.

The infrared absorbing composition can be applied using a dropwise addition method (drop cast), a spin coater, a slit spin coater, a slit coater, screen printing, applicator coating, or the like.

The drying conditions vary depending on the respective components, type of the solvent, use ratio, and the like. For example, the drying is performed at a temperature of 60° C. to 150° C. for about 30 seconds to 15 minutes.

The method of forming an infrared absorbing layer may include other steps. Other steps are not particularly limited, and can be appropriately selected according to the purpose. Examples thereof include a pre-heating step (pre-baking step), a curing treatment step, and a post-heating step (post-baking step).

<<Pre-Heating Step and Post-Heating Step>>

The heating temperature in the pre-heating step and the post-heating step is generally 80° C. to 200° C., and preferably 90° C. to 150° C. The heating time in the pre-heating step and the post-heating step is generally 30 seconds to 240 second, and preferably 60 seconds to 180 seconds.

<<Curing Treatment Step>>

The curing treatment step is a step of performing a curing treatment on the formed film if necessary. In a case where this treatment is performed, the mechanical strength of the infrared absorbing layer is improved. In a case where an infrared absorbing composition containing a polymerizable compound is used, it is preferable to perform the curing treatment step.

The curing treatment step is not particularly limited, and can be appropriately selected according to the purpose. Preferable examples thereof include an entire surface exposure treatment and an entire surface heating treatment. Here, in the invention, the expression “exposure” includes not only irradiation of light having various wavelengths, but also irradiation of radiation such as electron rays and X-rays.

The exposure is preferably performed by radiation irradiation, and as the radiation that can be used in the exposure, particularly, electron rays, KrF, ArF, ultraviolet rays such as g-rays, h-rays, and i-rays, and visible light are preferably used.

Examples of the exposure method include stepper exposure and exposure using a high-pressure mercury lamp.

The exposure amount is preferably 5 to 3,000 mJ/cm², more preferably 10 to 2,000 mJ/cm², and particularly preferably 50 to 1,000 mJ/cm².

Examples of the entire surface exposure treatment include a method of exposing an entire surface of the formed film. In a case where the infrared absorbing composition contains a polymerizable compound, the entire surface exposure promotes the curing of polymerization components in the film, and thus the curing of the film further proceeds, and solvent resistance and heat resistance of the infrared absorbing layer are improved.

The device that performs the entire surface exposure is not particularly limited, and can be appropriately selected according to the purpose. Preferable examples thereof include a UV exposure machine such as an ultrahigh-pressure mercury lamp.

Examples of the method for the entire surface heating treatment include a method of heating the entire surface of the formed film. Through the entire surface heating, solvent resistance and heat resistance of the infrared absorbing layer are improved.

The heating temperature in the entire surface heating is preferably 120° C. to 250° C., and more preferably 160° C. to 220° C. In a case where the heating temperature is not lower than 120° C., film hardness is improved by the heating treatment, and in a case where the heating temperature is not higher than 250° C., decomposition of the film components can be suppressed.

In the entire surface heating, the heating time is preferably 3 minutes to 180 minutes, and more preferably 5 minutes to 120 minutes.

The device that performs the entire surface heating is not particularly limited, and can be appropriately selected among known devices according to the purpose. Examples thereof include a dry oven, a hot plate, and an IR heater.

<<Dielectric Multi-Layer Film>>

The infrared cut filter according to the invention preferably has a dielectric multi-layer film. In a case where a dielectric multi-layer film is provided, an infrared cut filter having a wide view angle and excellent infrared shieldability can be easily obtained.

In the invention, the dielectric multi-layer film is a film that shields infrared rays using a light interference effect. That is, the dielectric multi-layer film means a film having properties of reflecting infrared rays. Specifically, the dielectric multi-layer film is a film formed by alternately laminating two or more dielectric layers having different refractive indices (high refractive index material layer and low refractive index material layer).

A film that shields infrared rays by absorbing the infrared rays (infrared absorbing agent-containing film) corresponds to an infrared absorbing film, and is different from the dielectric multi-layer film.

In the invention, the dielectric multi-layer film may be provided on one side or both sides of a copper-containing transparent layer. In a case where the dielectric multi-layer film is provided on one side, manufacturing cost is reduced and manufacturing easiness is improved. In a case where the dielectric multi-layer film is provided on both sides, an infrared cut filter that has high strength and hardly warps can be obtained. The dielectric multi-layer film may be or may not be in contact with the copper-containing transparent layer.

It is preferable that the infrared cut filter according to the invention has an infrared absorbing layer between the copper-containing transparent layer and the dielectric multi-layer film, and the infrared absorbing layer and the dielectric multi-layer film are in contact with each other. By virtue of such a configuration, the infrared absorbing layer is shielded from oxygen and moisture by the dielectric multi-layer film, and thus light resistance and moisture resistance of the infrared cut filter are improved. Furthermore, an infrared cut filter having a wide view angle and excellent infrared shieldability can be easily obtained.

As a material of the dielectric multi-layer film, for example, ceramics can be used. In order to form an infrared cut filter using a light interference effect, two or more types of ceramics having different refractive indices are preferably used. As the dielectric multi-layer film, specifically, a configuration formed by alternately laminating a high refractive index material layer and a low refractive index material layer can be preferably used.

A material having a refractive index of 1.7 or greater can be used as a material constituting the high refractive index material layer, and in general, a material having a refractive index of 1.7 to 2.5 is selected. Examples of this material include materials containing titanium oxide, zirconium oxide, tantalum pentoxide, niobium pentoxide, lanthanum oxide, yttrium oxide, zinc oxide, zinc sulfide or indium oxide as a main component, and a small amount of titanium oxide, tin oxide, and/or cerium oxide.

A material having a refractive index of 1.6 or less can be used as a material constituting the low refractive index material layer, and in general, a material having a refractive index of 1.2 to 1.6 is selected. Examples of this material include silica, alumina, lanthanum fluoride, magnesium fluoride, and sodium aluminum hexafluoride.

The method of forming the dielectric multi-layer film is not particularly limited. Examples thereof include a method including: forming a dielectric multi-layer film in which a high refractive index material layer and a low refractive index material layer are alternately laminated via a chemical vapor deposition (CVD) method, a sputtering method, a vacuum deposition method, or the like; and adhering the obtained dielectric multi-layer film to a copper-containing transparent layer and/or an infrared absorbing layer using an adhesive, and a method including alternately laminating a high refractive index material layer and a low refractive index material layer on a surface of a copper-containing transparent layer and/or an infrared absorbing layer via a CVD method, a sputtering method, a vacuum deposition method, or the like to form a dielectric multi-layer film.

Thicknesses of the high refractive index material layer and the low refractive index material layer are preferably 0.1λ to 0.5λ of the infrared wavelength λ (nm) to be shielded. In a case where the thicknesses are within the above-described range, shielding and transmittance of specific wavelengths are easily controlled.

The number of the layers in the dielectric multi-layer film is preferably 2 to 100, more preferably 2 to 60, and even more preferably 2 to 40. In a case where the substrate warps when the dielectric multi-layer film is deposited, the dielectric multi-layer film may be deposited on both sides of the substrate, or a method can be carried out in which a surface of the substrate on which the dielectric multi-layer film is deposited is subjected to irradiation with radiation such as ultraviolet light in order to solve the warping problem. In cases where radiation irradiation is performed, the irradiation may be performed while the dielectric multi-layer film is deposited, or the irradiation may be performed separately after the deposition.

<Layer Configuration of Infrared Cut Filter>

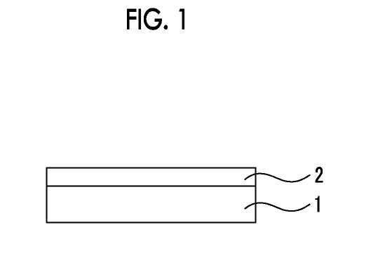

The infrared cut filter according to the invention may have a structure having a copper-containing transparent layer and an infrared absorbing layer. Examples thereof include a lamination structure shown in FIG. 1. In FIG. 1, 1 represents a copper-containing transparent layer, and 2 represents an infrared absorbing layer.

Examples of the layer configuration of the infrared cut filter according to the invention are as follows. In the following examples, a layer containing copper, but not containing an infrared absorbing agent is represented by Layer A, a layer containing copper and an infrared absorbing agent is represented by Layer A1, a layer containing an infrared absorbing agent is represented by Layer B, and a dielectric multi-layer film is represented by Layer C.

Among the following layer configurations, (9), (10), (25), (26), and (32) having a layer configuration in which Layer B is provided on both sides of Layer A are preferable. Among these, (9) and (10) are more preferable.

(38) to (50) having Layer A1 are also preferable, and (38) is more preferable.

(1) Layer A/Layer B

(2) Layer A/Layer B/Layer C

(3) Layer A/Layer C/Layer B

(4) Support/Layer B/Layer A

(5) Support/Layer B/Layer A/Layer C

(6) Support/Layer B/Layer C/Layer A

(7) Support/Layer C/Layer A/Layer B

(8) Support/Layer C/Layer B/Layer A

(9) Layer B/Layer A/Layer B

(10) Layer B/Layer A/Layer B/Layer C

(11) Layer B/Layer A/Layer C/Layer B

(12) Layer B/Support/Layer B/Layer A

(13) Layer B/Support/Layer B/Layer A/Layer C

(14) Layer B/Support/Layer B/Layer C/Layer A

(15) Layer B/Support/Layer C/Layer A/Layer B

(16) Layer B/Support/Layer C/Layer B/Layer A

(17) Layer C/Layer A/Layer B

(18) Layer C/Layer A/Layer B/Layer C

(19) Layer C/Layer A/Layer C/Layer B

(20) Layer C/Support/Layer B/Layer A

(21) Layer C/Support/Layer B/Layer A/Layer C

(22) Layer C/Support/Layer B/Layer C/Layer A

(23) Layer C/Support/Layer C/Layer A/Layer B

(24) Layer C/Support/Layer C/Layer B/Layer A

(25) Layer C/Layer B/Layer A/Layer B/Layer C

(26) Layer C/Layer B/Layer A/Layer C/Layer B

(27) Layer C/Layer B/Support/Layer B/Layer A

(28) Layer C/Layer B/Support/Layer B/Layer A/Layer C

(29) Layer C/Layer B/Support/Layer B/Layer C/Layer A

(30) Layer C/Layer B/Support/Layer C/Layer A/Layer B

(31) Layer C/Layer B/Support/Layer C/Layer B/Layer A

(32) Layer B/Layer C/Layer A/Layer C/Layer B

(33) Layer B/Layer C/Support/Layer B/Layer A

(34) Layer B/Layer C/Support/Layer B/Layer A/Layer C

(35) Layer B/Layer C/Support/Layer B/Layer C/Layer A

(36) Layer B/Layer C/Support/Layer C/Layer A/Layer B

(37) Layer B/Layer C/Support/Layer C/Layer B/Layer A

(38) Layer A1

(39) Layer A1/Layer C

(40) Layer C/Layer A1/Layer C

(41) Support/Layer A1/Layer C

(42) Support/Layer C/Layer A1

(43) Layer A1/Support/Layer A1/Layer C

(44) Layer C/Support/Layer A1/Layer C

(45) Layer A1/Support/Layer C/Layer A1

(46) Layer C/Support/Layer C/Layer A1

(47) Layer C/Layer A1/Support/Layer A1/Layer C

(48) Layer A1/Layer C/Support/Layer A1/Layer C

(49) Layer C/Layer A1/Support/Layer C/Layer A1

(50) Layer A1/Layer C/Support/Layer C/Layer A1

<Use of Infrared Cut Filter>

The infrared cut filter according to the invention is used for lenses (camera lenses for digital cameras, cellular phones, vehicle-mounted cameras, and the like, and optical lenses such as f-0 lenses and pickup lenses) having a function of absorbing or cutting infrared rays, optical filters for a semiconductor light receiving element, and the like. The infrared cut filter is also useful as a noise cut filter for a CCD camera and a filter for a CMOS image sensor.

The infrared cut filter can also be preferably used for organic electroluminescence (organic EL) elements, solar cell elements, and the like.

<Kit>

A kit according to the invention is a kit for manufacturing an infrared cut filter having a copper-containing transparent layer and an infrared absorbing agent-containing layer, and has a copper-containing transparent member and an infrared absorbing agent-containing infrared absorbing composition.

The infrared absorbing composition is synonymous with the infrared absorbing composition in the description of the infrared absorbing layer of the infrared cut filter, and its preferable ranges are also similar.

As the copper-containing transparent member, the materials in the description of the copper-containing transparent layer of the infrared cut filter can be used, and its preferable ranges are also similar.

<Solid-State Imaging Device>

A solid-state imaging device according to the invention includes the infrared cut filter according to the invention. Regarding details of the solid-state imaging device including the infrared cut filter, the description in paragraphs 0106 and 0107 of JP2015-044188A and the description in paragraphs 0010 to 0012 of JP2014-132333A can be referred to, and the contents thereof are incorporated into this specification.

### EXAMPLES

Hereinafter, the invention will be described in further detail with reference to examples. Materials, amounts, ratios, process details, process orders, and the like provided in the following examples can be appropriately changed without departing from the gist of the invention. Accordingly, ranges of the invention are not limited to the following specific examples. Unless otherwise noted, “%” and “part” are based on mass. In addition, in the following description, propylene glycol monomethyl ether acetate will be referred to as PGMEA. NMR is an abbreviate for nuclear magnetic resonance. In the following formulae, Me represents a methyl group, and Ph represents a phenyl group.

<Infrared Cut Filter>

<<Copper-Containing Transparent Layer>>

Copper-Containing Transparent Layer (copper-containing glass base) 1: Fluorophosphate glass (manufactured by AGC TECHNO GLASS Co., Ltd., NF-50, thickness: 0.5 mm) was used.

Copper-Containing Transparent Layer 2: 45 parts by mass of the following copper complex, 49.9 parts by mass of the following resin, 5 parts by mass of IRGACURE-OXE02 (manufactured by BASF SE), 0.1 parts by mass of tris(2,4-pentanedionato)aluminum (III) (manufactured by Tokyo Chemical Industry Co., Ltd.), 66.7 parts by mass of cyclohexanone, and 0.5 parts by mass of water were mixed together to prepare a copper complex-containing composition. A glass wafer was coated with the obtained copper complex-containing composition using a spin coater such that a film thickness after drying was 100 μm, and was heat-treated for 3 hours using a hot plate at 150° C. to produce a copper-containing transparent layer 2. The copper-containing transparent layer 2 is a laminate of the glass wafer and the copper complex-containing layer composed of the copper complex-containing composition.

Copper Complex: The following structure

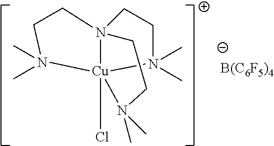

Resin: The following structure

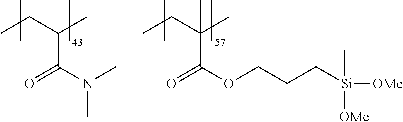

Copper-Containing Transparent Layer 3: A copper-containing transparent layer 3 was obtained in the same manner, except that in the copper complex of the copper-containing transparent layer 2, 22.5 parts by mass was substituted with the following compound.

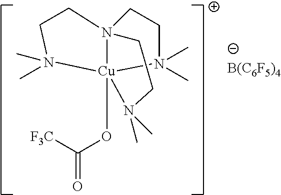

Copper-Containing Transparent Layer 4: A copper-containing transparent layer (a layer containing copper and an infrared absorbing agent) 4 was obtained in the same manner, except that 0.14 parts by mass of the following infrared absorbing agent (the following compound A-52) was added to the copper-containing transparent layer 3.

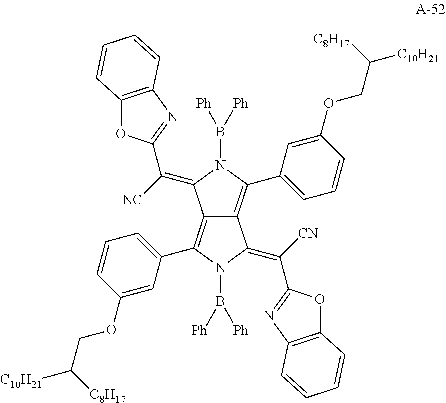

Copper-Containing Transparent Layer 5: On one side of the copper-containing transparent layer 1, 21 TiO₂ films, that were high refractive index dielectric films, and 21 SiO₂ films, that were low refractive index dielectric films, were alternately laminated to form a dielectric multi-layer film (total 42 layers of the TiO₂ films and the SiO₂ films, total film thickness: 4,300.82 nm), whereby a copper-containing transparent layer (a copper-containing glass base with a dielectric multi-layer film) 5 was obtained.

The thicknesses of the respective films in the dielectric multi-layer film are shown in the following table. In the following table, the numbers in the left columns correspond to a lamination order. No. 1 is on the copper-containing glass base side and No. 42 is an outermost surface. That is, the layers were laminated in order from No. 1 on the copper-containing glass to form the dielectric multi-layer film.

TABLE 4

| | Type | Film Thickness (nm) |
|---|---|---|
| 1 | TiO₂ | 22.2 |
| 2 | SiO₂ | 47.04 |
| 3 | TiO₂ | 37.58 |
| 4 | SiO₂ | 55.03 |
| 5 | TiO₂ | 33.04 |
| 6 | SiO₂ | 55.74 |
| 7 | TiO₂ | 34.49 |
| 8 | SiO₂ | 61.69 |
| 9 | TiO₂ | 34.08 |
| 10 | SiO₂ | 48.29 |
| 11 | TiO₂ | 33.34 |
| 12 | SiO₂ | 210.25 |
| 13 | TiO₂ | 118.89 |
| 14 | SiO₂ | 195.08 |
| 15 | TiO₂ | 106.77 |
| 16 | SiO₂ | 148.82 |
| 17 | TiO₂ | 99.94 |
| 18 | SiO₂ | 188.12 |
| 19 | TiO₂ | 116.04 |
| 20 | SiO₂ | 168.9 |
| 21 | TiO₂ | 93.17 |
| 22 | SiO₂ | 172.29 |
| 23 | TiO₂ | 112.44 |
| 24 | SiO₂ | 169.75 |
| 25 | TiO₂ | 86.15 |
| 26 | SiO₂ | 147 |
| 27 | TiO₂ | 77.92 |
| 28 | SiO₂ | 145 |
| 29 | TiO₂ | 75.54 |
| 30 | SiO₂ | 142.27 |
| 31 | TiO₂ | 75.07 |
| 32 | SiO₂ | 143.25 |
| 33 | TiO₂ | 75.29 |
| 34 | SiO₂ | 141.99 |
| 35 | TiO₂ | 76.89 |
| 36 | SiO₂ | 141.2 |
| 37 | TiO₂ | 78.83 |
| 38 | SiO₂ | 141.99 |
| 39 | TiO₂ | 81.65 |
| 40 | SiO₂ | 147.93 |
| 41 | TiO₂ | 85.12 |
| 42 | SiO₂ | 74.75 |

<<Infrared Absorbing Layer>>

<<Preparation of Infrared Absorbing Composition>>

(Infrared Absorbing Composition 1)

8.04 parts by mass of the following resin A, 0.1 parts by mass of the following compound SQ-23, 0.07 parts by mass of KAYARAD DPHA (manufactured by Nippon Kayaku Co., Ltd.) as a polymerizable compound, 0.265 parts by mass of MEGAFAC RS-72K (manufactured by DIC Corporation), 0.38 parts by mass of the following compound as a photopolymerization initiator, and 82.51 parts by mass of PGMEA as a solvent were mixed and stirred. Then, the mixture was filtrated with a nylon filter having a hole diameter of 0.5 μm (manufactured by Nihon Pall Ltd.), and thus an infrared absorbing composition was prepared.

Resin A: The following compound (Mw: 41,000)

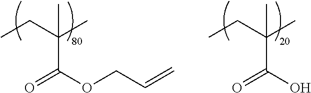

Compound SQ-23: The Following Structure

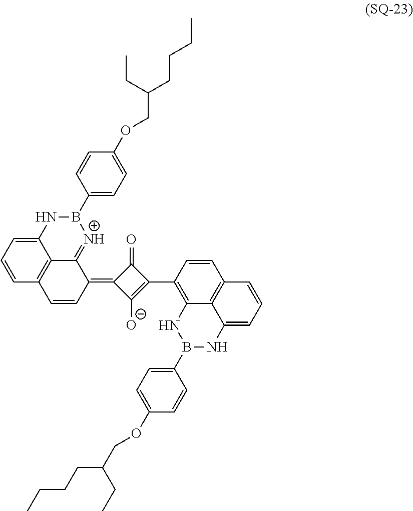 [SMILES: CCCCC(CC)COc1ccc(B2Nc3cccc4ccc(C5=C([O-])/C(=c6\ccc7cccc8c7c6=[NH+]B(c6ccc(OCC(CC)CCCC)cc6)N8)C5=O)c(c34)N2)cc1]

Photopolymerization Initiator: The Following Structure

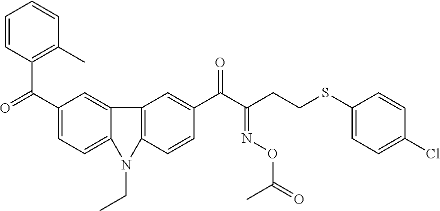 [SMILES: CCn1c2ccc(C(=O)/C(CCSc3ccc(Cl)cc3)=N/OC(C)=O)cc2c2cc(C(=O)c3ccccc3C)ccc21]

MEGAFAC RS-72K contains an alkylene group having a fluorine atom and an acryloyloxy group.

(Infrared Absorbing Composition 2)

An infrared absorbing composition 2 was prepared in the same manner as in the case of the infrared absorbing composition 1, except that the following compound A-52 was used in place of the compound SQ-23.

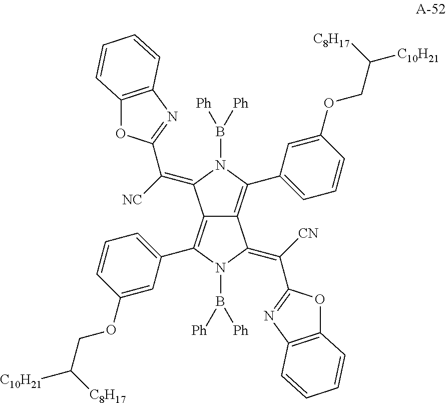

(Infrared Absorbing Composition 3)

0.5 parts by mass of the following compound C-15 was dissolved in 69.5 parts by mass of ion exchange water, 30.0 parts by mass of a 10 mass % aqueous solution of gelatin was further added thereto, and 0.3 parts by mass of 1,3-divinylsulfonyl-2-propanol was further added thereto as a hardener and stirred. Thus, an infrared absorbing composition 3 was prepared.

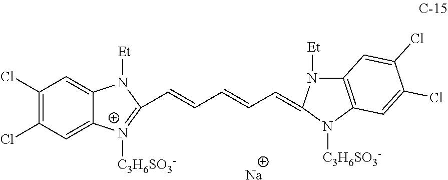

(Infrared Absorbing Composition 4)

An infrared absorbing composition 4 was prepared in the same manner as in the case of the infrared absorbing composition 3, except that the following compound 31 was used in place of the compound C-15.

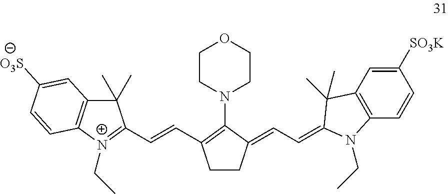

<Production of Infrared Cut Filter>

Each infrared absorbing composition prepared in the above description was coated on a surface of the copper-containing transparent layer using a spin coater (manufactured by MIKASA CO., LTD) to form a coating film. Pre-heating (pre-baking) was performed at 100° C. for 120 seconds, and then using an i-ray stepper, entire surface exposure was performed at 1,000 mJ/cm². Next, post-heating (post-baking) was performed at 220° C. for 300 seconds to form an infrared absorbing layer having a film thickness of 0.8 μm, and an infrared cut filter was obtained.

<Ratio B/A>

The infrared cut filter was dipped for 2 minutes at 25° C. in each of propylene glycol monomethyl ether (PGME), propylene glycol monomethyl ether acetate (PGMEA), methyl 3-methoxypropionate (MMP), ethyl lactate (EL), acetone, and ethanol, and a ratio of, to absorbance A at the maximum absorption wavelength before the infrared cut filter was dipped in each organic solvent, absorbance B at the wavelength at which the absorbance A was measured after the infrared cut filter was dipped in each organic solvent for 2 minutes at 25° C. was measured and evaluated based on the following standards.

5: B/A≧0.95

4: 0.95>B/A≧0.90

3: 0.90>B/A≧0.80

2: 0.80>B/A≧0.70

1: 0.70>B/A

<Light Resistance>

50,000 lux irradiation was performed for 20 hours on the infrared cut filter using a xenon lamp, and then chromatic aberration ΔEab before and after a light resistance test was measured. A filter with smaller ΔEab exhibits higher light resistance.

ΔEab is a value that is obtained from the following chromatic aberration formula based on the CIE1976 (L*, a*, b*) color coordinate system (edited by The Color Science Association of Japan, Handbook of Color Science (1985) p. 266).

ΔEab={(ΔL*)²+(Δa*)²+(Δb*)²}^{1/2}

<<Determination Standards>>

5: ΔEab<3

4: 3≦ΔEab<5

3: 5≦ΔEab<10

2: 10≦ΔEab<20

1: 20≦ΔEab

<Heat Resistance>

The infrared cut filter was heated for 30 minutes at 260° C. using a hot plate, and then chromatic aberration ΔEab before and after a heat resistance test was measured using a colorimeter MCPD-1000 (manufactured by OTSUKA ELECTRONICS Co., Ltd.) to perform the evaluation according to the following standards. A filter with smaller ΔEab exhibits higher heat resistance.

<<Determination Standards>>

5: ΔEab<3

4: 3≦ΔEab<5

3: 5≦ΔEab<10

2: 10≦ΔEab<20

1: 20≦ΔEab

<Infrared Shieldability>

Average transmittance at 700 to 1,000 nm measured in a direction perpendicular to the surface of the infrared cut filter was evaluated according to the following standards.

5: Less than 1%

4: Not less than 1% and less than 3%

3: Not less than 3% and less than 5%

2: Not less than 5% and less than 10%

1: Not less than 10%

<View Angle Dependency>

The incidence angle was changed to be perpendicular (0 degree), and also changed to 40 degrees with respect to the surface of the infrared cut filter to evaluate, according to the following standards, the quantity of shift of the wavelength at which the transmittance of the slope caused by a reduction in the spectral transmittance in a wavelength region of 600 nm or greater ranging from visible to near-infrared became 50%.

5: Less than 5 nm

4: Not less than 5 nm and less than 10 nm

3: Not less than 10 nm and less than 20 nm

2: Not less than 20 nm and less than 30 nm

1: Not less than 30 nm

TABLE 5

| | Used Copper-Containing Transparent Layer | Used Infrared Absorbing Composition |
|---|---|---|
| Example 1 | Copper-Containing Transparent Layer 1 | Infrared Absorbing Composition 1 |
| Example 2 | Copper-Containing Transparent Layer 1 | Infrared Absorbing Composition 2 |
| Example 3 | Copper-Containing Transparent Layer 1 | Infrared Absorbing Composition 3 |
| Example 4 | Copper-Containing Transparent Layer 1 | Infrared Absorbing Composition 4 |
| Example 5 | Copper-Containing Transparent Layer 2 | Infrared Absorbing Composition 1 |
| Example 6 | Copper-Containing Transparent Layer 2 | Infrared Absorbing Composition 2 |
| Example 7 | Copper-Containing Transparent Layer 2 | Infrared Absorbing Composition 3 |
| Example 8 | Copper-Containing Transparent Layer 2 | Infrared Absorbing Composition 4 |
| Example 9 | Copper-Containing Transparent Layer 3 | Infrared Absorbing Composition 1 |
| Example 10 | Copper-Containing Transparent Layer 3 | Infrared Absorbing Composition 2 |
| Example 11 | Copper-Containing Transparent Layer 3 | Infrared Absorbing Composition 3 |
| Example 12 | Copper-Containing Transparent Layer 3 | Infrared Absorbing Composition 4 |
| Example 13 | Copper-Containing Transparent Layer 4 | — |
| Example 14 | Copper-Containing Transparent Layer 5 | Infrared Absorbing Composition 4 |
| Comparative | Copper-Containing Transparent Layer 1 | — |
| Example 1 | | |

TABLE 6

| | Light | Heat | Ratio B/A | | | | | |
|---|---|---|---|---|---|---|---|---|
| | Resistance | Resistance | PGME | PGMEA | MMP | EL | Acetone | Ethanol |
| Example 1 | 5 | 5 | 5 | 5 | 5 | 5 | 5 | 5 |
| Example 2 | 5 | 5 | 5 | 5 | 5 | 5 | 5 | 5 |
| Example 3 | 5 | 5 | 5 | 5 | 5 | 5 | 5 | 5 |
| Example 4 | 4 | 5 | 5 | 5 | 5 | 5 | 5 | 5 |
| Example 5 | 5 | 5 | 5 | 5 | 5 | 5 | 4 | 5 |
| Example 6 | 5 | 5 | 5 | 5 | 5 | 5 | 4 | 5 |
| Example 7 | 5 | 5 | 5 | 5 | 5 | 5 | 4 | 5 |
| Example 8 | 4 | 5 | 5 | 5 | 5 | 5 | 4 | 5 |
| Example 9 | 5 | 5 | 5 | 5 | 5 | 5 | 4 | 5 |
| Example 10 | 5 | 5 | 5 | 5 | 5 | 5 | 4 | 5 |
| Example 11 | 5 | 5 | 5 | 5 | 5 | 5 | 4 | 5 |
| Example 12 | 4 | 5 | 5 | 5 | 5 | 5 | 4 | 5 |
| Example 13 | 5 | 5 | 5 | 5 | 5 | 5 | 4 | 5 |
| Example 14 | 5 | 5 | 5 | 5 | 5 | 5 | 5 | 5 |
| Comparative | 5 | 5 | 5 | 5 | 5 | 5 | 5 | 5 |
| Example 1 | | | | | | | | |

TABLE 7

| | Infrared Shieldability | View Angle Dependency |
|---|---|---|
| Example 1 | 5 | 5 |
| Example 2 | 5 | 5 |
| Example 3 | 5 | 5 |
| Example 4 | 5 | 5 |
| Example 5 | 5 | 5 |
| Example 6 | 5 | 5 |
| Example 7 | 5 | 5 |
| Example 8 | 5 | 5 |
| Example 9 | 5 | 5 |
| Example 10 | 5 | 5 |
| Example 11 | 5 | 5 |
| Example 12 | 5 | 5 |
| Example 13 | 5 | 5 |
| Example 14 | 5 | 4 |
| Comparative | 1 | 5 |
| Example 1 | | |

From the above results, Examples 1 to 14 were excellent in infrared shieldability and view angle dependency. In addition, B/A was 0.9 or greater. These infrared cut filters had no defects even after dipped in each organic solvent.

The same effects are obtained even in a case where “KAYARAD DPHA” is changed to the same amount of ethyleneoxy-denatured pentaerythritol tetraacrylate (NK ester ATM-35E; manufactured by Shin-Nakamura Chemical Co., Ltd.), dipentaerythritol triacrylate (KAYARAD D-330; manufactured by Nippon Kayaku Co., Ltd.), dipentaerythritol tetraacrylate (KAYARAD D-320; manufactured by Nippon Kayaku Co., Ltd.), or dipentaerythritol penta(meth)acrylate (KAYARAD D-310; manufactured by Nippon Kayaku Co., Ltd.) in the infrared absorbing composition 1.

The same effects are obtained even in a case where the resin A is changed to the same amount of the following resin in the infrared absorbing composition 1.

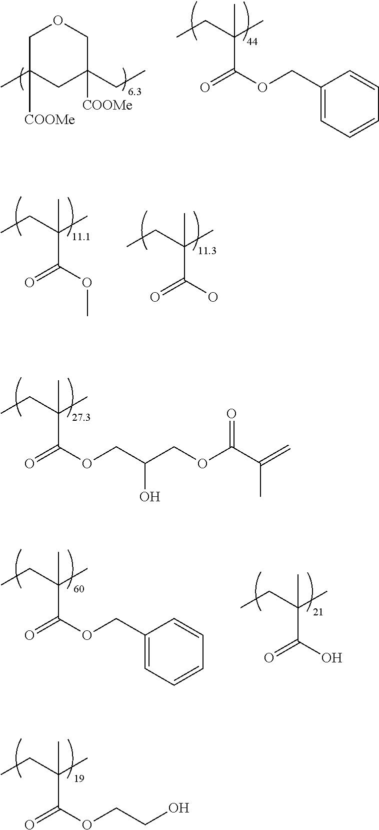

The same effects are obtained even in a case where the surfactant described in paragraph 0167 of this specification is further added in a range of 0.0001 to 5 mass % with respect to the total solid content of the infrared absorbing composition in the infrared absorbing composition 1.

The same effects are obtained even in a case where PGMEA is substituted with the solvent described in paragraph 0165 of this specification in the infrared absorbing composition 1.

### EXPLANATION OF REFERENCES

1: copper-containing transparent layer
2: infrared absorbing layer

What is claimed is:

1. An infrared cut filter comprising:
a copper-containing transparent layer,
wherein the copper-containing transparent layer further contains an infrared absorbing agent, or;
the infrared cut filter further comprises an infrared absorbing agent-containing layer.

2. The infrared cut filter according to claim 1,
wherein a maximum absorption wavelength is shown in a wavelength region of 600 nm or greater, and
a ratio B/A of, to absorbance A at the maximum absorption wavelength before the infrared cut filter is dipped in at least one organic solvent selected from propylene glycol monomethyl ether, propylene glycol monomethyl ether acetate, methyl 3-methoxypropionate, ethyl lactate, acetone, and ethanol, absorbance B at the wavelength at which the absorbance A is measured after the infrared cut filter is dipped in the organic solvent for 2 minutes at 25° C. is 0.9 or greater.

3. The infrared cut filter according to claim 1,
wherein the infrared absorbing agent-containing layer includes a resin.

4. The infrared cut filter according to claim 1,
wherein the infrared absorbing agent-containing layer includes a three-dimensional crosslinked material.

5. The infrared cut filter according to claim 4,
wherein the three-dimensional crosslinked material is formed by curing a polymerizable compound having two or more polymerizable groups.

6. The infrared cut filter according to claim 1,
wherein the infrared absorbing agent-containing layer includes gelatin.

7. The infrared cut filter according to claim 1,
wherein the infrared absorbing agent is a compound having a maximum absorption wavelength in a wavelength region of 675 to 900 nm.

8. The infrared cut filter according to claim 1,
wherein the infrared absorbing agent includes an organic coloring agent.

9. The infrared cut filter according to claim 1,
wherein the infrared absorbing agent contains at least one selected from a cyanine compound, a pyrrolopyrrole compound, a squarylium compound, a phthalocyanine compound, and a naphthalocyanine compound.

10. The infrared cut filter according to claim 1,
wherein the infrared absorbing agent is at least one selected from compounds represented by Formulae 1 to 3, 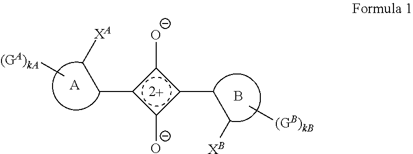
in Formula 1, a ring A and a ring B each independently represent an aromatic ring,
X^{A} and X^{B} each independently represent a substituent,
G^{A} and G^{B} each independently represent a substituent,
kA represents an integer of 0 to nA, and kB represents an integer of 0 to nB,
nA represents a maximum integer in which substitution with the ring A is possible, and nB represents a maximum integer in which substitution with the ring B is possible, and
each of X^{A} and G^{A}, and X^{B} and G^{B} may be bonded to form a ring, and in a case where there are plural G^{A}'s and G^{B}'s, each of G^{A}'s and G^{B}'s may be bonded to form a ring, 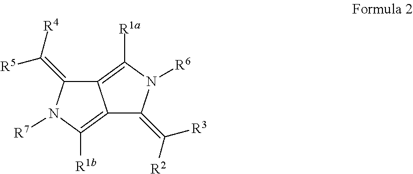
in Formula 2, R^{1a} and R^{1b} each independently represent an alkyl group, an aryl group, or a heteroaryl group,
R² to R⁵ each independently represent a hydrogen atom or a substituent, and each of R² and R³, and R⁴ and R⁵ may be bonded to form a ring,
R⁶ and R⁷ each independently represent a hydrogen atom, an alkyl group, an aryl group, a heteroaryl group, —BR^{A}R^{B}, or a metal atom, and R^{A} and R^{B} each independently represent a hydrogen atom or a substituent, and
R⁶ may be bonded to R^{a} or R³ by a covalent bond or a coordination bond, and R⁷ may be bonded to R^{1b} or R⁵ by a covalent bond or a coordination bond, 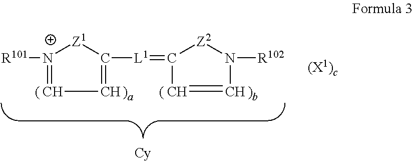
in Formula 3, Z¹ and Z² each independently represent a non-metallic atomic group necessary for forming a five-membered or six-membered nitrogen-containing heterocyclic ring that may be condensed,
R¹⁰¹ and R¹⁰² each independently represent an alkyl group, an alkenyl group, alkynyl group, an aralkyl group, or an aryl group,
L¹ represents a methine chain composed of an odd number of methines,
a and b each independently represent 0 or 1,
in a case where a is 0, a carbon atom and a nitrogen atom are bonded by a double bond, and in a case where b is 0, a carbon atom and a nitrogen atom are bonded by a single bond, and
in a case where a site represented by Cy in the formula is a cationic portion, X¹ represents an anion, and c represents the number necessary for keeping a balance of electric charges, in a case where a site represented by Cy in the formula is an anionic portion, X¹ represents a cation, and c represents the number necessary for keeping a balance of electric charges, and in a case where the electric charge of a site represented by Cy in the formula is neutralized in the molecule, c is zero.

11. The infrared cut filter according to claim 1,
wherein the infrared absorbing agent is a compound capable of being dissolved in an amount of 1 mass % or greater in water at 25° C.

12. The infrared cut filter according to claim 1, comprising:
the copper-containing transparent layer; and
the infrared absorbing agent-containing layer,
wherein the infrared absorbing agent-containing layer is provided on both sides of the copper-containing transparent layer.

13. The infrared cut filter according to claim 1, further comprising:
a dielectric multi-layer film.

14. The infrared cut filter according to claim 13, comprising:
the copper-containing transparent layer;
the infrared absorbing agent-containing layer; and
the dielectric multi-layer film,
wherein the infrared absorbing agent-containing layer is provided between the copper-containing transparent layer and the dielectric multi-layer film; and
the infrared absorbing agent-containing layer and the dielectric multi-layer film are in contact with each other.

15. A kit for manufacturing an infrared cut filter having a copper-containing transparent layer and an infrared absorbing agent-containing layer, comprising:
a copper-containing transparent member; and
an infrared absorbing composition containing an infrared absorbing agent.

16. A solid-state imaging device comprising:
the infrared cut filter according to claim 1.
